(19) United States
(12) Patent Application Publication
(10) Pub. No.: US 2025/0338683 A1
(43) Pub. Date: Oct. 30, 2025

(54) PANEL STRUCTURE, PIXEL STRUCTURE, AND METHOD FOR REPAIRING PIXEL STRUCTURE

(71) Applicant: Century Technology ( Shen-Zhen) Corp., LTD, Shen-Zhen (CN)

(72) Inventors: Deng-Kai CHANG, Shen-Zhen (CN); Lei-Cheng Sun, Shen-Zhen (CN); Ke-Xian Liu, Shen-Zhen (CN); Chang Zhang, Shen-Zhen (CN); Hsin-Chieh Wu, Shen-Zhen (CN); Chen-Qiong Lv, Shen-Zhen (CN); Sung-Nan Cheng, Shen-Zhen (CN); Yang Mei, Shen-Zhen (CN); Bing-Bing Liu, Shen-Zhen (CN); Shao-Fu Yang, Shen-Zhen (CN); Kuang-Hua Liu, Shen-Zhen (CN); Wen-Po Ko, Shen-Zhen (CN); Kuo-Sheng Lee, Shen-Zhen (CN); Chih-Kwang Tzen, Shen-Zhen (CN)

(21) Appl. No.: 19/191,183

(22) Filed: Apr. 28, 2025

(30) Foreign Application Priority Data
Apr. 28, 2024 (CN) 202410529603.4
Jun. 25, 2024 (CN) 202410828743.1
Jun. 27, 2024 (CN) 202410854864.3
Dec. 5, 2024 (CN) 202411787929.3
Feb. 14, 2025 (CN) 202510168134.2
Feb. 14, 2025 (CN) 202510169121.7

(51) Int. Cl. H10H 29/01; H10H 29/34; H10H 29/37; H10H 29/49

(52) U.S. Cl. CPC H10H 29/012; H10H 29/34; H10H 29/37; H10H 29/49

(57) ABSTRACT

A pixel structure comprises a substrate, a plurality of vertical diode dies, a flip-chip diode die, and an upper circuit layer. The substrate includes a lower circuit layer, which includes a plurality of first circuits and second circuits. The first circuits have a first polarity, and the second circuits have a second polarity. The plurality of vertical diode dies are disposed on the substrate and are respectively coupled to the first circuits. The flip-chip diode die is disposed on the substrate and is coupled to one of the first circuits and the second circuit. The upper circuit layer is disposed on the plurality of vertical diode dies and the flip-chip diode die. The upper circuit layer includes a plurality of third circuits, which are respectively coupled to the plurality of vertical diode dies, and the third circuits have the second polarity.

### CROSS-REFERENCE TO RELATED APPLICATION

This application claims priority to Chinese Patent Applications No. CN 202410529603.4 filed on Apr. 28, 2024; CN 202410828743.1 filed on Jun. 25, 2024; CN 202410854864.3 filed on Jun. 27, 2024; CN 202411787929.3 filed on Dec. 5, 2024; CN 202510169121.7 filed on Feb. 14, 2025; and CN 202510168134.2 filed on Feb. 14, 2025, the disclosures of which are incorporated herein in their entirety by reference.

### TECHNICAL FIELD

The present disclosure relates to a substrate structure for micro-light-emitting diodes, particularly a substrate structure containing a plurality of types of micro-light-emitting diodes.

### BACKGROUND

Micro-light-emitting diodes (micro-LEDs) are widely used in the lighting and display industries. According to the layout of the hierarchical structure, they can be mainly divided into flip-chip micro-LEDs and vertical micro-LEDs. The positive electrode (P-pole) and negative electrode (N-pole) of flip-chip micro-LEDs are located on the same side of the die and are disposed on the same horizontal plane; while the positive and negative electrodes of vertical micro-LEDs are located on the upper and lower sides of the die respectively and are disposed in the vertical direction. Since the positive and negative electrodes of flip-chip micro-LEDs are on the same side, it is easy to cause current congestion problems. In contrast, the electrode distribution of vertical micro-LEDs is more uniform, which effectively improves the current distribution and thus enhances the luminous efficiency. In addition, vertical micro-LEDs have excellent heat dissipation performance and are very suitable for the requirements of high-precision or small-size displays.

As display technology develops towards higher resolution and higher pixels per inch (PPI), the pixel size of light-emitting diode displays will become smaller and smaller, and the die size also needs to be reduced synchronously. Vertical micro-LEDs play a key role in the display industry due to their good heat dissipation performance and high luminous efficiency.

However, the existing technology still faces many challenges in the mass transfer and die repair of vertical micro-LEDs, which is also the main reason why vertical micro-LEDs have not yet dominated the market.

On the other hand, with the advancement of technology, micro-LED display devices are expected to gradually replace traditional liquid crystal display devices and become the mainstream in the market. Existing micro-LEDs include two types: pure-color micro-LEDs and color-conversion micro-LEDs. Among them, pure-color micro-LEDs can directly emit light of the corresponding color, while color-conversion micro-LEDs can convert the color of the emitted light through inkjet materials.

Compared with color conversion micro-LEDs, pure-color micro-LEDs have advantages such as simple structure, wider color gamut, and higher reliability. However, the manufacturing process of pure-color micro-LEDs requires a plurality of complex mass transfers, and their repair process is also quite complicated. In contrast, although the manufacturing process of color conversion micro-LEDs only requires one mass transfer, and the repair process of color conversion micro-LEDs is relatively simple. However, color conversion micro-LEDs also have disadvantages such as complex structure, narrower color gamut, and lower reliability.

On the other hand, there are currently variations in production equipment and manufacturing technology in the micro-LED process technology, resulting in specification differences among different types of micro-LEDs (such as three-color LEDs of red, green, and blue light). For example, the height difference value of various micro-LEDs may range from 2 μm to 10 μm.

Generally speaking, the height difference of micro-LEDs mainly stems from the process variations of the following structural layers: epitaxial layer, electrode layer, bonding layer, and encapsulation layer. The height difference among micro-LEDs will have an adverse impact on the subsequent eutectic bonding process, such as causing poor bonding and reducing the process yield. In addition, these height differences will also have a negative impact on the alignment accuracy in the process and the optical performance of the end product.

Therefore, how to effectively solve the height difference among micro-LEDs to improve process stability and yield is a major challenge in the development of the LED industry.

On the other hand, limited by the thickness difference among red micro-LED dies, green micro-LED dies, and blue micro-LED dies, the traditional micro-LED process fills a filling material into the gaps in each micro-LED through a filling technology to fix a plurality of components in the micro-LED, and then planarizes the filling material to overcome the problems caused by this thickness difference. Moreover, for different components in the micro-LED, different filling materials can be used in the filling technology to fix each component in sequence.

However, the existing filling technology still has the problem of poor flatness of the filling material, which causes an open circuit between components and makes the micro-LED unable to emit light normally. In addition, when different filling materials are used in the micro-LED to fix each component, the interface between each filling material may also lead to a decrease in the yield when manufacturing the micro-LED and the reliability of the micro-LED itself.

On the other hand, the manufacturing process of a micro-LED display device requires a plurality of mass transfers to move millions of micro-LED units. However, the existing mass transfer technology cannot achieve precise positioning, and there is currently no suitable method to arrange scattered micro-LED units on the same plane and neatly. Therefore, the existing mass transfer technology cannot accurately and effectively move a large number of micro-LED units, which poses a bottleneck in the manufacturing process of micro-LED display devices.

On the other hand, the existing mass transfer technology uses a film made of polydimethylsiloxane (PDMS) (hereinafter referred to as the PDMS film) to transfer micro-LED units. However, there is currently no suitable method to ensure that a plurality of micro-LED units remain neat and non-skewed after detaching from the PDMS film, which poses a bottleneck in the manufacturing process of micro-LED display devices.

### SUMMARY

In view of this, the inventor proposes a pixel structure, which includes: a substrate, a plurality of vertical diode dies, a flip-chip diode die, and an upper circuit layer. The substrate has a lower circuit layer, which includes a plurality of first circuits and a second circuit. These first circuits have a first polarity, and the second circuit has a second polarity. The plurality of vertical diode dies are disposed on the substrate and are respectively coupled to these first circuits. The flip-chip diode die is disposed on the substrate and is coupled to one of the first circuits and the second circuit. The upper circuit layer is disposed on the plurality of vertical diode dies and the flip-chip diode die. The upper circuit layer includes a plurality of third circuits, which are respectively coupled to these vertical diode dies. These third circuits have the second polarity.

In some embodiments, the pixel structure further includes a plurality of blocking dams and a light-transmitting filling layer. The plurality of blocking dams define a plurality of accommodation sites. The plurality of vertical diode dies and the flip-chip diode die are respectively located within the plurality of accommodation sites. The light-transmitting filling layer covers the top of the flip-chip diode die, and the top surface of the light-transmitting filling layer is substantially coplanar with the top surfaces of these blocking dams.

In some embodiments, the plurality of vertical diode dies include at least one ineffective vertical diode die and at least one effective vertical diode die. The color category of the light beam corresponding to the flip-chip diode die is different from the color categories of the light beams respectively corresponding to the at least one effective vertical diode die.

In some embodiments, the pixel structure further includes a plurality of first light conversion material layers, which respectively cover the tops of the vertical diode dies.

In some embodiments, the pixel structure further includes a second light conversion material layer, which covers the top of the flip-chip diode die.

The inventor further proposes a panel structure, including: a substrate, a first pixel structure, a second pixel structure, and an upper circuit layer. The substrate has a lower circuit layer, and the lower circuit layer includes a plurality of first circuits and a plurality of second circuits. These first circuits have a first polarity, and these second circuits have a second polarity. The first pixel structure has a plurality of first accommodation sites, and the first pixel structure includes a plurality of first vertical diode dies and a flip-chip diode die. The plurality of first vertical diode dies are disposed on the substrate and are respectively located within these first accommodation sites, and are respectively coupled to these first circuits. The flip-chip diode die is disposed on the substrate and is located within one of the first accommodation sites, and is coupled to one of the first circuits and one of the second circuits. The second pixel structure has a plurality of second accommodation sites, and the second pixel structure includes a plurality of second vertical diode dies and a filling layer. The plurality of second vertical diode dies are disposed on the substrate and are respectively located within these second accommodation sites, and are respectively coupled to these first circuits. The filling layer is disposed on the substrate and is located within one of the second accommodation sites. The upper circuit layer is disposed on the first pixel structure and the second pixel structure. The upper circuit layer includes a plurality of third circuits, which are respectively coupled to these first vertical diode dies and these second vertical diode dies. These third circuits have the second polarity.

The inventor further proposes a repair method for a pixel structure, including: providing a substrate; forming a lower circuit layer on the substrate, wherein the lower circuit layer includes a first circuit and a second circuit, the first circuit has a first polarity, and the second circuit has a second polarity; disposing a vertical diode die on the substrate and connecting the vertical diode die to the first circuit; and determining whether the vertical diode die is effective to decide whether to dispose a flip-chip diode die on the substrate.

In some embodiments, the repair method for the pixel structure further includes disposing the flip-chip diode die on the substrate when it is determined that the vertical diode die is ineffective.

In some embodiments, the repair method for the pixel structure further includes: when it is determined that the vertical diode die is ineffective, disposing the flip-chip diode die on the substrate, wherein the flip-chip diode die is a short-wavelength light-emitting diode die; and coating a light conversion material layer on the flip-chip diode die.

In some embodiments, the repair method for the pixel structure further includes: forming a plurality of blocking dams on the substrate, wherein the plurality of blocking dams define a plurality of accommodation sites; disposing a plurality of the vertical diode dies on the substrate and respectively locating them within these accommodation sites; and when it is determined that all of these vertical diode dies are effective, disposing a filling layer within the remaining accommodation sites, wherein the remaining accommodation sites do not contain the vertical diode dies.

In some embodiments, the repair method for the pixel structure further includes forming an upper circuit layer on the plurality of vertical diode dies and the flip-chip diode die, wherein the upper circuit layer includes a third circuit that is coupled to the vertical diode die, and the third circuit has the second polarity.

The inventor further proposes a hybrid micro-LED structure, including: a substrate; a red micro-LED die disposed on the substrate; a green micro-LED die disposed on the substrate; a blue micro-LED die disposed on the substrate; a spare micro-LED die disposed on the substrate; an isolation layer disposed on the substrate, wherein the isolation layer surrounds the spare micro-LED die and forms an inkjet space with the spare micro-LED die, and the inkjet space is used to fill an inkjet material; a filling layer disposed on the substrate to fix the red micro-LED die, the green micro-LED die, the blue micro-LED die, the spare micro-LED die, and the isolation layer on the substrate; and a light-transmitting layer disposed on the filling layer; wherein any one of the red micro-LED die, the green micro-LED die, the blue micro-LED die, and the spare micro-LED die is adjacent to at least one of the remaining three.

In some embodiments, the spare micro-LED die is an ultraviolet micro-LED die, and the light-transmitting layer includes an anti-ultraviolet material.

In some embodiments, the spare micro-LED die is another blue micro-LED die.

In some embodiments, the spare micro-LED die is adjacent to the blue micro-LED die.

In some embodiments, the spare micro-LED die is further adjacent to the red micro-LED die or the green micro-LED die.

In some embodiments, the isolation layer includes an opaque material, wherein the opaque material surrounds the spare micro-LED die and the inkjet space.

In some embodiments, the isolation layer includes an opaque material and an isolation material, wherein the opaque material surrounds the inkjet space, and the isolation material surrounds the spare micro-LED die.

In some embodiments, when one of the red micro-LED die, the green micro-LED die, and the blue micro-LED die is damaged, the inkjet space is filled with an inkjet material corresponding to the color of the damaged one.

The inventor further proposes a repair method for a hybrid micro-LED structure, including: disposing a red micro-LED die, a green micro-LED die, a blue micro-LED die, and a spare micro-LED die on a substrate; disposing an isolation layer on the substrate to surround the spare micro-LED die, such that the isolation layer and the spare micro-LED die form an inkjet space; respectively lighting up the red micro-LED die, the green micro-LED die, and the blue micro-LED die to check whether any of them is damaged; and when one of the red micro-LED die, the green micro-LED die, and the blue micro-LED die is damaged, performing the following steps: filling an inkjet material corresponding to the color of the damaged one among the red micro-LED die, the green micro-LED die, and the blue micro-LED die into the inkjet space.

In some embodiments, the spare micro-LED die is selected from an ultraviolet micro-LED die or another blue micro-LED die.

In some embodiments, a method for repairing a hybrid micro-LED structure further includes: when none of the red micro-LED dies, green micro-LED dies, and blue micro-LED dies are damaged, performing the following steps: filling a filling material on the substrate to form a filling layer, wherein the filling layer is disposed on the substrate so that the red micro-LED dies, green micro-LED dies, blue micro-LED dies, spare micro-LED dies, and isolation layer are fixed on the substrate; and disposing a light-transmitting layer on the filling layer.

The inventor further proposes a panel structure, including: a first diode die and a second diode die. The first diode die includes a first electrode, and the first electrode has a first electrode thickness. The second diode die includes a second electrode, and the second electrode has a second electrode thickness. The first electrode thickness is greater than the second electrode thickness, and the die heights of the first diode die and the second diode die are substantially the same.

In some embodiments, the panel structure further includes a plurality of pixel structures, each including the first diode die and the second diode die. The first electrode thickness of the first electrode of the first diode die in each pixel structure is substantially the same, and the second electrode thickness of the second electrode of the second diode die in each pixel structure is substantially the same.

In some embodiments, the first diode die and the second diode die are respectively a vertical diode die, and the first electrode and the second electrode are respectively a bottom electrode of the vertical diode die.

In some embodiments, the bottom electrode has a trapezoidal structure, and the first electrode thickness and the second electrode thickness are the height of the trapezoidal structure.

In some embodiments, the panel structure further includes a third diode die, including a third electrode. The third electrode has a third electrode thickness. The third electrode thickness is greater than the second electrode thickness, and the first electrode thickness is greater than the third electrode thickness. The die heights of the first diode die, the second diode die, and the third diode die are substantially the same.

The inventor further proposes a manufacturing method for a diode die, including: providing a substrate; forming an epitaxial layer on the substrate; forming a bonding layer on the epitaxial layer; disposing a bottom electrode layer on the bonding layer; grinding the bottom electrode layer; and forming a top electrode layer under the epitaxial layer to form a first diode die.

In some embodiments, the method for manufacturing a diode die further includes: providing another substrate; forming another epitaxial layer on the other substrate; forming another bonding layer on the other epitaxial layer; disposing another bottom electrode layer on the other bonding layer; measuring a first height from the bottom of the substrate to the top of the bottom electrode layer; measuring a second height from the bottom of the other substrate to the top of the other bottom electrode layer; comparing the first height and the second height; and when it is determined that the first height is greater than the second height, grinding the bottom electrode layer until the first height drops to the second height.

In some embodiments, the method for manufacturing a diode die further includes, when it is determined that the second height is less than a lower limit height, not performing the step of grinding the bottom electrode layer until the first height drops to the second height.

In some embodiments, the method for manufacturing a diode die further includes: forming another top electrode layer under the other epitaxial layer to form a second diode die; and transferring the first diode die and the second diode die to the same panel structure.

In some embodiments, there are a plurality of first diode dies, there are a plurality of second diode dies, the panel structure includes a plurality of pixel structures, and each of the pixel structures respectively includes one of the first diode dies and one of the second diode dies.

The inventor further proposes a vertical micro-LED unit, which includes: a first backplane and a second backplane. The first backplane includes a first substrate, a first circuit layer, a first contact pad, and a transparent electrode layer. The first circuit layer is disposed on the first substrate. The first contact pad is disposed on the first circuit layer. The transparent electrode layer is disposed on the first circuit layer and the first contact pad. The second backplane includes a second substrate, a second circuit layer, a eutectic metal layer, an alloy layer, a micro-LED die, a second contact pad, and an isolation layer. The second circuit layer is disposed on the second substrate. The eutectic metal layer is disposed on the second circuit layer. The alloy layer is disposed on the eutectic metal layer. The micro-LED die is disposed on the alloy layer. The second contact pad is disposed on the micro-LED die. The isolation layer is disposed on the second substrate to surround the micro-LED die. The first backplane is disposed on the second backplane to form a cavity. The projected areas of the first contact pad and the second contact pad in the normal direction of the first backplane at least partially overlap, and the transparent electrode layer connects the second contact pad and the isolation layer. When the first backplane is disposed on the second backplane, the isolation layer deforms such that the thickness of the deformed isolation layer is equal to the sum of the thicknesses of the first contact pad, the second circuit layer, the eutectic metal layer, the alloy layer, the micro-LED die, and the second contact pad.

In some embodiments, the cavity is in a vacuum state.

In some embodiments, the cavity is filled with an inert gas.

In some embodiments, the isolation layer includes an opaque material.

In some embodiments, the isolation layer includes an opaque material and a light-transmissive material, wherein the opaque material surrounds the micro-LED die and the second contact pad, and the light-transmissive material surrounds the second circuit layer, the eutectic metal layer, and the alloy layer.

In some embodiments, the shape of the alloy layer is a trapezoid. The upper base of the trapezoid is connected to the eutectic metal layer, and the lower base of the trapezoid is connected to the micro-LED die.

The inventor further proposes a vertical micro-LED structure, which includes: a first micro-LED unit, a second micro-LED unit, and a third micro-LED unit. The first micro-LED unit includes the vertical micro-LED unit described in any of the foregoing embodiments, wherein the micro-LED die of the first micro-LED unit is a red micro-LED die. The second micro-LED unit includes the vertical micro-LED unit described in any of the foregoing embodiments, wherein the micro-LED die of the second micro-LED unit is a green micro-LED die. The third micro-LED unit includes the vertical micro-LED unit described in any of the foregoing embodiments, wherein the micro-LED die of the third micro-LED unit is a blue micro-LED die. Any one of the first micro-LED unit, the second micro-LED unit, and the third micro-LED unit is adjacent to at least one of the remaining two.

In some embodiments, the thickness of the first contact pad of the second micro-LED unit and the thickness of the first contact pad of the third micro-LED unit are greater than the thickness of the first contact pad of the first micro-LED unit.

The inventor further proposes a manufacturing method for a vertical micro-LED unit, which includes: forming a first backplane; forming a second backplane; and disposing the first backplane on the second backplane to form a cavity. The steps of forming the first backplane include: disposing a first circuit layer on a first substrate; disposing a first contact pad on the first circuit layer; and disposing a transparent electrode layer on the first circuit layer and the first contact pad. The steps of forming the second backplane include: disposing a second circuit layer on a second substrate; disposing a micro-LED die on the second circuit layer; disposing a second contact pad on the micro-LED die; and disposing an isolation layer on the second substrate to surround the micro-LED die. The projected areas of the first contact pad and the second contact pad in the normal direction of the first backplane at least partially overlap, and the transparent electrode layer is connected to the second contact pad and the isolation layer.

The inventor further proposes a manufacturing method for a vertical micro-LED structure, including: forming a first backplane; forming a second backplane; and arranging the first backplane on the second backplane to form a plurality of cavities. The steps of forming the first backplane include: arranging a plurality of first circuit layers on a first substrate; arranging a plurality of first contact pads on the corresponding first circuit layers; and arranging a plurality of transparent electrode layers on the corresponding first circuit layers and first contact pads. The steps of forming the second backplane include: arranging a plurality of second circuit layers on a second substrate; arranging a red micro-LED die, a green micro-LED die, and a blue micro-LED die on the corresponding second circuit layers; arranging a plurality of second contact pads corresponding to the plurality of first contact pads on the red micro-LED die, the green micro-LED die, and the blue micro-LED die respectively; and arranging an isolation layer on the second substrate to surround the red micro-LED die, the green micro-LED die, and the blue micro-LED die. The projected areas of each first contact pad and the corresponding second contact pad in the normal direction of the first backplane at least partially overlap, and each transparent electrode layer is connected to the corresponding second contact pad and the isolation layer.

The inventor further proposes a pre-alignment device adapted for a plurality of micro-LED units, including: a vibrating machine, an alignment tray, a plurality of electromagnets, and a controller. The vibrating machine includes a plurality of side walls and a base plate, and the plurality of side walls are disposed around the base plate. The alignment tray is disposed on the base plate and includes a plurality of grooves disposed in an array. Each groove is used to accommodate each micro-LED unit, and the bottom of each groove includes a through hole. Each electromagnet is disposed in each through hole, and each electromagnet is used to generate a magnetic field along the extension direction of the through hole. The controller is electrically connected to the vibrating machine and the plurality of electromagnets and is used to control each electromagnet to generate a magnetic field. The thickness of the alignment tray is less than the height of each side wall.

In some embodiments, the shape of each groove is trapezoidal, and the width of the bottom of each groove is less than the width of the top surface of each groove.

In some embodiments, the shape of each groove is rectangular.

The inventor further proposes a pre-alignment method adapted for a plurality of micro-LED units, which includes: placing a plurality of micro-LED units on an alignment tray, wherein the alignment tray includes a plurality of grooves, and the bottom of each groove includes a through hole; generating an attractive force along the extension direction of the through hole; and generating a vibration force to cause the alignment tray to vibrate, wherein each micro-LED unit vibrates accordingly and moves into each groove; wherein, in response to the attractive force being greater than the vibration force, each micro-LED unit is fixed in each groove; in response to the attractive force being less than the vibration force, each micro-LED unit is detached from each groove.

In some embodiments, the attractive force is a magnetic attractive force.

In some embodiments, each micro-LED unit includes a micro-LED die, a carrier layer, and a magnetic conductive layer, wherein the carrier layer is disposed on the magnetic conductive layer, and the micro-LED die is disposed on the carrier layer; wherein, the height of each micro-LED unit is greater than the depth of each groove.

In some embodiments, the shape of the carrier layer and the shape of the magnetic conductive layer are both trapezoidal, and the width of the bottom of the magnetic conductive layer is smaller than the width of the bottom of each groove.

In some embodiments, the material of the carrier layer has electrical conductivity and non-magnetic conductivity.

In some embodiments, the pre-alignment method further includes: in response to each micro-LED unit being fixed in each groove, stopping generating the vibration force; and stopping generating the attractive force.

In some embodiments, the attractive force is a vacuum suction force.

The inventor further proposes an alignment device adapted for a plurality of micro-LED units, which includes a support tray and an alignment tray. The support tray includes a plurality of grooves. Each groove extends along a first direction, a plurality of grooves are disposed at intervals along a second direction, and the first direction is orthogonal to the second direction. The alignment tray is disposed on the support tray. The alignment tray includes a plurality of columns, and a plurality of columns are disposed at intervals along the second direction, and each column is respectively aligned with each groove. Each column is provided with a plurality of grooves, the bottom of each groove includes a through hole, and a plurality of grooves in each column are disposed at intervals along the first direction.

In some embodiments, the alignment device further includes: a vacuum machine coupled to the plurality of grooves; and a controller electrically connected to the vacuum machine for controlling the vacuum machine.

In some embodiments, the alignment tray includes a conductive film, and the conductive film is disposed on the wall surface of each groove.

In some embodiments, the alignment device further includes: a tilting mechanism, which is disposed on the lower surface of the support tray and electrically connected to the controller; wherein the controller is further configured to control the tilting mechanism.

In some embodiments, the alignment device further includes: a vibrating machine, which is disposed on the lower surface of the support tray and electrically connected to the controller; wherein the controller is further configured to control the vibrating machine.

The inventor further proposes an alignment method adapted for a plurality of micro-LED units, including: moving a plurality of pre-aligned micro-LED units disposed on a carrier board vertically above an alignment tray, wherein the alignment tray includes a plurality of grooves, the bottom of each groove includes a through hole, and each micro-LED unit is respectively aligned with each groove; and generating an attractive force along the extending direction of the through hole to attract each micro-LED unit from the carrier board to the bottom of each groove.

In some embodiments, the attractive force is a vacuum suction force.

In some embodiments, the alignment method further includes: stopping generating the attractive force; disposing a transparent cover plate on the alignment tray, wherein a conductive film is formed on the lower surface of the transparent cover plate, and a conductive film is also formed on the wall surface of each groove of the alignment tray; and energizing the plurality of micro-LED units through the conductive film of the transparent cover plate and the conductive film of the alignment tray.

In some embodiments, the alignment method further includes: removing the transparent cover plate; and removing the damaged plurality of micro-LED units.

In some embodiments, the alignment method further includes: stopping generating the attractive force; and tilting the alignment tray so that each micro-LED unit is aligned with one wall surface of each groove.

In some embodiments, the alignment method further includes: stopping generating the attractive force; and generating a vibration force to make the alignment tray vibrate; wherein, in response to the vibration of the alignment tray, each micro-LED unit is aligned with one wall surface of each groove.

### BRIEF DESCRIPTION OF DRAWINGS

FIG. 1 is a cross-sectional view of a pixel structure according to some embodiments.

FIG. 2A is a schematic diagram of the layered structure of a vertical diode die according to some embodiments.

FIG. 2B is a schematic diagram of the layered structure of a flip-chip diode die according to some embodiments.

FIG. 3A is a schematic diagram of the configuration of a vertical diode die according to some embodiments.

FIG. 3B is a schematic diagram of the configuration of a flip-chip diode die according to some embodiments.

FIGS. 4A-4D are top views of pixel structures according to different embodiments.

FIG. 5 is a top view of the panel structure according to some embodiments.

FIG. 6 is a flowchart of the method for repairing a pixel structure according to the first embodiment.

FIGS. 7A-7H are schematic diagrams of the manufacturing process of the method for repairing a pixel structure according to the first embodiment.

FIG. 8 is a flowchart of the method for repairing a pixel structure according to the second embodiment.

FIGS. 9A-9C are schematic diagrams of the manufacturing process of the method for repairing a pixel structure according to the second embodiment.

FIG. 10 is a flowchart of the method for repairing a pixel structure according to the third embodiment.

FIG. 11 is a schematic diagram of the manufacturing process of the method for repairing a pixel structure according to the third embodiment.

FIG. 12 is a top-plan view of the hybrid micro-LED structure according to the fourth embodiment.

FIG. 13 is a cross-sectional schematic diagram of the hybrid micro-LED structure in FIG. 12 along the section line 2-2.

FIG. 14 is a top-plan view of the hybrid micro-LED structure according to the fifth embodiment.

FIG. 15 is a flowchart showing the operation of an embodiment of the hybrid micro-LED structure in FIG. 12.

FIG. 16 is a flowchart showing the operation of an embodiment following step S42 in FIG. 15.

FIG. 17 is a schematic cross-sectional view of the hybrid micro-LED structure in FIG. 12 along section line 2-2.

FIG. 18 is a schematic diagram of a plurality of diode dies with different die heights according to some embodiments.

FIG. 19 is a flowchart of a method for manufacturing a diode die according to some embodiments.

FIGS. 20A to 20K are schematic diagrams of a method for manufacturing a diode die according to some embodiments.

FIG. 21 is a schematic diagram of a diode die according to some embodiments.

FIG. 22 is a schematic diagram comparing the heights of a plurality of semi-finished substrates according to some embodiments.

FIG. 23 is a flowchart of a method for manufacturing a diode die according to other embodiments.

FIGS. 24A to 24B are schematic diagrams of a method for manufacturing a diode die according to other embodiments.

FIG. 25 is a schematic diagram of a panel structure according to some embodiments.

FIG. 26 is a side plan view of a vertical micro-LED unit according to the sixth embodiment.

FIG. 27 is a side plan view of an embodiment of the first backplane in FIG. 26.

FIG. 28 is a side plan view of an embodiment of the second backplane in FIG. 26.

FIG. 29 is a partial exploded view of the vertical micro-LED unit in FIG. 26.

FIG. 30 is a top plan view of an embodiment of the first backplane in FIG. 26.

FIG. 31 is a top plan view of an embodiment of the second backplane in FIG. 26.

FIG. 32 is an operational flowchart of an embodiment of the vertical micro-LED unit in FIG. 26.

FIG. 33 is a side plan view of the vertical micro-LED unit according to the seventh embodiment.

FIG. 34 is a side plan view of the vertical micro-LED structure according to some embodiments.

FIG. 35 is a side plan view of an embodiment of the first backplane in FIG. 34.

FIG. 36 is a side plan view of an embodiment of the second backplane in FIG. 34.

FIG. 37 is a partial exploded view of the vertical micro-LED unit in FIG. 34.

FIG. 38 is a top plan view of an embodiment of the first backplane in FIG. 34.

FIG. 39 is a top plan view of an embodiment of the second backplane in FIG. 34.

FIG. 40 is an operational flowchart of an embodiment of the vertical micro-LED structure in FIG. 34.

FIG. 41 is a side schematic view of the pre-alignment device according to the eighth embodiment.

FIG. 42 is a top schematic view of the pre-alignment device in FIG. 41.

FIG. 43 is an operational flowchart of the pre-alignment device according to some embodiments.

FIG. 44 is an operational schematic view of the pre-alignment device in FIG. 41.

FIG. 45 is a partially enlarged view of the pre-alignment device according to the eighth embodiment in FIG. 44.

FIG. 46 is a partially enlarged view of the pre-alignment device according to the ninth embodiment in FIG. 44.

FIG. 47 is a side schematic view of the pre-alignment device according to the ninth embodiment.

FIG. 48 is a schematic side view of the alignment device according to the tenth embodiment.

FIG. 49 is a schematic top view of an embodiment of the support tray in FIG. 48.

FIG. 50 is a schematic top view of an embodiment of the alignment tray in FIG. 48.

FIG. 51 is an operational flowchart of an embodiment of the alignment device in FIG. 48.

FIG. 52 is a schematic diagram of the first exemplary state of the alignment device in FIG. 48.

FIG. 53 is a schematic diagram of the first exemplary state of the alignment device in FIG. 48.

FIG. 54 is an operational flowchart following step S11 in FIG. 51.

FIG. 55 is a schematic side view of the alignment device according to the eleventh embodiment.

FIG. 56 is a schematic diagram of the first exemplary state of the alignment device in FIG. 55.

FIG. 57 is a schematic diagram of the second exemplary state of the alignment device in FIG. 55.

FIG. 58 is an operational flowchart following step S11 in FIG. 51.

FIG. 59 is a modular block diagram of the alignment device according to the twelfth embodiment.

FIG. 60 is a schematic side view of the alignment device in FIG. 48.

FIG. 61 is an operational flowchart following step S11 in FIG. 51.

FIG. 62 is a modular block diagram of the alignment device according to the thirteenth embodiment.

FIG. 63 is a schematic side view of the alignment device in FIG. 62.

### DESCRIPTION OF EMBODIMENTS

In order to make the purposes, means, and effects of the technical means disclosed in different embodiments of the present disclosure more understandable, the following description will elaborate on the specific embodiments of the proposed technical means in conjunction with the drawings. The descriptions of the technical means recorded in the following embodiments of the present disclosure are merely illustrative for the purpose of explanation and do not represent all the embodiments of the present disclosure or limit the present disclosure to specific embodiments. Based on the different embodiments in the present disclosure, all other embodiments obtained by those with ordinary knowledge in the technical field without excessive experimentation shall fall within the scope of protection intended by the present disclosure. Unless otherwise defined, all technical and specialized terms used in the present disclosure have the same meanings as commonly understood by those with ordinary knowledge in the technical field to which the present disclosure belongs. The terms used in the present disclosure are only for the purpose of describing specific embodiments and are not intended to limit the present disclosure.

It should be noted that when an element is referred to as being “disposed on” another element, it can be directly on the other element and make “direct” physical or electrical contact with each other; or it can also include elements existing between the two and make “indirect” physical or electrical contact with each other. When an element is considered to be “connected”, “coupled”, “disposed”, or “electrically connected” to another element, it can be that two or more elements make “direct” physical or electrical contact with each other, or make “indirect” physical or electrical contact with each other.

In all descriptions related to specific numerical values in the present disclosure, although not directly described, they all contain the meaning of “approximately” or “substantially”. That is, these specific numerical values will cover the possible range of numerical errors, so as to represent the error range implied by possible unexpected impacts and deviations in the process or material selection. The said error range can include the range of changes that do not significantly change the material, structure, configuration, characteristics, and effects, such as a deviation range of 0%-10%, and the said error range is clear to those with ordinary knowledge in this technical field. For example, when it is described that “two objects are substantially parallel”, in fact, if it is observed that there is a slight height difference between the two objects, but this difference is negligible relative to the size of the objects themselves (for example, less than 10%) and does not affect the effect, the relative configuration between the two observed objects will still be interpreted as being within the scope of “substantially parallel” described in the present disclosure.

The terms “vertical”, “horizontal”, “left”, “right”, “up”, “down”, “inside”, “outside”, “front”, “back” and similar expressions used in the present disclosure are only used to indicate the relative positional relationship based on the drawings, and do not limit that the elements using these terms can only be implemented in the indicated manner. When the absolute position of the described object changes, the description of the relative position may also change accordingly.

The term “column” used in this disclosure is not limited to a plurality of units disposed sequentially “from left to right” or “from right to left” in the diagram. A plurality of units disposed sequentially “from top to bottom” and “from bottom to top” in the diagram can also be referred to as “columns”. The “trapezoid” mentioned in this disclosure refers to a shape where the width of the upper base is smaller than that of the lower base, but this is not intended to limit the form of the “trapezoid”. In other words, a “trapezoid” with the width of the upper base greater than that of the lower base is still within the scope of the patent application in this case.

The terms “a/an” or “one” used in this disclosure are used to describe the elements and components of this creation. This term is only for the convenience of description and to give the basic concept of this creation. This description should be understood as including one or at least one, and unless clearly indicated otherwise, the singular also includes the plural. The term “comprising” is an open-ended term and should be interpreted as “including but not limited to”. The term “and/or” used in this disclosure includes any and all combinations of one or more of the associated listed items.

The terms “a/an”, “another”, “first”, “second”, “third” and other terms used in this disclosure are used to distinguish the referred elements. Unless specifically indicated, they are not used for sorting or limiting the differences of the referred elements, nor are they used to limit the scope of this case.

FIG. 1 is a cross-sectional view of a pixel structure according to some embodiments. Please refer to FIG. 1. In this embodiment, the pixel structure 50 includes a substrate 500, a plurality of vertical diode dies 520, a flip-chip diode die 530, and an upper circuit layer 540. The plurality of vertical diode dies 520 and the flip-chip diode die 530 are disposed on the substrate 500, and the upper circuit layer 540 is disposed on the plurality of vertical diode dies 520 and the flip-chip diode die 530. The term “on” can be, but is not limited to, “directly on”. For example, the upper circuit layer 540 in FIG. 1 has a third circuit 541. The third circuit 541 can be connected only to the upper electrode 542 directly above the vertical diode die 520 through a thin strip-shaped finger-shaped electrode structure. Meanwhile, the third circuit 541 does not pass directly on the flip-chip diode die 530. A lower circuit layer 510 can be disposed on the substrate 500. The lower circuit layer 510 includes a first circuit 511 and a second circuit 512. Part of the first circuit 511 is connected to the lower electrode 513 of the vertical diode die 520. One of the first circuits 511 is connected to the lower electrode 513 of the flip-chip diode die 530, and the second circuit 512 is connected to another lower electrode 513 of the flip-chip diode die 530. It should be understood that the layout of the lower circuit layer 510 shown in FIG. 1 is only an example for easy understanding and does not limit the lower circuit layer 510 to be inside the substrate 500. The lower circuit layer 510 can also be disposed on the surface of the substrate 500. In other words, the substrate 500 can be a single-sided, double-sided, or multi-layer circuit board.

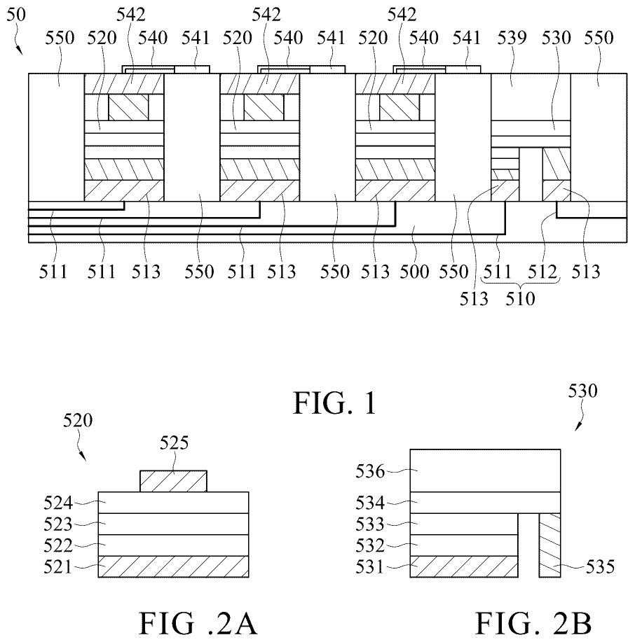

The main difference between the first circuit 511 and the second circuit 512 lies in their polarities. Here, the first circuit 511 has the first polarity, and the second circuit 512 has the second polarity. In addition, the third circuit 541 also has the second polarity. The polarities of the first polarity and the second polarity are opposite. That is, when the first polarity is the P pole, the second polarity is the N pole; when the first polarity is the N pole, the second polarity is the P pole. FIG. 2A is a schematic diagram of the layered structure of a vertical diode die according to some embodiments; FIG. 2B is a schematic diagram of the layered structure of a flip-chip diode die according to some embodiments. Please refer to FIG. 1, FIG. 2A, and FIG. 2B together.

As shown in FIG. 2A, the layered structure of the vertical diode die 520 can be roughly divided into a first electrode 521, a first doped layer 522, a first quantum well 523, a second doped layer 524, and a second electrode 525. The polarities of the first electrode 521 and the second electrode 525 are opposite. The electrodes can be made of conductive materials, such as metals. The polarities of the first doped layer 522 and the second doped layer 524 are opposite. The doped layers can be P-type or N-type doped layers. The doped elements of the doped layers are selected according to the valence electrons of the laminate materials to form P-type or N-type doped layers. For example, if the laminate material of the doped layer is gallium nitride (GaN), the dopant of the P-doped layer can be magnesium (Mg) from Group 2, and the dopant of the N-type doped layer can be silicon (Si) from Group 5. The quantum well is used to restrict the movement of carriers to form a quantum confinement effect, thereby improving the luminous efficiency of the diode die. The first electrode 521 is used to connect to the first circuit 511 and has the first polarity, while the second electrode 525 is used to connect to the third circuit 541 and has the second polarity. The first electrode 521 and the second electrode 525 are disposed vertically. The current (electron flow) of the first circuit 511 flows through the vertical diode die 520 to the third circuit 541.

As shown in FIG. 2B, the layered structure of the flip-chip diode die 530 can be roughly divided into a third electrode 531, a third doped layer 532, a second quantum well 533, a fourth doped layer 534, a fourth electrode 535, and a substrate layer 536. The polarities of the third electrode 531 and the fourth electrode 535 are opposite, and the polarities of the third doped layer 532 and the fourth doped layer 534 are opposite. The substrate layer 536 is the substrate layer used to support the layered structure during the die manufacturing process, such as the sapphire substrate 500. In some other embodiments, the flip-chip diode die 530 may not have the substrate layer 536. The third electrode 531 is used to connect to the first circuit 511 and has the first polarity, while the fourth electrode 535 is used to connect to the second circuit 512 and has the second polarity. The third electrode 531 and the fourth electrode 535 are disposed horizontally. The current (electron flow) of the first circuit 511 flows through the flip-chip diode die 530 to the second circuit 512.

Referring to FIG. 1, in some embodiments, the vertical diode dies 520 have color categories, and the color categories of a plurality of vertical diode dies 520 included in the same pixel structure 50 are different. For example, as shown in FIG. 1, this embodiment includes three vertical diode dies 520, which have red, green, and blue colors respectively. The color categories can be defined according to the main wavelength of the emitted light of the diode dies, or according to the original nominal specifications of the diode dies. The flip-chip diode dies 530 also have color categories. In this embodiment, the flip-chip diode dies 530 can be red, green, or blue. It should be understood that the color categories of the vertical diode dies 520 and the flip-chip diode dies 530 are not limited to red, green, and blue. In addition, in other embodiments, the vertical diode dies 520 and/or the flip-chip diode dies 530 themselves do not have color categories, but the light beams corresponding to the vertical diode dies 520 or the flip-chip diode dies 530 have color categories, which will be described in detail later.

In some embodiments, the pixel structure 50 includes a substrate 500, a plurality of vertical diode dies 520, a flip-chip diode die 530, an upper circuit layer 540, a plurality of first blocking dams 550, and a second filling layer 539. As shown in FIG. 1, the pixel structure 50 includes the first blocking dam 550. The first blocking dam 550 defines a total of four accommodation sites. The vertical diode die 520 and the flip-chip diode die 530 are respectively located within the accommodation sites. In addition, the third circuit 541 is mainly disposed directly on the first blocking dam 550. The first blocking dam 550 can be used to prevent the light emitted by the diode dies from interfering with the adjacent diode dies. Therefore, in this embodiment, the first blocking dam 550 surrounds the diode dies with an opaque material. In some embodiments, the opaque material can be a black matrix (BM) material or a material with light reflectivity, such as but not limited to bauxite, dielectric multilayer films, and reflective resin materials. The second filling layer 539 covers the flip-chip diode die 530, and the top surface of the second filling layer 539 is substantially coplanar with the top surface of the first blocking dam 550. The second filling layer 539 can be a light-transmissive material to allow the light emitted by the flip-chip diode die 530 to penetrate the second filling layer 539. The light-transmissive material can be but is not limited to silicone, epoxy resin, polyimide, benzocyclobutene, perfluorocyclobutane, SU8 photoresist, acrylic resin, polyethylene terephthalate, and polyetherimide.

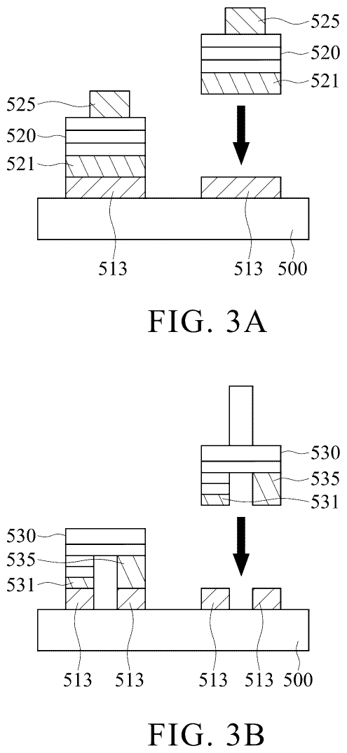

FIG. 3A is a schematic diagram of the configuration of a vertical diode die according to some embodiments; FIG. 3B is a schematic diagram of the configuration of a flip-chip diode die according to some embodiments. Please refer to both FIG. 3A and FIG. 3B. When the vertical diode die 520 is disposed on the substrate 500, the first electrode 521 of the vertical diode die 520 is connected to the lower electrode 513 on the surface of the substrate 500, while the second electrode 525 of the vertical diode die 520 is not yet connected to the circuit, thus forming an open-circuit state. In contrast, when the flip-chip diode die 530 is disposed on the substrate 500, the third electrode 531 and the fourth electrode 535 of the flip-chip diode die 530 are respectively connected to the lower electrode 513 on the surface of the substrate 500, thus forming a conducting state. Therefore, the flip-chip diode die 530 can be tested immediately after being transferred to the substrate 500 to confirm whether there are any defects in the diode die itself; or whether there are any defects in the connection state between the diode die and the substrate 500. However, the vertical diode die 520 can only be tested for the die and its connection state after the formation step of the upper circuit layer 540 at the end of the packaging process is completed. This makes it difficult to replace the vertical diode die 520 in the pixel structure 50 after most of the packaging process is completed.

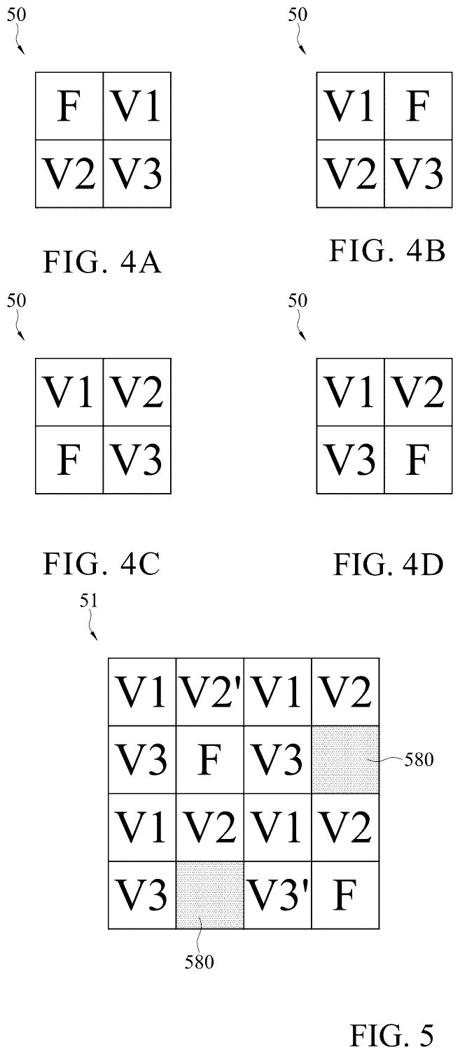

FIGS. 4A-4D are top views of the pixel structure according to different embodiments. Please refer to FIGS. 4A-4D together. In this embodiment, the pixel structure 50 includes a vertical diode die V1, a vertical diode die V2, a vertical diode die V3, and a flip-chip diode die F. The arrangement relationship between the flip-chip diode die F and the other vertical diode dies V1, V2, V3 can be arbitrarily combined. In some embodiments, all the pixel structures 50 included in the same panel structure 51 have the same arrangement relationship, for example, the pixel structures 50 in FIG. 4A are periodically configured. In other embodiments, the same panel structure 51 can include pixel structures 50 with a plurality of arrangement relationships, for example, the pixel structures 50 in FIG. 4A and FIG. 4B are alternately and periodically configured. Each pixel structure 50 includes four accommodation sites. As shown in FIG. 4A, the accommodation site in the upper left corner corresponds to the flip-chip diode die F. In some embodiments, the first circuit 511 of the substrate 500 forms the lower electrode 513 at each accommodation site, while the second circuit 512 forms the lower electrode 513 only at the accommodation site corresponding to the flip-chip diode die F.

There may be effective vertical diode dies 520 and ineffective vertical diode dies 520 among the vertical diode dies V1, V2, and V3. In some embodiments, an effective vertical diode die 520 means that there are no defects in the diode die itself or in the connection state between the diode die and the substrate 500. An ineffective vertical diode die 520 means that there are defects in the diode die itself or in the connection state between the diode die and the substrate 500. The defects are defined according to the yield standard of the manufacturing process. For example, the light beam intensity threshold of a specific wavelength is used as the defect judgment standard. In other embodiments, an effective vertical diode die 520 means that there are no defects in the light-emitting effect produced by the diode die and its attachments. An ineffective vertical diode die 520 means that there are defects in the light-emitting effect produced by the diode die and its attachments, which will be described in detail later.

FIG. 5 is a top view of a panel structure according to some embodiments. Please refer to FIG. 5. In this embodiment, the pixel structures 50 in FIG. 4D are periodically disposed to form a panel structure 51. This embodiment only shows four groups of pixel structures 50 included in the panel structure 51. Among them, the pixel structure 50 in the upper left of FIG. 5 includes an ineffective vertical diode die V2′, and the pixel structure 50 in the lower right of FIG. 5 includes an ineffective vertical diode die V3′. These pixel structures 50 are defined as the first pixel structures 50. The vertical diode dies 520 included in the pixel structures 50 in the upper right and lower left of FIG. 5 are all effective vertical diode dies 520. These pixel structures 50 are defined as the second pixel structures 50. In this embodiment, the flip-chip diode dies F can be used to replace the ineffective vertical diode dies V2′ and V3′. In detail, in this embodiment, the pixel structure 50 includes vertical diode dies 520 of various different color categories. When the vertical diode die 520 of any color category is ineffective, it will cause the pixel structure 50 to be unable to produce the light beam of the color category, thus forming a defect. And, as mentioned above, the replacement process of the vertical diode die 520 is relatively complex. In this embodiment, the flip-chip diode dies F are arranged in the pixel structure 50 with ineffective vertical diode dies V2′ and V3′ to produce the light beam of the color category. In this way, a specific type of flip-chip diode die F can be selected and directly disposed at the preset accommodation site to replace the ineffective vertical diode dies V2′ and V3′. In addition, the installed flip-chip diode dies F can be immediately detected to ensure that there are no defects.

In some embodiments, the color category of the flip-chip diode die F is the same as that of the ineffective vertical diode dies V2′ and V3′. Thus, the light beam generated by the flip-chip diode die F can cover the spectral range that the ineffective vertical diode dies V2′ and V3′ were originally expected to cover. In some embodiments, a specific pixel structure 50 includes ineffective vertical diode dies V2′ and V3′, and the color category of the flip-chip diode die F is different from that of the effective vertical diodes included in the specific pixel structure 50. Thus, the light beam generated by the flip-chip diode die F can cover the part of the spectral range that the light beam generated by the specific pixel structure 50 cannot cover. In some embodiments, the accommodation site corresponding to the flip-chip diode die F in the second pixel structure 50 is filled with a third filling layer 580. The third filling layer 580 can be used to seal the lower electrode 513 of the substrate 500 at the accommodation site, and it can be made of the light-transmissive material or opaque material described in this disclosure. In some embodiments, the third filling layer 580 can also be made of the same material as the first blocking dam 550 or the second filling layer 539. In this embodiment, the panel structure 51 includes both the first pixel structure 50 and the second pixel structure 50. In other words, each pixel structure 50 on the panel structure 51 does not necessarily include the flip-chip diode die F, and each pixel structure 50 on the panel structure 51 does not necessarily include the third filling layer 580. In addition, the panel structure 51 can include the ineffective vertical diode dies V2′ and V3, or they can be removed.

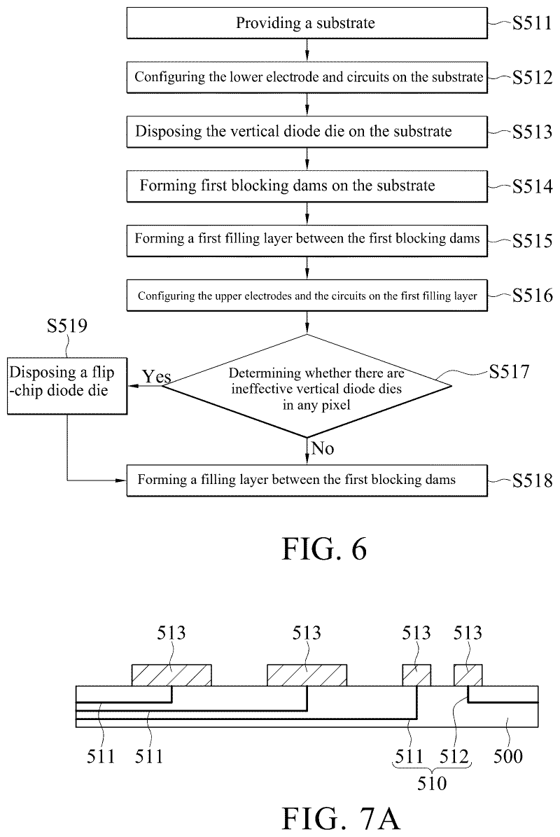

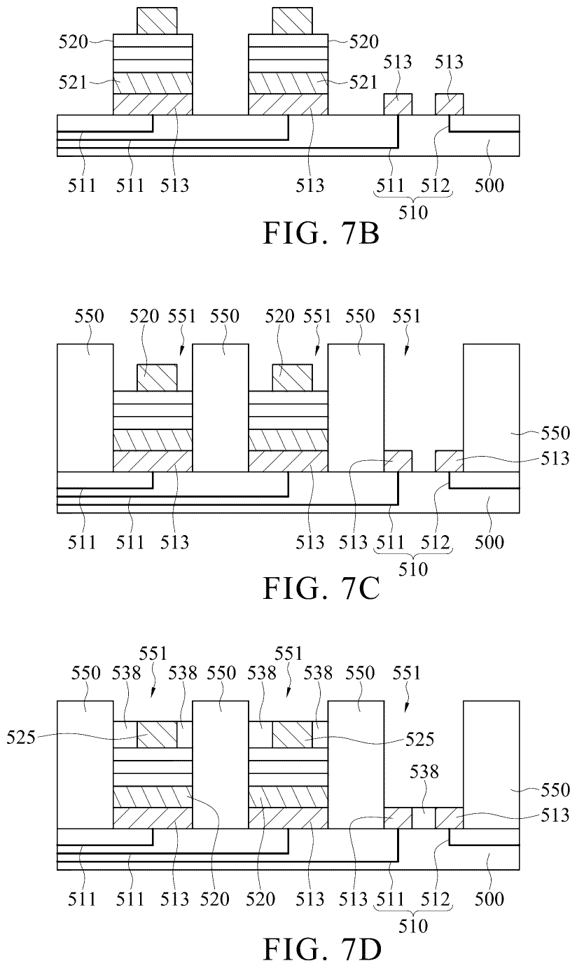

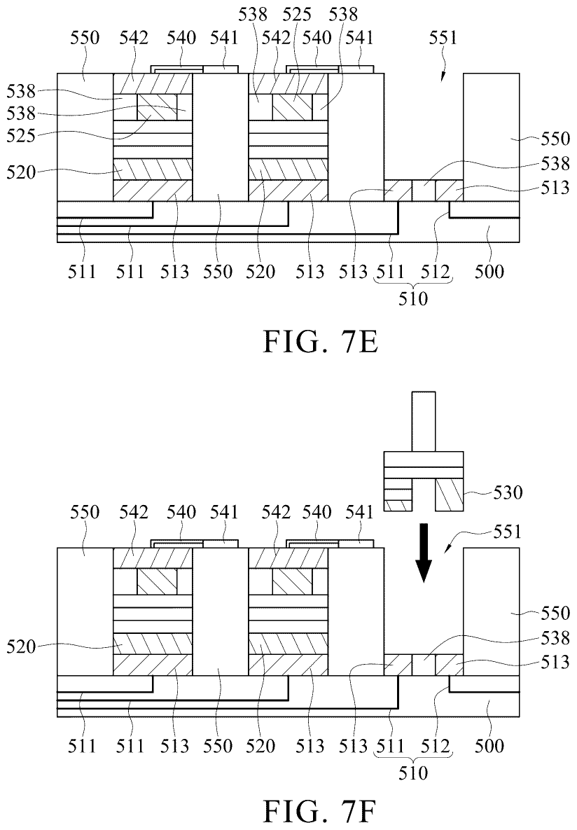

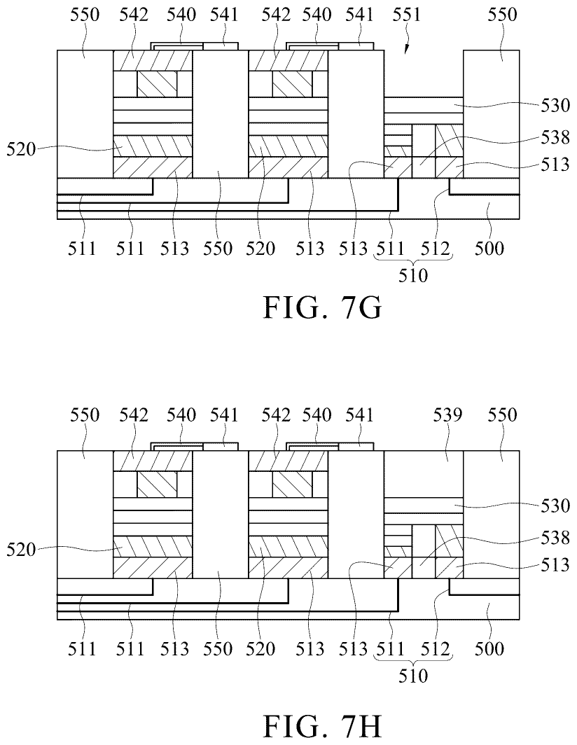

FIG. 6 is a flowchart of a method for repairing a pixel structure according to the first embodiment; FIGS. 7A-7H are schematic process diagrams of the method for repairing a pixel structure according to the first embodiment. Please refer to FIGS. 7A-7H in sequence according to the steps in FIG. 6. In some embodiments, the method for repairing the pixel structure 50 (hereinafter referred to as the “repair method”) can be used to repair pixels containing ineffective vertical diode dies V2′ and V3′ to produce the pixel structure 50. The repair method is described below according to different embodiments. It should be understood that although the flowcharts in this disclosure are presented in a specific order, the order is only an example, and implementations in other different orders can be expected.

Please refer to FIG. 7A. The repair method involves providing a substrate 500 (step S511) and configuring the lower electrode 513 and circuits on the substrate 500 (step S512). In this embodiment, a first circuit 511 and a second circuit 512 are provided on the substrate 500 and are respectively connected to the lower electrode 513. The lower electrode 513 is provided at a specific position on the substrate 500, which is equivalent to an accommodation site. Among them, there is a pair of lower electrodes 513 within the specific accommodation site, which are suitable for connecting the flip-chip diode die 530. The circuits respectively connected to this pair of lower electrodes 513 are the first circuit 511 and the second circuit 512. The material of the substrate 500 can be, but is not limited to, silicon (Si), silicon dioxide (SiO₂), gallium arsenide (GaAs), silicon carbide (SiC), glass, silicone, epoxy resin, polyimide (PI), benzocyclobutene (BCB), perfluorocyclobutane (PFCB), SU8 photoresist, acrylic resin, polyethylene terephthalate (PET), and polyetherimide. The lower electrode 513 and the circuits are made of conductive materials, such as metals, and the forming methods can be, but are not limited to, coating, electroplating, chemical vapor deposition (CVD), physical vapor deposition (PVD), area-selective deposition (ASD), and atomic layer deposition (ALD).

Please refer to FIG. 7B. The repair method involves disposing the vertical diode die 520 on the substrate 500 (step S513). The vertical diode die 520 is disposed on the substrate 500, and its first electrode 521 can be electrically connected to the lower electrode 513 of the lower circuit layer 510 through welding. Referring to FIG. 7C again, the repair method involves forming first blocking dams 550 on the substrate 500 (step S514). The first blocking dam 550 can be formed on the surface of the substrate 500 or attached to the surface of the substrate 500 after being formed. The first blocking dam 550 forms accommodation sites 551 around the positions of each lower electrode 513. In FIG. 7C, two accommodation sites 551 contain the vertical diode die 520, and one accommodation site 551 is an empty space. The surface of the substrate 500 at the bottom of the empty space has a lower electrode 513 connected to different circuits.

Please refer to FIG. 7D. The repair method involves forming a first filling layer 538 between the first blocking dams 550 (Step S515). The first filling layer 538 is used to cover and protect the vertical diode dies 520, leaving only a part of the second electrode 525 exposed. In addition, the first filling layer 538 can also be used to cover and protect the lower electrodes 513 within the vacancies, leaving only a part of the lower electrodes 513 exposed. The first filling layer 538 can be made of the light-transmissive material or opaque material described in this disclosure, and the materials used for different accommodation sites 551 can be different. For example, the first filling layer 538 formed by the light-transmissive material can cover the vertical diode dies 520, while the first filling layer 538 formed by the opaque material can cover the vacancies.

Please refer to FIG. 7E. The repair method involves configuring the upper electrodes 542 and the circuits on the first filling layer 538 (Step S516). In this embodiment, the upper electrodes 542 are disposed on the vertical diode dies 520 and are electrically connected to the second electrodes 525 of the vertical diode dies 520. The upper circuit layer 540 is disposed on the upper electrodes 542 and the first blocking dams 550 to form the third circuits 541. The third circuits 541 mainly pass directly on the first blocking dams 550 and extend to the surface of the upper electrodes 542 through the strip-shaped structures. The upper electrodes 542 are made of light-transmissive conductive materials, such as but not limited to Indium Tin Oxide (ITO), zinc oxide (ZnO), Fluorine-doped Tin Oxide (FTO), graphene, and poly(3,4-ethylenedioxythiophene)-polystyrene sulfonate (PEDOT:PSS). The upper circuits are made of conductive materials and can be formed on the upper electrodes 542 and the first blocking dams 550 by the circuit manufacturing process described in this disclosure.

In step S517, the repair method involves determining whether there are ineffective vertical diode dies V2′ and V3′ in each pixel. For example, the repair method provides a power supply, electrically connects the first circuit 511 to the first polarity of the power supply, and electrically connects the third circuit 541 to the second polarity of the power supply, so that current passes through each vertical diode. Then, the repair method uses a camera to photograph each pixel structure 50 to determine whether the pixel structure 50 fails to generate a light beam of a specific color category, or the intensity of the light beam at a specific accommodation site 551 does not reach the intensity threshold, so as to determine whether each vertical diode die 520 in the pixel structure 50 is effective. When the repair method determines that there are no ineffective vertical diode dies V2′ and V3′ in each pixel (in step S517, the determination result is “No”), a filling layer is formed between the first blocking dams 550 (step S518). For example, a third filling layer 580 is formed in the empty space. In some embodiments, the third filling layer 580 fills the accommodation site 551 until the top surface of the third filling layer 580 is substantially coplanar with the top surface of the first blocking dam 550.

When the repair method determines that there are ineffective vertical diode dies V2′ and V3′ in any pixel (in step S517, the determination result is “Yes”), a flip-chip diode die 530 is disposed (step S519). In other embodiments, between step S517 and step S519, the repair method further includes determining whether the number of ineffective vertical diode dies V2′ and V3′ is greater than a quantity threshold (not shown in the figure). The quantity threshold may refer to the defect acceptance standard of the panel structure 51 (including a plurality of pixel structures 50). When the repair method determines that the number of ineffective vertical diode dies V2′ and V3′ is less than the quantity threshold, step S518 is executed; when the repair method determines that the number of ineffective vertical diode dies V2′ and V3′ is greater than or equal to the quantity threshold, step S519 is executed.

Please refer to both FIG. 7F and FIG. 7G. In this embodiment, the repair method determines the state of a specific pixel structure 50 to determine the existence of a defect and/or the color category. The repair method selects a specific flip-chip diode die 530 and transfers it to the accommodation site 551 of the pixel structure 50 by suction. The color category of the specific flip-chip diode die 530 corresponds to the color category of the defect. Then, please refer to FIG. 7H. The repair method involves forming a filling layer between the first blocking dams 550 (step S518). For example, a second filling layer 539 is formed on the flip-chip diode die 530. In this embodiment, the second filling layer 539 fills the accommodation site 551 until the top surface of the second filling layer 539 is substantially coplanar with the top surface of the first blocking dam 550.

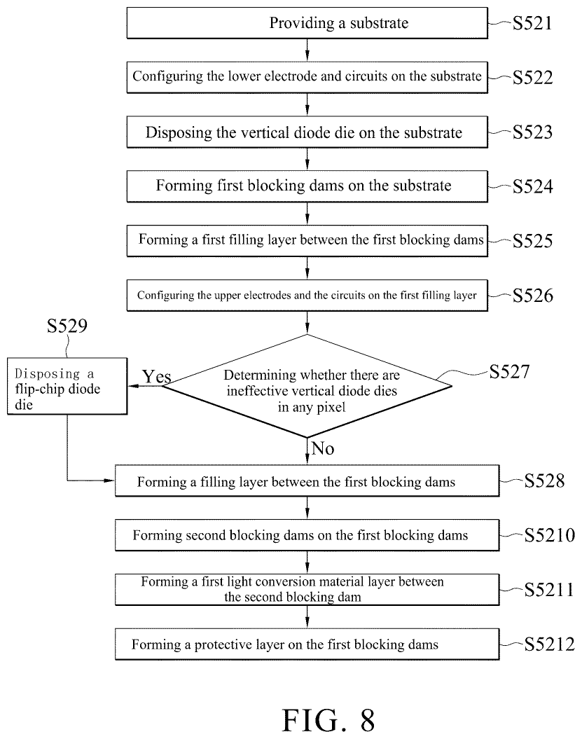

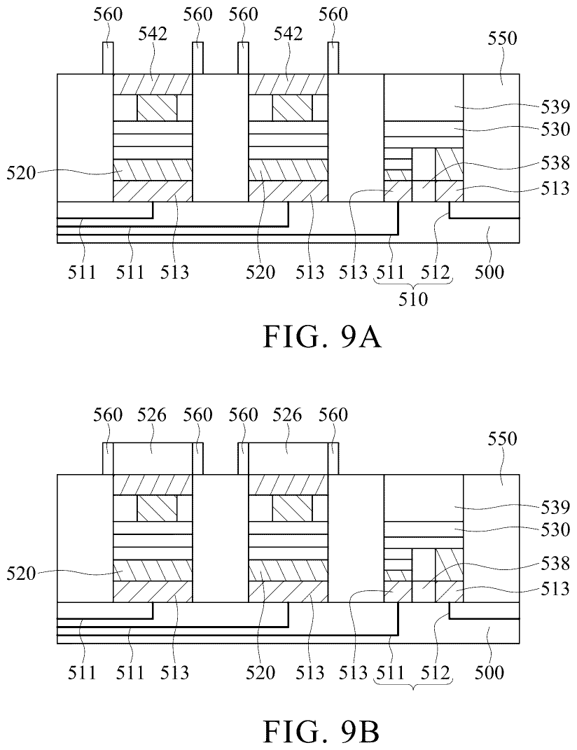

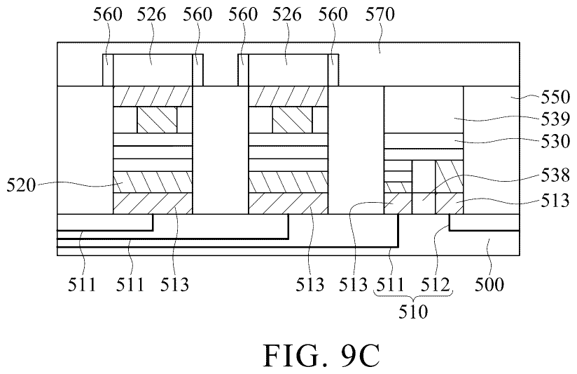

FIG. 8 is a flowchart of the method for repairing a pixel structure according to the second embodiment; FIGS. 9A to 9C are schematic diagrams of the manufacturing process of the method for repairing a pixel structure according to the second embodiment. Please refer to FIGS. 9A to 9C in sequence according to the steps in FIG. 8. The main difference between the repair methods of the second embodiment and the first embodiment lies in steps S527 to S5212. In this embodiment, the vertical diode die 520 itself does not have a color category. For example, the vertical diode die 520 is a short-wavelength light-emitting diode die, such as but not limited to a blue-light diode or an ultraviolet-light diode. In this embodiment, the short-wavelength light-emitting diode die is used to excite the light-conversion material to generate an emission beam corresponding to a specific color category. The short-wavelength light-emitting diode die can refer to the light-emitting diode die used to generate the excitation beam. The wavelength of the excitation beam is lower than the wavelength of the emission beam of the light-conversion material, or lower than the absorption edge wavelength of the light-conversion material. The light-conversion material can use fluorescent materials or quantum dots. The fluorescent materials can use sulfides, oxides, oxysulfides, nitrides, oxynitrides, halides or organic polymers, such as but not limited to yttrium aluminum garnet (YAG), zinc silicate (Zn₂SiO₄), zinc sulfide (ZnS), poly(p-phenylene vinylene). The materials of quantum dots can be but not limited to cadmium selenide (CdSe), indium phosphide (InP), zinc tellurium selenide (ZnTeSe), lead sulfide (PbS), and perovskite.

In step S527, the repair method determines whether there are ineffective vertical diode dies V2′ and V3′ in each pixel. In this embodiment, the repair method can make the determination based on whether the light beam generated by the vertical diode die 520 exceeds the intensity threshold, or based on whether the generated light beam is within the preset wavelength range. When the repair method determines that there are no ineffective vertical diode dies V2′ and V3′ in each pixel (in step S527, the determination result is “No”), a filling layer is formed between the first blocking dams 550 (step S528); when the repair method determines that there are ineffective vertical diode dies V2′ and V3′ in any pixel (in step S527, the determination result is “Yes”), a flip-chip diode die 530 is set (step S529). In this embodiment, the repair method determines the accommodation sites 551 of the ineffective vertical diode dies V2′ and V3′ in the pixel structure 50 to confirm the color category of the corresponding emitted light beam. For example, in FIG. 4D, the vertical diode die V1 corresponds to the red emitted light beam, the vertical diode die V2 corresponds to the green emitted light beam, and the vertical diode die V3 corresponds to the blue emitted light beam. Then, for the pixel structure 50 in the lower right corner of FIG. 5, when it is confirmed that the lower left corner of the pixel structure 50 contains an ineffective vertical diode die V3′, it can be determined that the pixel structure 50 has a defect of being unable to generate blue light after completion. It should be understood that here, “correspond” means that the accommodation sites 551 corresponding to the specific vertical diode dies V1, V2, and V3 are the same as the accommodation sites 551 corresponding to the emitted light beams of specific colors, but it is not limited to the specific vertical diode dies V1, V2, and V3 generating the emitted light beams of specific colors. For example, the vertical diode die V1 generates a red light beam; or, the vertical diode die V1 generates ultraviolet light, and then generates a red light beam through color conversion. Based on this, the repair method selects a specific flip-chip diode die 530 to be transferred to the accommodation site 551 of the pixel structure 50. The color category of the specific flip-chip diode die 530 corresponds to the color category of the defect. Then, the repair method forms a filling layer between the first blocking dams 550 (step S528), for example, a second filling layer 539 is formed on the flip-chip diode die 530.

Please refer to FIG. 9A. The repair method involves forming second blocking dams 560 on top of the first blocking dams 550 (step S5210). In this embodiment, the second blocking dam 560 is located directly on the first blocking dam 550 and only surrounds the accommodation site 551 containing the vertical diode die 520. In other embodiments, the second blocking dam 560 can also be located on the inner edge of the first blocking dam 550 surrounding the accommodation site 551. In addition, the second blocking dam 560 can also surround the accommodation site 551 containing the flip-chip diode die 530. The second blocking dam 560 can be made of the opaque material described in this disclosure. In some embodiments, the second blocking dam 560 is made of the same material as the first blocking dam 550.

Please refer to FIG. 9B. The repair method involves forming a first light conversion material layer 526 between the second blocking dams 560 (step S5211). The first light conversion material layer 526 has color categories, respectively corresponding to specific accommodation sites 551 on the pixel structure 50. In this embodiment, the color category of each first light conversion material is different from that of the flip-chip diode die 530. For example, if the two first light conversion material layers 526 in FIG. 9B are used to generate red and green emission beams respectively, then the flip-chip diode die 530 is used to generate a blue emission beam. Please refer to FIG. 9C. The repair method involves forming a protective layer 570 on the first blocking dams 550 (step S5212). In this embodiment, the protective layer 570 is used to cover and protect the vertical diode die 520, the flip-chip diode die 530, and the light conversion material layer. The protective layer 570 can be made of the light-transmissive material described in this disclosure. In some embodiments, the protective layer 570 is made of the same material as the second filling layer 539.

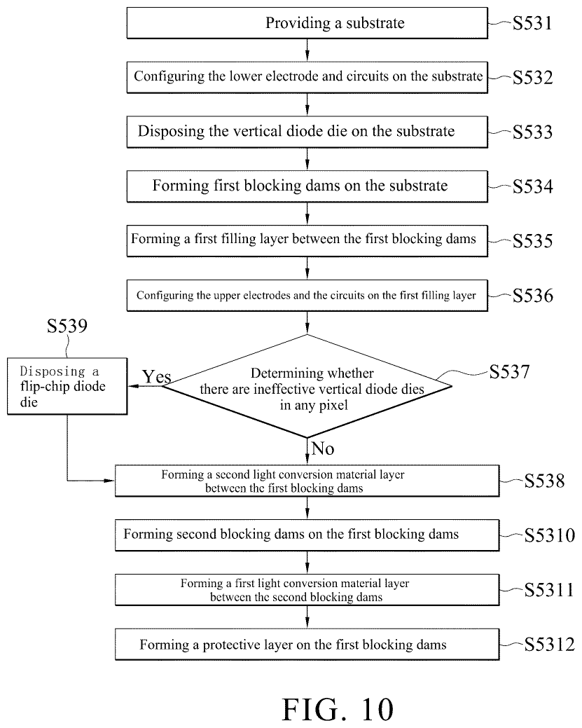

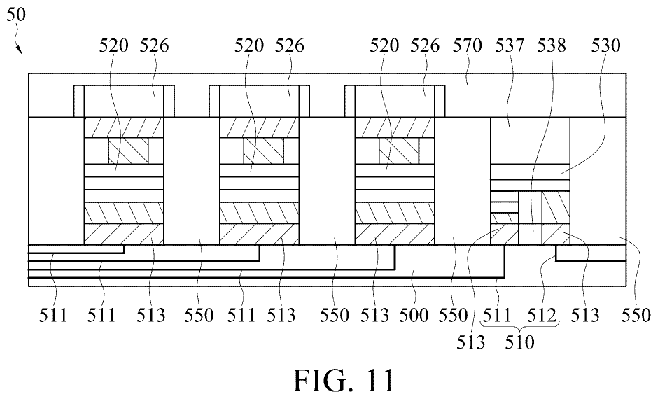

FIG. 10 is a flowchart of a method for repairing a pixel structure according to a third embodiment; FIG. 11 is a schematic diagram of the manufacturing process of the method for repairing a pixel structure according to the third embodiment. Please refer to FIG. 10 and FIG. 11 together. The main difference between the repair methods of the third embodiment and the second embodiment lies in steps S538 to S5311. In this embodiment, the flip-chip diode die 530 itself does not have a color category. For example, the flip-chip diode die 530 is a short-wavelength light-emitting diode die.

In step S537, when the repair method determines that any pixel has an ineffective vertical diode die V2′, V3′ (in step S537, the determination result is “Yes”), then a flip-chip diode die 530 is set (step S539). In this embodiment, the repair method determines the accommodation site 551 of the ineffective vertical diode dies V2′, V3′ within the pixel structure 50 to confirm the color category of the corresponding emitted light beam. However, the flip-chip diode die 530 does not need to correspond to the color category of the defect. Thereafter, the repair method involves forming a second light conversion material layer 537 between the first blocking dams 550 (step S538). The second light conversion material layer 537 has a color category and corresponds to the color category of the defect. For example, FIG. 11 includes three first light conversion material layers 526, which are respectively used to generate red, green, and blue emitted light beams. Among them, the vertical diode die 520 corresponding to the red light beam is ineffective. Then, the repair method forms a second light conversion material layer 537 corresponding to red on the flip-chip diode die 530. In other embodiments, when the repair method determines that the vertical diode die 520 at a specific site of the pixel structure 50 is ineffective, the first light conversion material layer 526 is not formed on the specific site.

In other embodiments, the repair method determines the accommodation sites 551 of the ineffective vertical diode dies V2′ and V3′ within the pixel structure 50. Then, in step S538, the repair method forms a second light conversion material layer (light conversion material layer) 537 between the first blocking dams 550 to cover the flip-chip diode dies 530. Next, second blocking dams 560 are formed on the first blocking dams 550 (step S5310). In step S5311, the repair method forms a first light conversion material layer 526 between the second blocking dams 560 to cover the vertical diode dies 520. The color categories of each first light conversion material layer 526 and the second light conversion material layer 537 are different. Next, a protective layer 570 is formed on the first blocking dam 550 (step S5312). In this embodiment, the repair method does not need to confirm the color category of the defect and then select the second light conversion material layer 537 of the corresponding color category. Therefore, the accommodation sites 551 of the pixel structure 50 are not necessarily related to the color category.

Referring back to FIG. 1, in some embodiments, the pixel structure 50 includes a substrate 500, a plurality of vertical diode dies 520, flip-chip diode dies 530, and an upper circuit layer 540. The flip-chip diode dies 530 can be set in the pixel structure 50 after the repair process or before the repair process. In some embodiments, when the pixel structure 50 is applied, it may face the problems that pure-color micro-LEDs need to perform a plurality of complex mass transfers and complex repair processes during the manufacturing process, while color-conversion micro-LEDs have the problems of complex structure, narrow color gamut, and low reliability. In some embodiments, the hybrid micro-LED structure and its repair method in the following embodiments can be used to implement or apply to the pixel structure 50. By combining pure-color micro-LEDs and color-conversion micro-LEDs in the micro-LEDs, a pixel structure 50 of micro-LEDs with a simple structure, a wider color gamut, higher reliability, and a simple repair process can be achieved. However, the present disclosure is not limited to this. Under different design considerations or application scenarios, other structures, processes, or manufacturing processes can be used to implement the pixel structure 50 disclosed in the present disclosure.

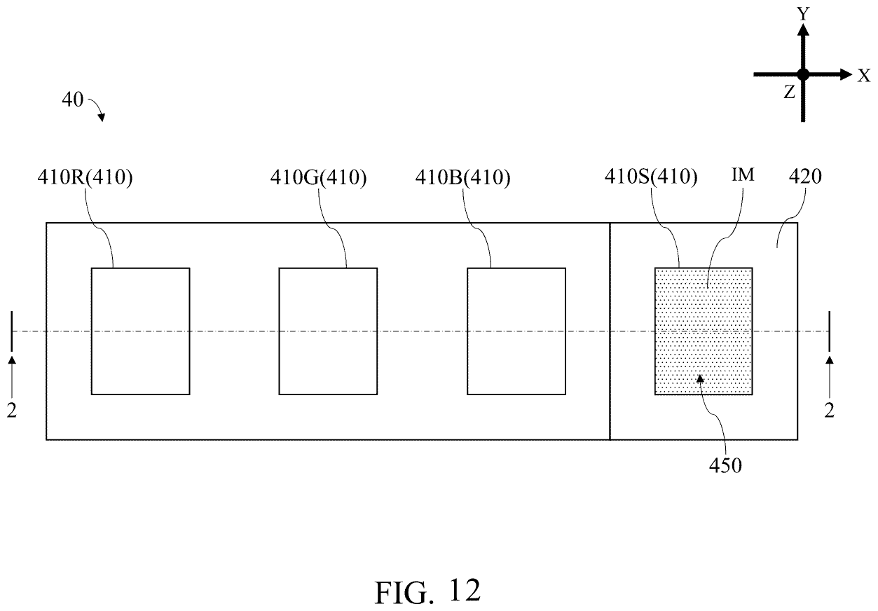

Please refer to FIGS. 12 to 14. A hybrid micro-LED structure 40 includes a substrate 400, a plurality of micro-LED dies 410 (including a red micro-LED die 410R, a green micro-LED die 410G, a blue micro-LED die 410B, and a spare micro-LED die 410S), an isolation layer 420, a filling layer 430, and a light-transmitting layer 440. The red micro-LED die 410R, the green micro-LED die 410G, the blue micro-LED die 410B, the spare micro-LED die 410S, and the isolation layer 420 are disposed on the substrate 400. In some embodiments, the spare micro-LED die 410S can be another blue micro-LED die or an ultraviolet (UV) micro-LED die, without being limited thereto.

The isolation layer 420 surrounds the spare micro-LED die 410S on all sides and forms an inkjet space 450 with the spare micro-LED die 410S. The inkjet space 450 is used to fill an inkjet material IM. In other words, in some embodiments, the combination of the spare micro-LED die 410S, the isolation layer 420, the inkjet space 450, and the inkjet material IM can be regarded as a color conversion micro-LED. By filling the inkjet material IM into the inkjet space 450 and lighting up the spare micro-LED die 410S, the color conversion micro-LED can emit light corresponding to the color of the inkjet material IM. In other words, in some embodiments, the light (such as blue light or ultraviolet light) emitted by the spare micro-LED die 410S can have its color converted through the inkjet material IM, so that the color conversion micro-LED can emit light of different colors.

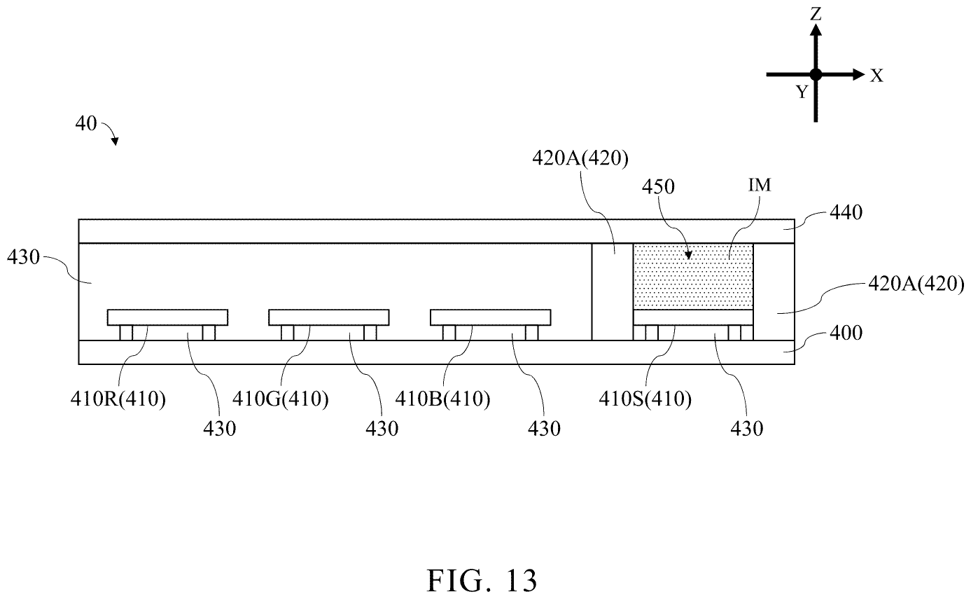

Any one of the red micro-LED die 410R, the green micro-LED die 410G, the blue micro-LED die 410B, and the spare micro-LED die 410S is adjacent to at least one of the remaining three. Taking FIG. 13 as an example, in this embodiment, the red micro-LED die 410R, the green micro-LED die 410G, the blue micro-LED die 410B, and the spare micro-LED die 410S are sequentially disposed along a first direction (such as but not limited to the X axis direction) and then disposed on the substrate 400, thereby forming a rectangular array with 4 rows and 1 column.

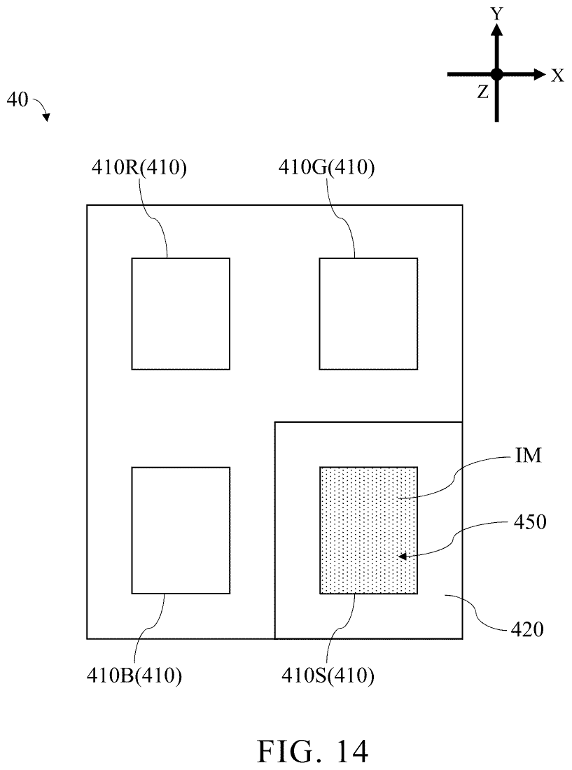

Taking FIG. 14 as an example again, in this embodiment, the red micro-LED die 410R, the green micro-LED die 410G, the blue micro-LED die 410B, and the spare micro-LED die 410S are sequentially disposed along the first direction (such as but not limited to the X-axis direction) and a second direction (such as but not limited to the Y axis direction) and then disposed on the substrate 400, thereby forming a rectangular array with 2 rows and 2 columns.

It should be noted that the dispersement order among the red micro-LED die 410R, the green micro-LED die 410G, the blue micro-LED die 410B, and the spare micro-LED die 410S is not limited to the on embodiments (including FIGS. 12 and 14). For example, the spare micro-LED die 410S can be set between any two of the red micro-LED die 410R, the green micro-LED die 410G, and the blue micro-LED die 410B (not shown in the figure). Alternatively, the red micro-LED die 410R can be set between any two of the green micro-LED die 410G, the blue micro-LED die 410B, and the spare micro-LED die 410S (not shown in the figure).

In some embodiments, the hybrid micro-LED structure 40 can be applied to a micro-LED display device. The hybrid micro-LED structure 40 forms a pixel in the micro-LED display device, and the red micro-LED die 410R, the green micro-LED die 410G, the blue micro-LED die 410B, and the spare micro-LED die 410S are each a sub-pixel. That any one of the red micro-LED die 410R, the green micro-LED die 410G, the blue micro-LED die 410B, and the spare micro-LED die 410S is adjacent to at least one of the remaining three means that each sub-pixel in a single pixel is adjacent to at least one of the remaining three sub-pixels. If two adjacent sub-pixels belong to different pixels, they are not the “adjacent” described here.

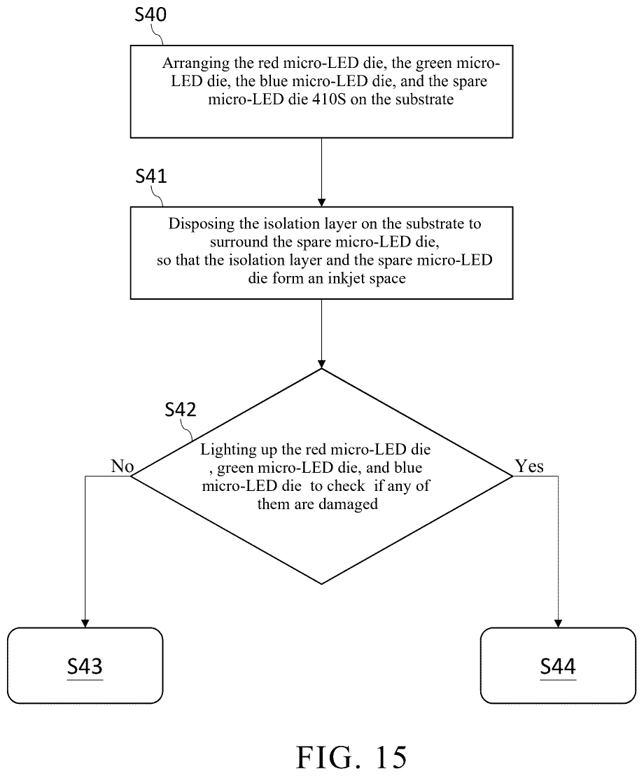

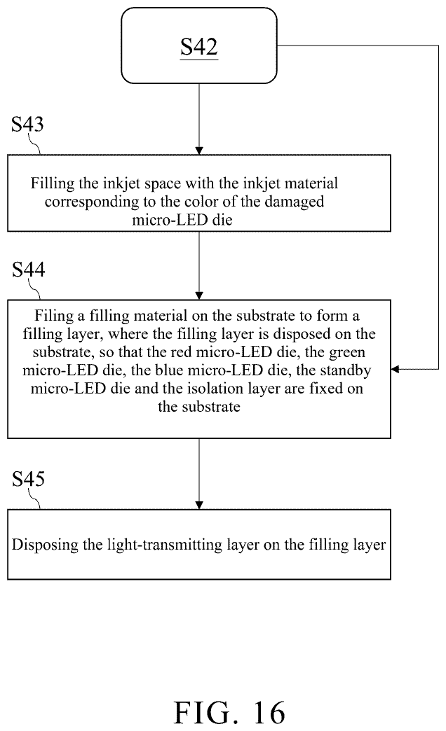

Please refer to FIGS. 12, 13, 15, and 16. The following takes FIGS. 12 and 13 as examples to illustrate the manufacturing process of the hybrid micro-LED structure 40 and the repair method when the micro-LED die 410 is damaged. First, the red micro-LED die 410R, the green micro-LED die 410G, the blue micro-LED die 410B, and the spare micro-LED die 410S are arranged on the substrate 400 (step S40). In some embodiments, the micro-LED die 410 can be disposed on the substrate 400 through the mass transfer technology.

In some embodiments, the material of the substrate 400 can be an opaque insulating material, such as but not limited to silicon (Si), silicon dioxide (SiO₂), gallium arsenide (GaAs), and silicon carbide (SiC). In other embodiments, the material of the substrate 400 can be a light-transmitting insulating material, such as but not limited to glass, silicone, epoxy resin, polyimide (PI), benzocyclobutene (BCB), perfluorocyclobutane (PFCB), SU8 photoresist, acrylic resin, polyethylene terephthalate (PET), and polyetherimide.

In some embodiments, when a plurality of micro-LED dies 410 are disposed on the substrate 400, each micro-LED die 410 is electrically connected to at least one driving circuit (not shown) in the hybrid micro-LED structure 40 through a pair of electrodes (including the N-pole and the P-pole). In some embodiments, the hybrid micro-LED structure 40 can drive each micro-LED die 410 to emit light through a single driving circuit. In other embodiments, the hybrid micro-LED structure 40 can also drive each micro-LED die 410 to emit light through a plurality of driving circuits respectively. In other words, in some embodiments, each micro-LED die 410 can be independently driven to emit light respectively.

In some embodiments, when the spare micro-LED die 410S is another blue micro-LED die, the spare micro-LED die 410S is adjacent to the blue micro-LED die 410B (as shown in FIG. 12). Here, when a plurality of micro-LED dies 410 are disposed on the substrate 400 through the mass transfer technology, the blue micro-LED die 410B and the spare micro-LED die 410S can be transferred and disposed at adjacent positions simultaneously, thereby improving the efficiency of mass transfer. In some embodiments, the spare micro-LED die 410S is further adjacent to the red micro-LED die 410R or the green micro-LED die 410G. Taking FIG. 14 as an example, in this embodiment, the spare micro-LED die 410S is adjacent to the green micro-LED die 410G and the blue micro-LED die 410B.

After step S40, an isolation layer 420 is disposed on the substrate 400 to surround the spare micro-LED die 410S, so that the isolation layer 420 and the spare micro-LED die 410S form an inkjet space 450 (step S41). In some embodiments, the isolation layer 420 can be disposed on the substrate 400 through deposition techniques, such as but not limited to chemical vapor deposition (CVD) technology, physical vapor deposition (PVD) technology, area selective deposition (ASD) technology, and atomic layer deposition (ALD) technology.

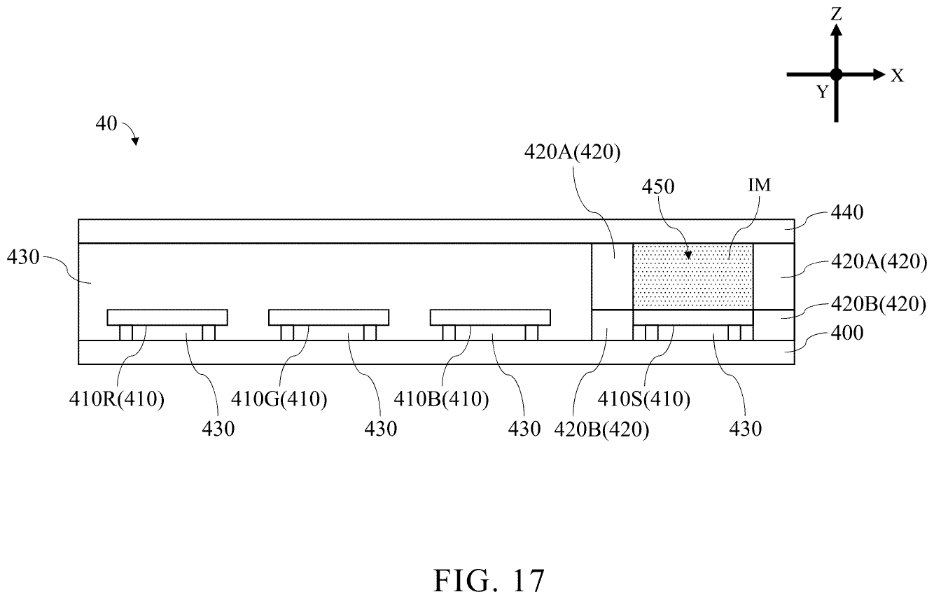

Please refer to FIGS. 13 and 17. As shown in FIG. 13, in some embodiments, the isolation layer 420 includes an opaque material 420A (as shown in FIG. 13), and the opaque material 420A surrounds the spare micro-LED dies 410S and the inkjet space 450. In other embodiments, the isolation layer 420 includes an opaque material 420A and an isolation material 420B (as shown in FIG. 17). The opaque material 420A surrounds the inkjet space 450, and the isolation material 420B surrounds the spare micro-LED dies 410S. In other words, in this embodiment, the isolation material 420B is formed on the substrate 400 to surround the spare micro-LED dies 410S, and then the opaque material 420A is formed on the isolation material 420B to surround the inkjet space 450.

In some embodiments, the isolation layer 420 is used to prevent the light emitted by the spare micro-LED dies 410S from interfering with the adjacent micro-LED dies 410. Therefore, the isolation layer 420 surrounds the inkjet space 450 through the opaque material 420A. In some embodiments, the opaque material 420A can be a black matrix (BM) material or a light-reflective material, such as but not limited to bauxite, dielectric multilayer films, and reflective resin materials. In some embodiments, the isolation material 420B can be a light-transmissive material (such as but not limited to silicone, epoxy resin, polyimide, benzocyclobutene, perfluorocyclobutane, SU8 photoresist, acrylic resin, polyethylene terephthalate, and polyetherimide), or it can be an opaque material (such as but not limited to black matrix material, bauxite, dielectric multilayer films, and reflective resin materials). After step S41, the red micro-LED dies 410R, green micro-LED dies 410G, and

blue micro-LED dies 410B are checked to see if any of them are damaged and unable to emit light (step S42). In some embodiments, the situations where the micro-LED dies 410 are unable to emit light include that they have defects themselves and cannot emit light, or they are physically damaged during the mass transfer process, but are not limited to these.

When one of the red micro-LED die 410R, the green micro-LED die 410G, and the blue micro-LED die 410B is damaged, it means that the hybrid micro-LED structure 40 cannot emit light with normal color. At this time, the hybrid micro-LED structure 40 needs to be repaired. Therefore, in some embodiments after step S42, the inkjet space 450 can be filled with the inkjet material IM corresponding to the color of the damaged micro-LED die 410 (step S43) to supplement the light of the missing color in the hybrid micro-LED structure 40. For example, when the red micro-LED die 410R is damaged and cannot emit light, it means that the hybrid micro-LED structure 40 cannot emit red light. At this time, the inkjet space 450 can be filled with red inkjet material IM to change the color of the light emitted by the standby micro-LED die 410S, so that the hybrid micro-LED structure 40 can emit red light through the standby micro-LED die 410S and the red inkjet material IM.

In some embodiments, the inkjet material IM is a quantum dot (QD). A quantum dot is a nanomaterial used to change the wavelength of the light emitted by the micro-LED die 410 (hereinafter referred to as uLED light) to change the color of the uLED light. For example, quantum dots with a larger size (e.g., a diameter of 5 to 6 nanometers, not limited thereto) can convert the color of the uLED light into red or orange, and quantum dots with a smaller size (e.g., a diameter of 2 to 3 nanometers, not limited thereto) can convert the color of the uLED light into blue or green. In some embodiments, the quantum dots are selected from materials such as cadmium selenide (CdSe), indium phosphide (InP), zinc tellurium selenide (ZnTeSe), and perovskite, not limited thereto.

In some embodiments, when one of the red micro-LED die 410R, the green micro-LED die 410G, and the blue micro-LED die 410B is damaged, the damaged micro-LED die 410 can be permanently turned off to reduce the power consumption of the hybrid micro-LED structure 40 during use. For example, when the red micro-LED die 410R is damaged, the red micro-LED die 410R is permanently turned off, so that only the green micro-LED die 410G, the blue micro-LED die 410B, and the spare micro-LED die 410S in the hybrid micro-LED structure 40 can emit light.

After the micro-LED die 410 in the hybrid micro-LED structure 40 is repaired, the hybrid micro-LED structure 40 can continue to complete its manufacturing process. Therefore, in some embodiments after step S43, a filling material is filled on the substrate 400 to form a filling layer 430 (step S44). Here, the filling layer 430 is disposed on the substrate 400, and the filling layer 430 is used to fix each micro-LED die 410 and the isolation layer 420 on the substrate 400. In some embodiments, the filling material can be a transparent material with adhesiveness, such as but not limited to adhesive, underfill, anisotropic conductive paste (ACP), anisotropic conductive film (ACF), non-conductive paste (NCP), and non-conductive film (NCF).

Finally, after step S44, a light-transmitting layer 440 is disposed on the filling layer 430 (step S45) to strengthen and protect the hybrid micro-LED structure 40. In some embodiments, the material of the light-transmitting layer 440 can be a hard material with light transmittance, such as but not limited to glass and acrylic. In other embodiments, when the spare micro-LED die 410S is an ultraviolet micro-LED die, the material of the light-transmitting layer 440 can be a hard material with light transmittance and ultraviolet resistance, such as but not limited to polycarbonate (PC) and polymethyl methacrylate (PMMA).

When the red micro-LED die 410R, the green micro-LED die 410G, and the blue micro-LED die 410B are all undamaged, there is no need to fill any inkjet material IM in the inkjet space 450. Therefore, in some other embodiments after step S42, the filling material can be directly filled on the substrate 400 to form the filling layer 430 (step S44), and the light-transmitting layer 440 can be disposed on the filling layer 430 (step S45). In some embodiments, when the red micro-LED die 410R, the green micro-LED die 410G, and the blue micro-LED die 410B are all undamaged, the spare micro-LED die 410S can be constantly turned off to reduce the power consumption of the hybrid micro-LED structure 40 during use. That is to say, at this time, only the red micro-LED die 410R, the green micro-LED die 410G, and the blue micro-LED die 410B in the hybrid micro-LED structure 40 can emit light.

According to any embodiment, the hybrid micro-LED structure combines the characteristics of pure-color micro-LEDs and color-conversion micro-LEDs, so that the hybrid micro-LED structure has the advantages of small area and high color accuracy at the same time. In addition, since the repair process of the hybrid micro-LED structure is simple, when a panel or display device made of the hybrid micro-LED structure has dead pixels, the manufacturer can easily find the positions of the dead pixels and repair them, thereby improving the yield and reliability of the panel and the display device.

Referring again to FIG. 1, in some embodiments, the pixel structure 50 includes a substrate 500, a plurality of vertical diode dies 520, a flip-chip diode die 530, and an upper circuit layer 540. In some embodiments, when the vertical diode dies 520 or the flip-chip diode die 530 are applied, they may face the problem of variations in production equipment or manufacturing technology, resulting in specification differences among different types of diode dies. Among them, the height differences between the diode dies may have an adverse impact on the subsequent eutectic bonding process, such as causing poor bonding and reducing the process yield. These height differences will also have a negative impact on the alignment accuracy during the process and the optical performance of the final product. In some embodiments, the diode dies and their manufacturing methods in the following embodiments can be used to implement or be applied to the vertical diode dies 520 or the flip-chip diode die 530. The pixel structure 50 can also be used to implement or be applied to the panel structure in the following embodiments. However, the present disclosure is not limited to this. Under different design considerations or application scenarios, other structures, processes, or manufacturing methods can be adopted to implement the vertical diode dies 520 or the flip-chip diode die 530 disclosed in the present disclosure.

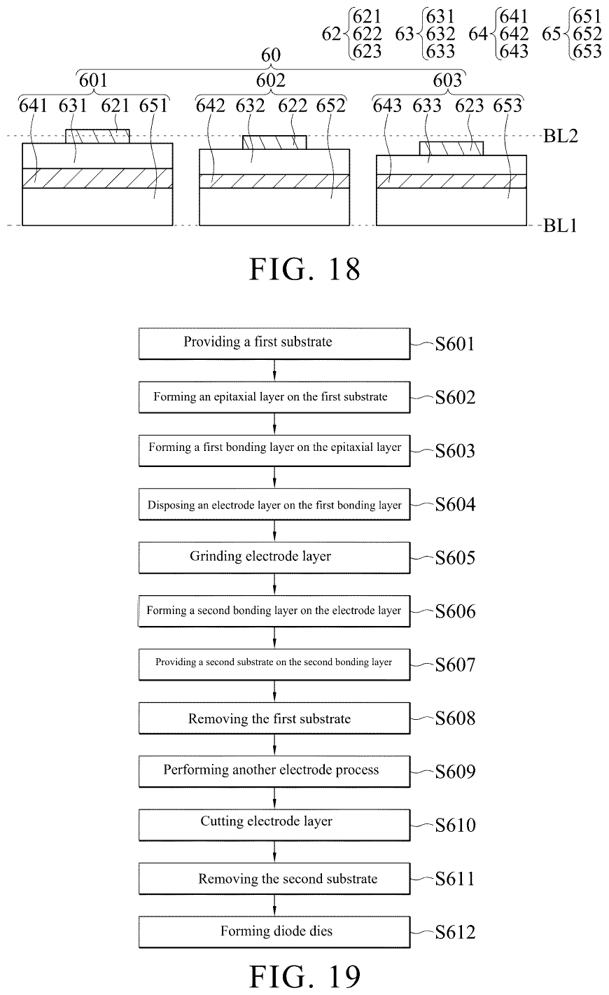

FIG. 18 is a schematic diagram of a plurality of diode dies with different die heights according to some embodiments. In this embodiment, there are three diode dies 60, namely the first diode die 601, the second diode die 602, and the third diode die 603. In this embodiment, the diode dies 60 are vertical diode dies. Each vertical diode die includes a top electrode 62 (i.e., top electrodes 621, 622, 623), an epitaxial layer 63 (i.e., epitaxial layers 631, 632, 633), a bottom electrode 64 (i.e., bottom electrodes 641, 642, 643), and a second substrate 65 (i.e., second substrates 651, 652, 653). The bottom electrode 64 is disposed on the second substrate 65, the epitaxial layer 63 is disposed on the bottom electrode 64, and the top electrode 62 is disposed on the epitaxial layer 63. In other embodiments, the vertical diode die may not include the second substrate 65, and the epitaxial layer 63 may also have a multi-layer structure, for example, including a P-type or N-type doped layer. The first diode die 601, the second diode die 602, and the third diode die 603 shown in FIG. 18 are placed on the same horizontal plane. The first reference line BL1 represents the height of the horizontal plane, and the second reference line BL2 represents the height of the upper surface of one of the diode dies 60, for example, the height of the upper surface of the top electrode 622 of the second diode die 602 in FIG. 18. In this embodiment, the height of the first diode die 601 is higher than the second reference line BL2, and the height of the third diode die 603 is lower than the second reference line BL2. The main reason is the process variation among the diode dies 60, which results in the first diode die 601 having a thicker bottom electrode 641 and the third diode die 603 having a thinner epitaxial layer 633.

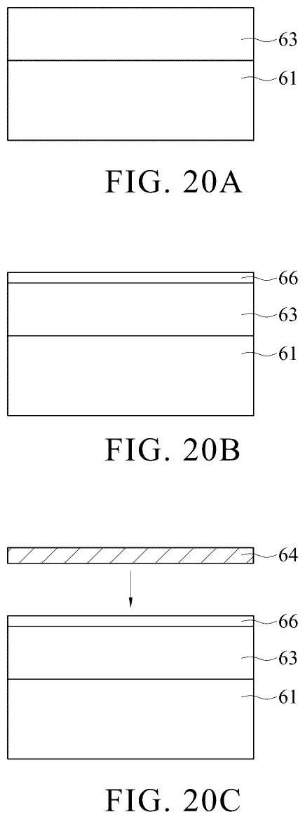

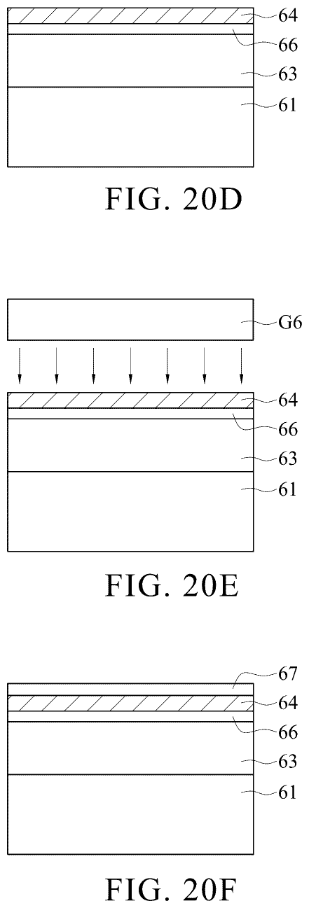

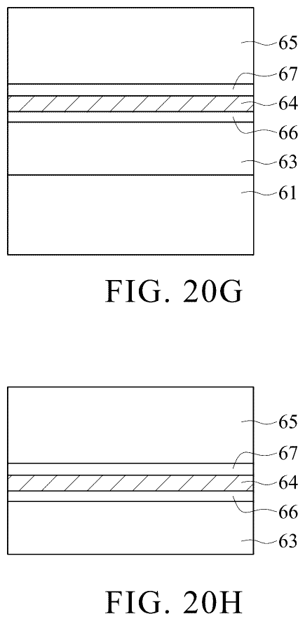

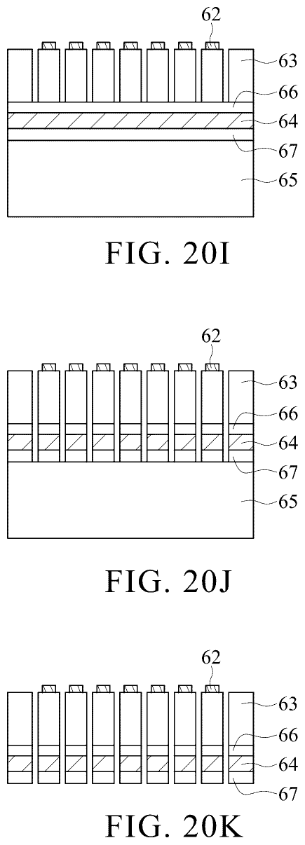

FIG. 19 is a flowchart of a manufacturing method for a diode die according to some embodiments; FIGS. 20A to 20K are schematic diagrams of a manufacturing method for a diode die according to some embodiments. Please refer to FIGS. 20A to 20K sequentially based on FIG. 19. As shown in FIG. 20A, the manufacturing method includes providing a first substrate 61 (step S601) and forming an epitaxial layer 63 on the first substrate 61 (step S602). The material of the first substrate 61 can be selected from the group consisting of silicon (Si), silicon dioxide (SiO₂), aluminum oxide (Al₂O₃), gallium arsenide (GaAs), silicon carbide (SiC), glass, silicone, epoxy resin, polyimide (PI), benzocyclobutene (BCB), perfluorocyclobutane (PFCB), SU8 photoresist, acrylic resin, polyethylene terephthalate (PET), polyetherimide, and combinations thereof. The material of the epitaxial layer 63 can be selected from the group consisting of gallium nitride (GaN), gallium arsenide (GaAs), indium gallium phosphide (InGaP), zinc selenide (ZnSe), silicon carbide (SiC), aluminum gallium nitride (AlGaN), zinc sulfide (ZnS), silicon (Si), and combinations thereof. The epitaxial layer 63 has a lattice constant that is the same as or similar to that of the first substrate 61. The process for forming the epitaxial layer 63 can use a deposition method, such as but not limited to chemical vapor deposition (CVD), physical vapor deposition (PVD), area selective deposition (ASD), and atomic layer deposition (ALD).

As shown in FIG. 20B, the manufacturing method includes forming a first bonding layer 66 on the epitaxial layer 63 (step S603). The first bonding layer 66 serves as an intermediate layer between the epitaxial layer 63 and the bottom electrode 64 to improve the bonding strength between the two. The process for forming the first bonding layer 66 can use a deposition method or a coating method. As shown in FIGS. 20C and 20D, the manufacturing method includes disposing an electrode layer on the first bonding layer 66 (step S604) to indirectly bond the bottom electrode 64 to the epitaxial layer 63. In this embodiment, after the bottom electrode 64 is pre-formed, it is then disposed on the first bonding layer 66. Therefore, the bottom electrode 64 can have a relatively thick layered structure to facilitate further processing of the bottom electrode 64 in subsequent processes. The process for disposing the electrode layer can use pressing and annealing. The bottom electrode 64 can be a conductive material, such as but not limited to gold, silver, copper, aluminum, or an alloy containing the aforementioned metals.

As shown in FIG. 20E, the manufacturing method includes grinding the electrode layer (Step S605). In this embodiment, the process variation of the bottom electrode 64 may cause the thickness specification of the bottom electrode 64 to not meet the requirements. The grinding process in Step S605 makes the thickness specification of the bottom electrode 64 meet the absolute thickness acceptance specification and/or the relative thickness acceptance specification. The absolute thickness acceptance specification refers to an absolute value, for example, the acceptance range that limits the thickness value of the bottom electrode 64 to be between 10 μm and 100 μm. In some embodiments, the bottom electrode 64 of the diode die 60 is formed into a special shape (such as a trapezoid) for use in the pre-alignment process. The special shape (such as a trapezoid) must meet the specified absolute value range. Based on this, the manufacturing method includes grinding the electrode layer to make its thickness meet the thickness specification acceptance range of the special shape. The relative thickness acceptance specification refers to a relative value. For example, it limits the thickness value of the bottom electrode 64 of a specific diode die 60 so that the height of the specific diode die 60 is substantially the same as the height of other diode dies 60, which will be described in detail later.

As shown in FIG. 20F, the manufacturing method includes forming a second bonding layer 67 on the electrode layer (Step S606). The second bonding layer 67 serves as an intermediate layer between the second substrate 65 and the bottom electrode 64 to enhance the bonding strength between the two. The process for forming the second bonding layer 67 can use a deposition method or a coating method. As shown in FIG. 20G, the manufacturing method includes disposing the second substrate 65 on the second bonding layer 67 (Step S607), so that the second substrate 65 is indirectly bonded to the bottom electrode 64. The process for disposing the second substrate 65 can use pressing and annealing. The material of the second substrate 65 can be selected from the group consisting of silicon (Si), silicon dioxide (SiO₂), aluminum oxide (Al₂O₃), gallium arsenide (GaAs), silicon carbide (SiC), glass, silicone, epoxy resin, polyimide (PI), benzocyclobutene (BCB), perfluorocyclobutane (PFCB), SU8 photoresist, acrylic resin, polyethylene terephthalate (PET), polyetherimide, and combinations thereof. The material of the second substrate 65 can be different from that of the first substrate 61. For example, the first substrate 61 uses a substrate on which an epitaxial layer 63 can be easily formed, and the second substrate 65 uses a reflective substrate to improve the luminous efficiency of the diode die 60. Alternatively, the material of the second substrate 65 can be the same as that of the first substrate 61. For example, both the first substrate 61 and the second substrate 65 use sapphire substrates.

As shown in FIG. 20H, the manufacturing method includes removing the first substrate 61 (Step S608). Based on this, the semi-finished diode substrate is transferred from the first substrate 61 to the second substrate 65. In this embodiment, when the diode substrate is inverted, the second substrate 65 is at the bottom of the diode substrate, and the epitaxial layer 63 is at the top, which is beneficial for performing subsequent processes on the epitaxial layer 63. As shown in FIG. 201, the manufacturing method includes performing another electrode process (Step S609). Specifically, in this embodiment, another electrode layer is formed on the surface of the epitaxial layer 63 and is cut into a plurality of independent dies, so that each independent die has a top electrode 62. The material of the top electrode 62 can be a conductive material, and it can be the same as or different from the material of the bottom electrode 64. The method for forming the top electrode 62 can use a deposition method or a pressing method.

As shown in FIG. 20J, the manufacturing method includes cutting the electrode layer (step S610). In this embodiment, the bottom electrode layer is cut to form the bottom electrodes 64 of each independent die. In some embodiments, the manufacturing method can cut the electrode layer at a specific angle so that the side surfaces of the bottom electrodes 64 of each independent die have an inclination angle, thus forming trapezoidal bottom electrodes 64. The manufacturing method of this embodiment only cuts the bottom electrode layer. In other embodiments, the manufacturing method cuts the bottom electrode layer and the second substrate 65 to form the bottom electrodes 64 of each independent die and the bottom substrate (such as the first diode die 601 shown in FIG. 18).

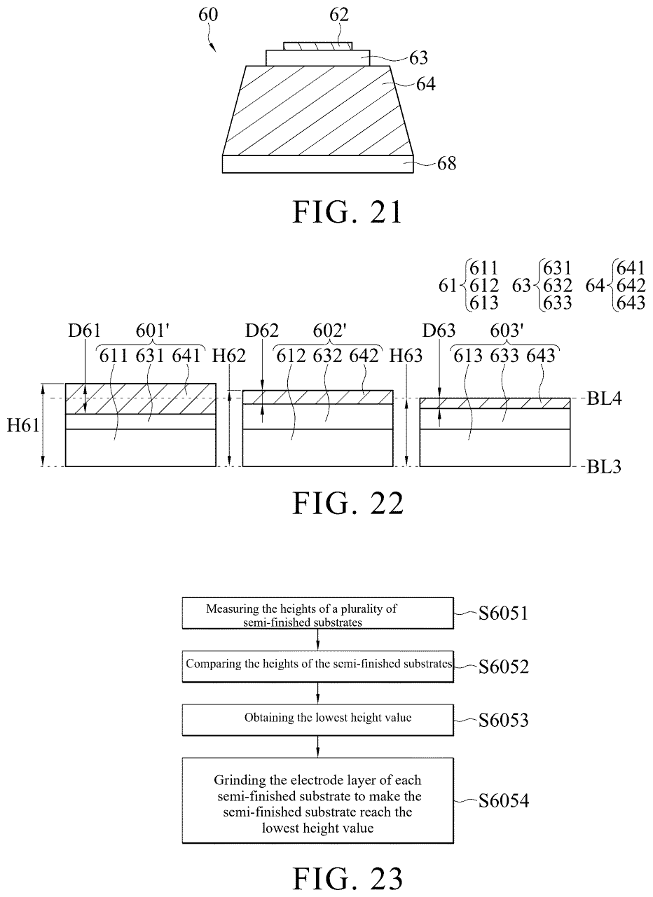

As shown in FIG. 20K, the manufacturing method includes removing the second substrate 65 (step S611) and forming the diode die 60 (step S612). In this embodiment, the manufacturing method produces at least 7 diode dies 60, and the diode dies 60 can be applied to the panel structure 600. FIG. 21 is a schematic diagram of a diode die according to some embodiments. Please refer to FIG. 21. In this embodiment, the diode die 60 includes a top electrode 62, an epitaxial layer 63, a bottom electrode 64, and a conductor layer 68 (i.e., conductor layers 681, 682, 683). The bottom electrode 64 is disposed on the conductor layer 68, the epitaxial layer 63 is disposed on the bottom electrode 64, and the top electrode 62 is disposed on the epitaxial layer 63. The conductor layer 68 can be the second bonding layer 67 or a conductive layer additionally formed on the surface of the bottom electrode 64 (or the second bonding layer 67) to protect the bottom electrode 64 and connect to an external substrate. The bottom electrode 64 of this embodiment has a trapezoidal structure, and its sidewall is the hypotenuse of the trapezoid, and the thickness is the height of the trapezoid. The trapezoidal structure of the bottom electrode 64 is beneficial for the pre-alignment of the diode die 60 before transfer. For example, the trapezoidal structure of the bottom electrode 64 corresponds to the trapezoidal concave holes on the alignment tray, and a large number of aligned diode dies 60 can be transferred to the external substrate at one time. In this embodiment, the diode die 60 can have a lower-limit height restriction to facilitate corresponding to the concave holes of the alignment tray.

The manufacturing methods described in the foregoing embodiments (for example, part or all of the processes from step S601 to step S612) can be repeatedly executed to produce the first diode die 601, the second diode die 602, and the third diode die 603. However, there may be process variations in the manufacturing method, resulting in differences in the size specifications of each diode die 60. For example, one or more of the epitaxial layer 63 formed in step S602, the first bonding layer 66 formed in step S603, and the electrode layer provided in step S604 in each process may have thickness differences.

FIG. 22 is a schematic diagram comparing the heights of a plurality of semi-finished substrates according to some embodiments. Please refer to FIG. 22. The first diode substrate 601′, the second diode substrate 602′, and the third diode substrate 603′ in this embodiment respectively correspond to the semi-finished substrates in step S604 (refer to FIG. 20D, the first bonding layer 66 is not shown in FIG. 22). When the first diode substrate 601′, the second diode substrate 602′, and the third diode substrate 603′ are placed on the same horizontal plane, the third reference lineBL3 represents the height of the horizontal plane, and the fourth reference lineBL4 represents the height of the upper surface of the diode substrate with the lowest height, for example, the height of the upper surface of the bottom electrode 643 of the third diode substrate 603′ in FIG. 22. In this embodiment, the first diode substrate 601′ has a height H61, and its bottom electrode 641 has a thickness D61; the second diode substrate 602′ has a height H62, and its bottom electrode 642 has a thickness D62; the third diode substrate 603′ has a height H63, and its bottom electrode 643 has a thickness D63. Among them, the thickness D61 is greater than the thickness D62, and the thickness D62 is greater than the thickness D63; the height H61 is greater than the height H62, and the height H62 is greater than the height H63. The main reason is that the bottom electrode 641 of the first diode substrate 601′ has a larger thickness D61 due to process variations, and the epitaxial layer 633 of the third diode substrate 603′ has a smaller thickness due to process variations.

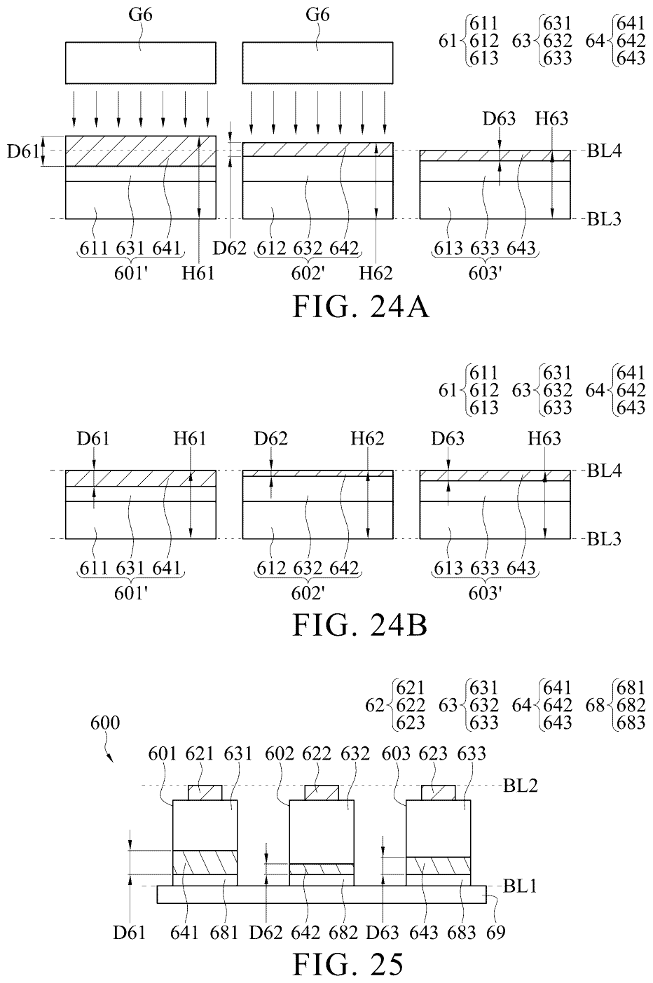

FIG. 23 is a flowchart of a manufacturing method of a diode die according to other embodiments; FIGS. 24A to 24B are schematic diagrams of a manufacturing method of a diode die according to other embodiments. Please refer to FIGS. 24A to 24B sequentially based on FIG. 23. In this embodiment, step S605 of the manufacturing method further includes steps S6051 to S6054. In step S6051, the manufacturing method measures the heights of a plurality of semi-finished substrates to obtain the heights H61, H62, and H63 of each diode substrate. For example, the first substrates 61 (i.e., the first substrates 611, 612, 613) of each diode substrate are placed on the same third reference lineBL3, and a laser thickness gauge measures the upper surface of the bottom electrode 64 of each diode substrate respectively to obtain the height of the diode substrate.

Subsequently, the manufacturing method includes comparing the heights of each semi-finished substrate (step S6052) to obtain the lowest height value (step S6053). As shown in FIG. 24A, the manufacturing method determines that the third diode substrate 603′ has the lowest height. Therefore, the fourth reference line BL4 is disposed on the top surface of the bottom electrode 643 of the third diode substrate 603′. In some embodiments, the lowest height value refers to the height value of the semi-finished diode substrate with the lowest height among a plurality of semi-finished diode substrates expected to be placed in the same panel structure 600. The manufacturing method includes grinding the electrode layers of each semi-finished substrate so that the semi-finished substrate reaches the lowest height value (step S6054). In this embodiment, the top surfaces of the first diode substrate 601′ and the second diode substrate 602′ both exceed the fourth reference line BL4. Therefore, the manufacturing method grinds both of them so that the height H61 is ground to the value of height H63, and the height H62 is also ground to the value of height H63. As shown in FIG. 24B, after step S6054, the values of height H61, height H62, and height H63 are substantially the same. Each bottom electrode 64 is ground so that the thickness D61 is greater than the thickness D63, and the thickness D63 is greater than the thickness D62.

In some embodiments, “substantially the same” may refer to sampling a plurality of diode dies 60 respectively formed on each diode substrate to obtain a plurality of sets of samples, and the heights of the diode dies 60 in each set of samples do not have significant differences (for example, based on a significance level of 5%). In other embodiments, “substantially the same” may refer to the allowable height variation between each diode substrate (diode die 60) being within the accuracy range of the grinding machine G6. In still other embodiments, “substantially the same” may refer to the allowable height variation between each diode substrate (diode die 60) being less than the allowable thickness variation between the bottom electrodes 64 of each diode substrate (diode die 60). For example, in this embodiment, if the thickness D61 is 100 μm and the thickness D62 is 80 μm, then the variation ratio between the thickness D61 and the thickness D62 is (100-80)/80, which is 25%. Therefore, when the height variation ratio between each diode substrate (diode die 60) is less than 25%, it can be considered substantially the same. It should be understood that the variation ratio exemplified in this embodiment is only an exemplary value for ease of explanation, and the actual height variation ratio should be defined according to the actual thickness variation ratio.

Based on the on, in step S6052, the manufacturing method includes comparing the height (first height) of one substrate with the height (second height) of another substrate. In some embodiments, the manufacturing method includes not performing the step of grinding the bottom electrode layer until the first height drops to the second height when it is determined that the second height is less than a specific lower limit height. For example, as shown in FIG. 24A, when the value of height H63 is less than the lower limit height but the value of height H62 is greater than the lower limit height, the grinding machine G6 does not perform the operation of grinding the height H61 of the first diode substrate 601′ to the value of height H63, nor does it perform the operation of grinding the height H62 of the second diode substrate 602′ to the value of height H63. However, the grinding machine G6 can perform the operation of grinding the height H61 of the first diode substrate 601′ to the value of height H62. The lower limit height can be defined according to the process requirements. For example, the lower limit height can be the sum of the dimensional specification parameters of the first substrate 61 and the epitaxial layer (epitaxial Layer) 63 in the semi-finished substrate, such as the sum of the upper limits of the acceptable thickness range, to avoid the bottom electrode 64 being completely ground away. Another example is that the lower limit height can be a value within the acceptable thickness specification range required for pre-aligning the diode die 60, such as the minimum acceptable thickness specification value, to allow the pre-alignment process to be performed on the diode die 60 produced from the diode substrate.

FIG. 25 is a schematic diagram of a panel structure according to some embodiments. Please refer to FIG. 25. The first diode substrate 601′ is processed into the first diode die 601 through the steps in FIG. 23, the second diode substrate 602′ is processed into the second diode die 602 through the steps in FIG. 23, and the third diode substrate 603′ is processed into the third diode die 603 through the steps in FIG. 23. In some embodiments, the manufacturing method includes transferring the first diode die 601, the second diode die 602, and the third diode die 603 to the third substrate 69 to form the panel structure 600. Based on this, in this embodiment, the panel structure 600 includes the first diode die 601, the second diode die 602, and the third diode die 603. The plurality of diode dies 60 on the panel structure 600 have substantially the same height. As shown in FIG. 25, the first reference line BL1 is disposed on the upper surface of the panel structure 600, and the second reference line BL2 is disposed on the upper surface of the top electrode 62 of the diode die 60. The first diode die 601, the second diode die 602, and the third diode die 603 have substantially the same height. However, the thickness D61 of the bottom electrode 64 of each diode die 60 is greater than the thickness D63, and the thickness D63 is greater than the thickness D62.

In some embodiments, the panel structure 600 includes a plurality of pixel structures. For example, the first diode die 601, the second diode die 602, and the third diode die 603 shown in FIG. 25 are located in the same pixel structure and correspond to red, green, and blue light respectively. The manufacturing method includes transferring a plurality of first diode dies 601 produced by processing the first diode substrate 601′ to each pixel structure on the panel structure 600, transferring a plurality of second diode dies 602 produced by processing the second diode substrate 602′ to each pixel structure on the panel structure 600, and transferring a plurality of third diode dies 603 produced by processing the third diode substrate 603′ to each pixel structure on the panel structure 600. Based on this, the thickness of the bottom electrodes 64 of the same type of diode dies 60 within each pixel structure is substantially the same. For example, the bottom electrodes 641 of the first diode dies 601 within each pixel structure all have a thickness D61, the bottom electrodes 642 of the second diode dies 602 all have a thickness D62, the bottom electrodes 643 of the third diode dies 603 all have a thickness D63, and the height of each diode die 60 is substantially the same.

Referring back to FIG. 1, in some embodiments, the pixel structure 50 includes a substrate 500, a plurality of vertical diode dies 520, flip-chip diode dies 530, and an upper circuit layer 540. In some embodiments, the vertical diode dies 520 or flip-chip diode dies 530 may face variations in production equipment or manufacturing technology during application, resulting in the problem of thickness differences between the diode dies. Although filling the gaps between the diode dies with filling materials to fix the diode dies can overcome this thickness difference problem, however, the existing filling technology still has the problem of poor flatness of the filling materials, causing open circuits between components and resulting in the micro-LED units being unable to emit light normally. In some embodiments, the vertical micro-LED structures, vertical micro-LED units, and their manufacturing methods in the following embodiments can be used to implement or be applied to the pixel structure 50. However, the present disclosure is not limited to this. Under different design considerations or application scenarios, other structures, processes, or manufacturing processes can be used to implement the pixel structure 50 disclosed in the present disclosure.

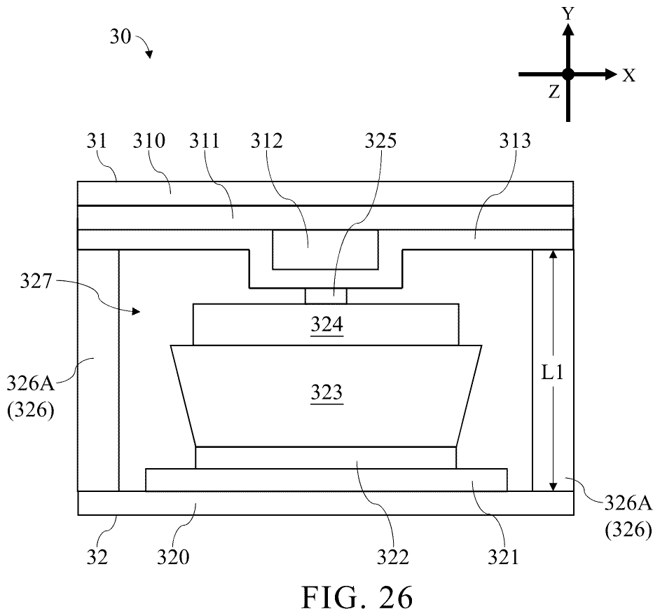

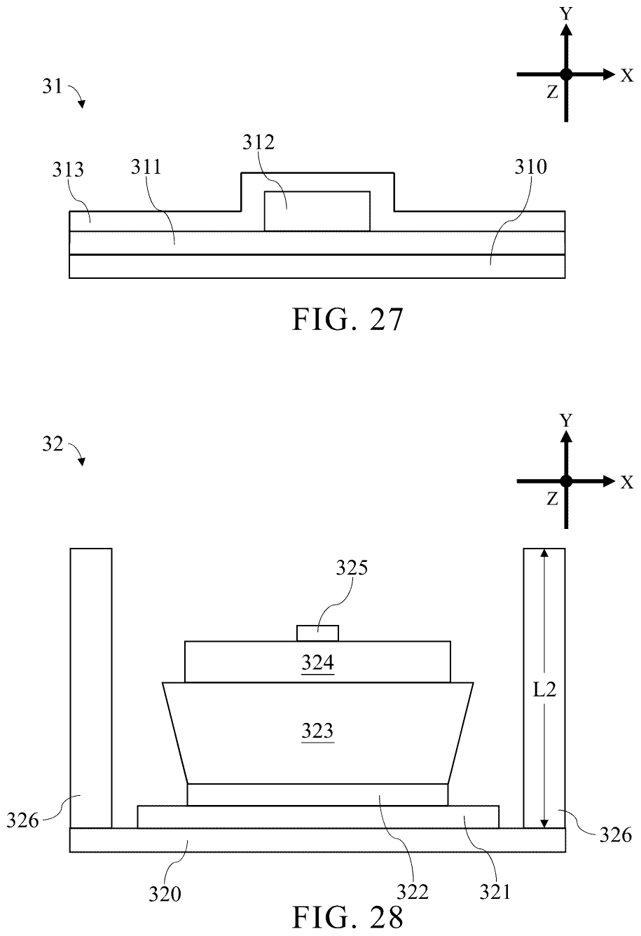

Please refer to FIGS. 26 to 31. FIG. 26 shows the vertical diode die 520 set in the accommodation site 551 in FIG. 1. Here, to facilitate the illustration of the connection relationship between the vertical diode die 520 and its surrounding components, the upper circuit layer 540 is enlarged and represented as the first circuit layer 311, and the lower circuit layer 510 is enlarged and represented as the second circuit layer 321. In this embodiment, a vertical micro-LED unit 30 includes a first backplane 31 and a second backplane 32. As shown in FIG. 27, the first backplane 31 includes a first substrate 310, a first circuit layer 311, a first contact pad 312, and a transparent electrode layer 313. The first circuit layer 311 is disposed on the first substrate 310. The first contact pad 312 is disposed on the first circuit layer 311. The transparent electrode layer 313 is disposed on the first circuit layer 311 and the first contact pad 312.

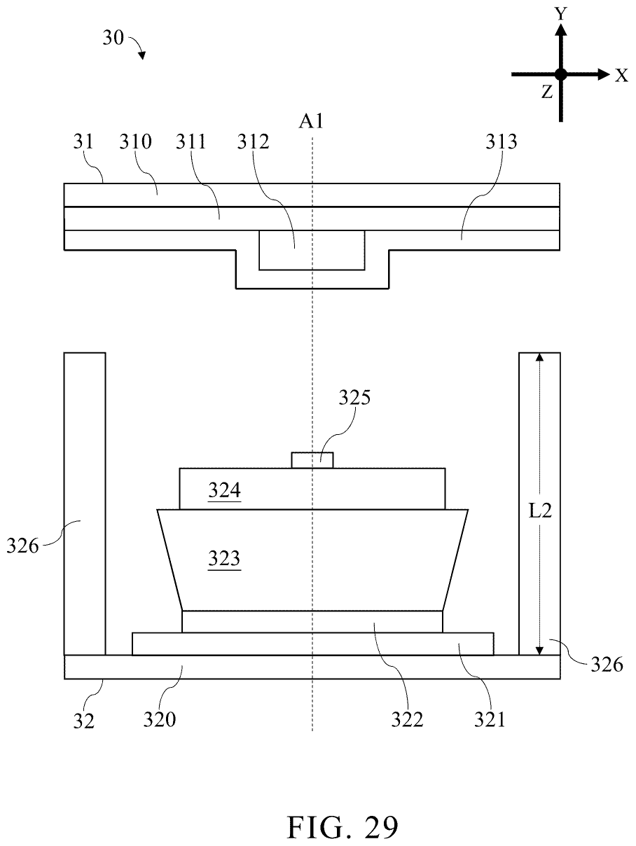

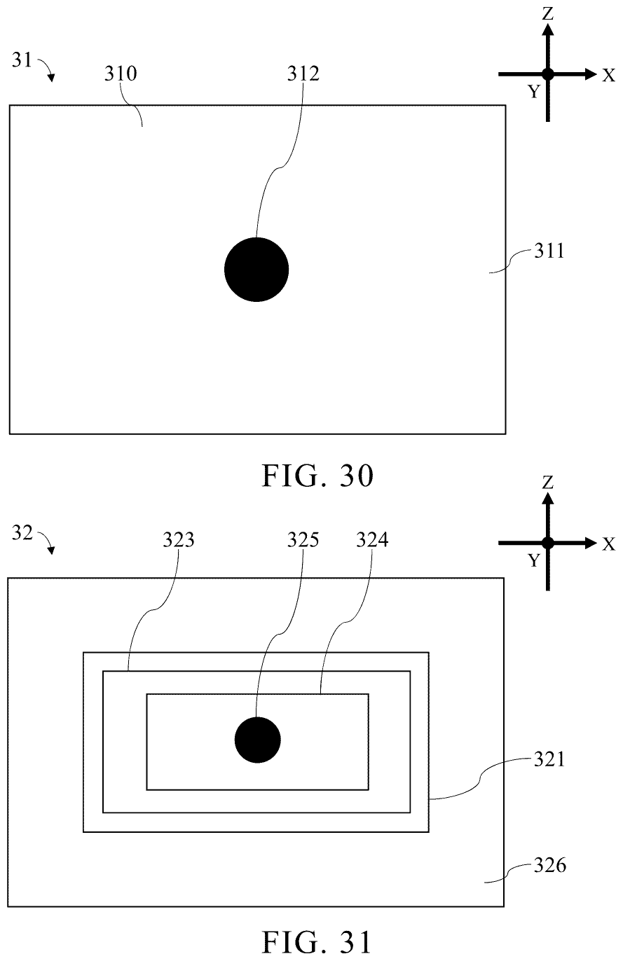

As shown in FIG. 28, the second backplane 32 includes a second substrate 320, a second circuit layer 321, a eutectic metal layer 322, an alloy layer 323, a micro-LED die 324, a second contact pad 325, and an isolation layer 326. The second circuit layer 321 is disposed on the second substrate 320. The eutectic metal layer 322 is disposed on the second circuit layer 321. The alloy layer 323 is disposed on the eutectic metal layer 322. The micro-LED die 324 is disposed on the alloy layer 323. The second contact pad 325 is disposed on the micro-LED die 324. The isolation layer 326 is disposed on the second substrate 320 to surround the micro-LED die 324. In other words, in some embodiments, the thickness L2 of the isolation layer 326 is greater than the sum of the thickness of the second circuit layer 321, the thickness of the eutectic metal layer 322, the thickness of the alloy layer 323, and the thickness of the micro-LED die 324, so that the isolation layer 326 can surround the micro-LED die 324.

As shown in FIGS. 26 and 29, the transparent electrode layer 313 of the first backplane 31 faces the second contact pad 325 and the isolation layer 326 of the second backplane 32 and is disposed on the second backplane 32, and a cavity 327 is formed between the first backplane 31 and the second backplane 32. In some embodiments, the cavity 327 is in a vacuum state to avoid the generation of water vapor in the vertical micro-LED unit 30, thereby preventing the water vapor from causing a short circuit between the components in the vertical micro-LED unit 30 and damaging them. In addition, in other embodiments, the cavity 327 can also be filled with an inert gas to achieve the same protective effect.

In some embodiments, the projected areas of the first contact pad 312 and the second contact pad 325 along the normal direction of the first backplane 31 at least partially overlap, and the transparent electrode layer 313 connects the second contact pad 325 and the isolation layer 326. Taking FIGS. 29 to 31 as an example, in this embodiment, the first contact pad 312 and the second contact pad 325 are coaxial A1 (as shown in FIG. 29), so that the projected areas of the first contact pad 312 and the second contact pad 325 along the axis A1 overlap (as shown in FIGS. 30 and 31).

In some embodiments, when the first backplane 31 is disposed on the second backplane 32, the isolation layer 326 is deformed such that the thickness L1 of the deformed isolation layer 326 is equal to the sum of the thickness of the first contact pad 312, the thickness of the second circuit layer 321, the thickness of the eutectic metal layer 322, the thickness of the alloy layer 323, the thickness of the micro-LED die 324, and the thickness of the second contact pad 325. In other words, in some embodiments, the thickness L2 of the isolation layer 326 before deformation (as shown in FIG. 28) is greater than the thickness L1 of the isolation layer 326 after deformation (as shown in FIG. 26).

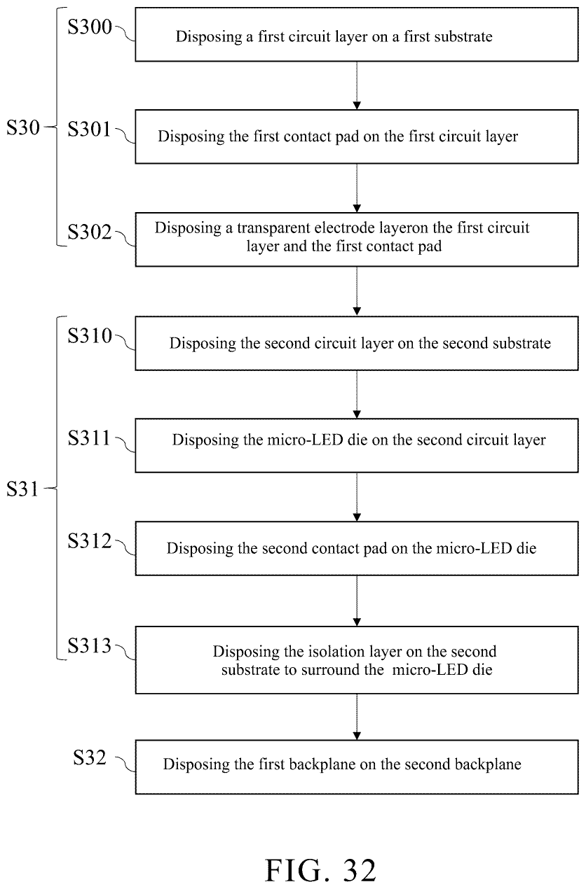

As shown in FIGS. 30 and 31, in some embodiments, the area of the first contact pad 312 is smaller than the area of the first circuit layer 311, the area of the first circuit layer 311 is smaller than the area of the micro-LED die 324, and the area of the second contact pad 325 is smaller than the area of the micro-LED die 324. Since the first circuit layer 311, the first contact pad 312, and the second contact pad 325 are all opaque, the areas of the first circuit layer 311, the first contact pad 312, and the second contact pad 325 all need to be smaller than the area of the micro-LED die 324 to avoid shielding the light emission of the micro-LED die 324. In addition, in some embodiments, the projected areas of the first circuit layer 311 and the isolation layer 326 along the normal direction of the first backplane 31 at least partially overlap. In other words, since a part of the first circuit layer 311 is disposed on the isolation layer 326, the first circuit layer 311 will not completely shield the light emission of the micro-LED die Please refer to FIGS. 26 to 32. The following takes FIGS. 26 to 31 as an example to illustrate the manufacturing process and steps of the vertical micro-LED unit 30. As shown in FIG. 32, when starting to manufacture the vertical micro-LED unit 30, the first backplane 31 and the second backplane 32 are individually formed (Steps S30, S31). It should be noted that the order between Step S30 of forming the first backplane 31 and Step S31 of forming the second backplane 32 can be exchanged. In other words, for the vertical micro-LED unit 30, the first backplane 31 can be formed first and then the second backplane 32 (as shown in FIG. 32), or the second backplane 32 can be formed first and then the first backplane 31.

As shown in FIG. 27, in Step S30 of forming the first backplane 31, the first circuit layer 311 is first disposed on the first substrate 310 (Step S300). In some embodiments, the material of the first substrate 310 is a light-transmitting insulating material, such as but not limited to glass, silicone, epoxy, polyimide (PI), benzocyclobutene (BCB), perfluorocyclobutane (PFCB), SU8 photoresist, acrylic resin, polyethylene terephthalate (PET), and polyetherimide. In some embodiments, the first circuit layer 311 can be disposed on the first substrate 310 through deposition techniques, where the deposition techniques are such as but not limited to sputtering technology, electron beam evaporation technology, chemical vapor deposition (CVD) technology, physical vapor deposition (PVD) technology, area selective deposition (ASD) technology, and atomic layer deposition (ALD) technology.

After Step S300, the first contact pad 312 is disposed on the first circuit layer 311 (Step S301), and then the transparent electrode layer 313 is disposed on the first circuit layer 311 and the first contact pad 312 (Step S302). Here, the first circuit layer 311, the first contact pad 312, and the transparent electrode layer 313 are electrically connected to each other. In some embodiments, the first contact pad 312 can be disposed on the first circuit layer 311 through screen printing technology, where the material of the first contact pad 312 is a conductive material, such as but not limited to gold, copper, and aluminum. In some embodiments, the transparent electrode layer 313 can be a transparent conductive film, such as but not limited to indium tin oxide (ITO), tin oxide (SnO₂), antimony tin oxide (ATO), conductive polymer (PEDOT), carbon nanotube (CNT), silver nanowire, and graphene.

As shown in FIG. 28, in step S31 of forming the second backplane 32, the second circuit layer 321 is first disposed on the second substrate 320 (step S310). In some embodiments, the material of the second substrate 320 may be an opaque insulating material, such as but not limited to silicon (Si), silicon dioxide (SiO₂), gallium arsenide (GaAs), and silicon carbide (SiC). In other embodiments, the material of the second substrate 320 may be the aforementioned light-transmitting insulating material.

After step S310, the micro-LED die 324 is disposed on the second circuit layer 321 (step S311), and then the second contact pad 325 is disposed on the micro-LED die 324 (step S312). Here, the second circuit layer 321, the micro-LED die 324, and the second contact pad 325 are electrically connected to each other. In some embodiments, the second contact pad 325 can be disposed on the second circuit layer 321 through screen printing technology, where the material of the second contact pad 325 is a conductive material, such as but not limited to gold, copper, and aluminum.

After step S312, the isolation layer 326 is disposed on the second substrate 320 to surround the micro-LED die 324 (step S313), where the isolation layer 326 can be disposed on the second substrate 320 through the aforementioned deposition technology. Finally, the transparent electrode layer 313 of the first backplane 31 faces the second contact pad 325 and the isolation layer 326 of the second backplane 32 and is disposed on the second backplane 32 (step S32) to complete the manufacture of the vertical micro-LED unit 30. At this time, a cavity 327 is formed between the first backplane 31 and the second backplane 32, and the projected areas of the first contact pad 312 and the second contact pad 325 in the normal direction of the first backplane 31 at least partially overlap. Among them, the transparent electrode layer 313 is connected to the second contact pad 325, so that the first circuit layer 311 is electrically connected to the second circuit layer 321. Here, the first circuit layer 311 and the second circuit layer 321 can be used as the two electrodes (including the P pole and the N pole) of the vertical micro-LED unit 30.

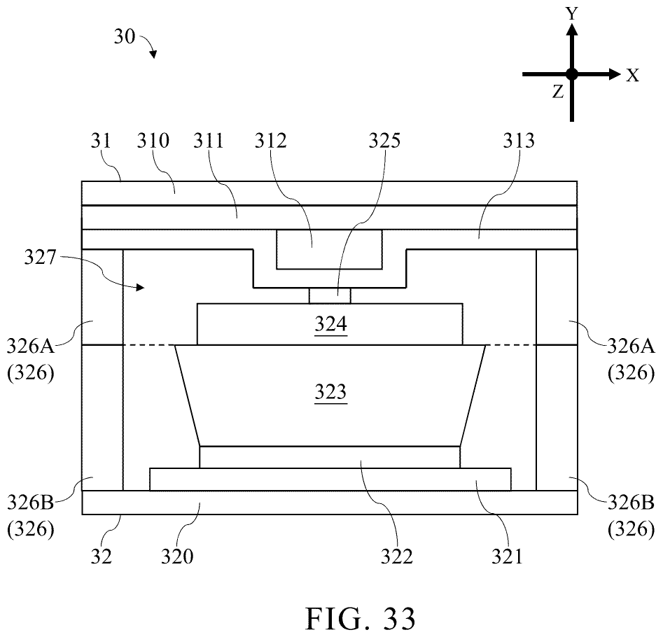

Please refer to FIGS. 26 and 33. As shown in FIG. 26, in some embodiments, the isolation layer 326 includes an opaque material 326A (as shown in FIG. 26). In other embodiments, the isolation layer 326 includes an opaque material 326A and a light-transmissive material 326B (as shown in FIG. 33). In some embodiments, the isolation layer 326 is used to prevent the light emitted by the micro-LED die 324 from interfering with the adjacent micro-LED die 324. Therefore, the opaque material 326A only needs to surround the micro-LED die 324. In some embodiments, the opaque material 326A can be a black matrix (BM) material or a light-reflective material, such as but not limited to bauxite, dielectric multilayer films, and reflective resin materials. In some embodiments, the light-transmissive material 326B is, for example but not limited to, silicone, epoxy resin, polyimide, benzocyclobutene, perfluorocyclobutane, SU8 photoresist, acrylic resin, polyethylene terephthalate, and polyetherimide. It should be noted that since the isolation layer 326 is plastic, the opaque material 326A in the isolation layer 326 is only used to make the isolation layer 326 opaque without affecting the plasticity of the isolation layer 326.

In some embodiments, the micro-LED die 324 is disposed on the second circuit layer 321 through mass transfer technology. It should be noted that when the micro-LED die 324 is disposed on the second circuit layer 321 through mass transfer, a eutectic metal layer 322 and an alloy layer 323 need to be pre-disposed on the second circuit layer 321 (as shown in FIGS. 26, 28, and 29) as a carrier for the mass transfer of the micro-LED die 324, so that the micro-LED die 324 can be disposed on the second circuit layer 321 and electrically connected to it. Among them, the eutectic metal layer 322 is used to align the micro-LED die 324 in advance to the set position, and the alloy layer 323 is used to bond the micro-LED die 324. In some embodiments, the shape of the alloy layer 323 is a trapezoid, where the upper base of the trapezoid is connected to the eutectic metal layer 322, and the lower base of the trapezoid is connected to the micro-LED die 324. In other words, the longer of the two parallel bases of the trapezoid is connected to the micro-LED die 324.

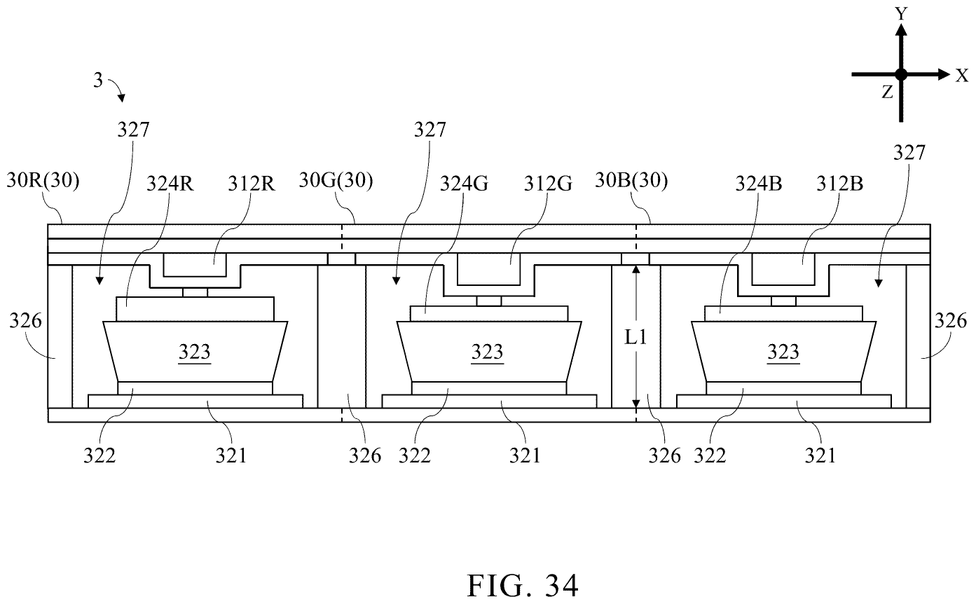

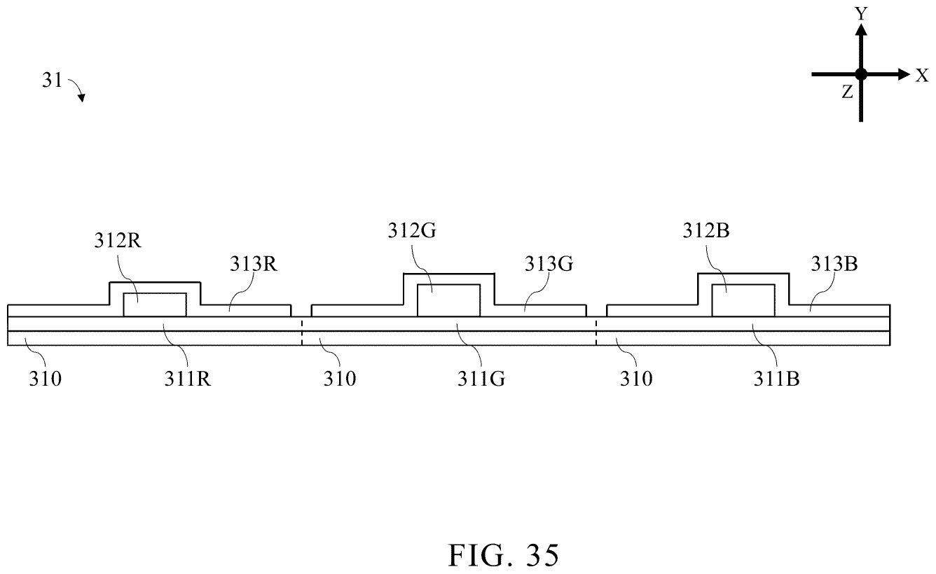

Please refer to FIGS. 34 and 35. In some embodiments, a plurality of vertical micro-LED units 30 can form a vertical micro-LED structure 3. Taking FIG. 34 as an example, in this embodiment, the vertical micro-LED structure 3 includes three vertical micro-LED units 30 (for the convenience of explanation, hereinafter referred to as the first micro-LED unit 30R, the second micro-LED unit 30G, and the third micro-LED unit 30B respectively). Among them, the micro-LED die 324R of the first micro-LED unit 30R is a red micro-LED die, the micro-LED die 324G of the second micro-LED unit 30G is a green micro-LED die, and the micro-LED die 324B of the third micro-LED unit 30B is a blue micro-LED die.

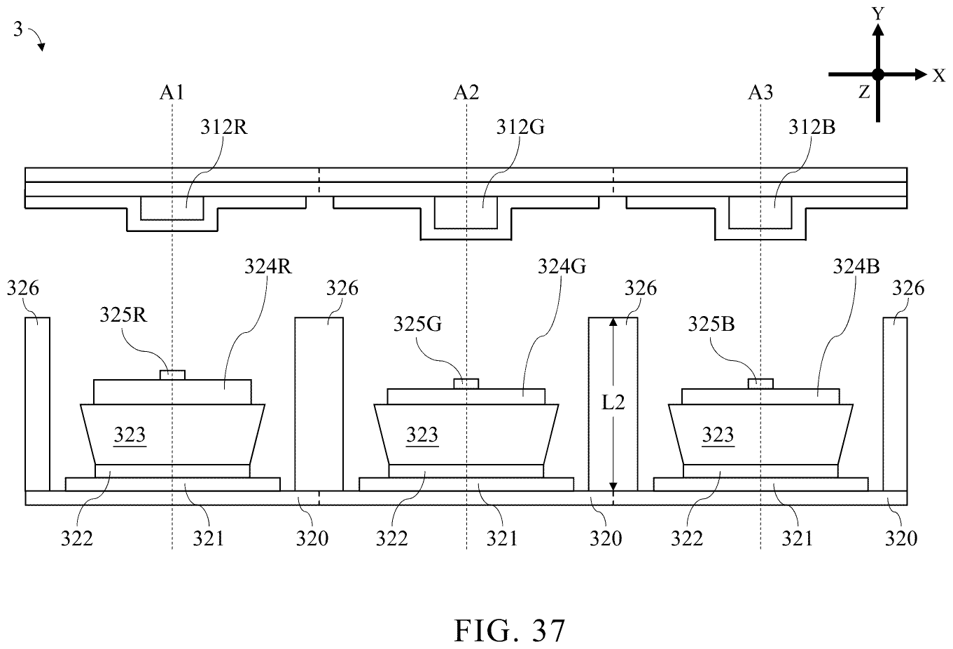

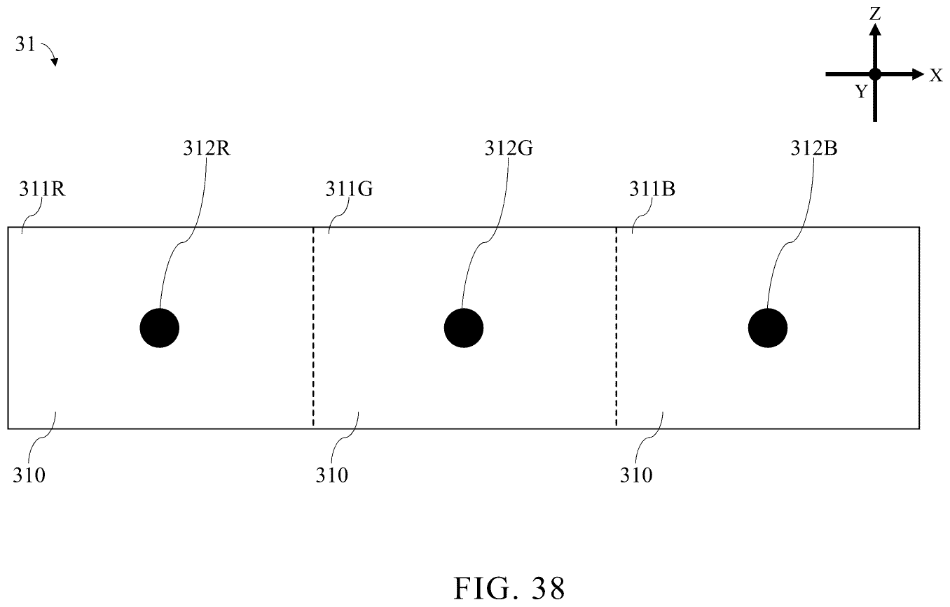

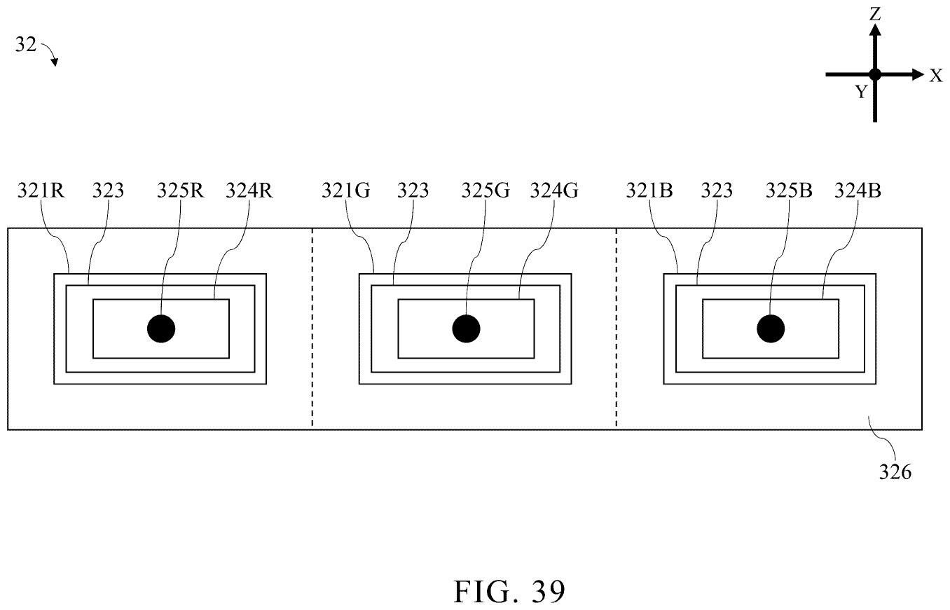

In some embodiments, the projection areas of the first contact pads 312R, 312G, 312B and the second contact pads 325R, 325G, 325B in the normal direction of the first backplane 31 at least partially overlap, and each transparent electrode layer 313R, 313G, and 313B connects the corresponding second contact pad 325R,325G, and 325B and the isolation layer 326. Taking FIGS. 37 to 39 as an example, in this embodiment, the first contact pad 312R and the second contact pad 325R are coaxial with axis A1 (as shown in FIG. 37), so that the projection areas of the first contact pad 312R and the second contact pad 325R along axis A1 overlap (as shown in FIGS. 38 and 39); the first contact pad 312G and the second contact pad 325G are coaxial with axis A2 (as shown in FIG. 37), so that the projection areas of the first contact pad 312G and the second contact pad 325G along axis A2 overlap (as shown in FIGS. 38 and 39); the first contact pad 312B and the second contact pad 325B are coaxial with axis A3 (as shown in FIG. 37), so that the projection areas of the first contact pad 312B and the second contact pad 325B along axis A3 overlap (as shown in FIGS. 38 and 39).

In some embodiments, the vertical micro-LED structure 3 can be applied to a micro-LED display device. Among them, the vertical micro-LED structure 3 constitutes a pixel in the micro-LED display device, and the first micro-LED unit 30R, the second micro-LED unit 30G, and the third micro-LED unit 30B are each a sub-pixel. In some embodiments, any one of the first micro-LED unit 30R, the second micro-LED unit 30G, and the third micro-LED unit 30B is adjacent to at least one of the other two. In other words, each sub-pixel in a single pixel of the micro-LED display device is adjacent to at least one of the other two sub-pixels. If two adjacent sub-pixels belong to different pixels, they are not the “adjacent” described here.

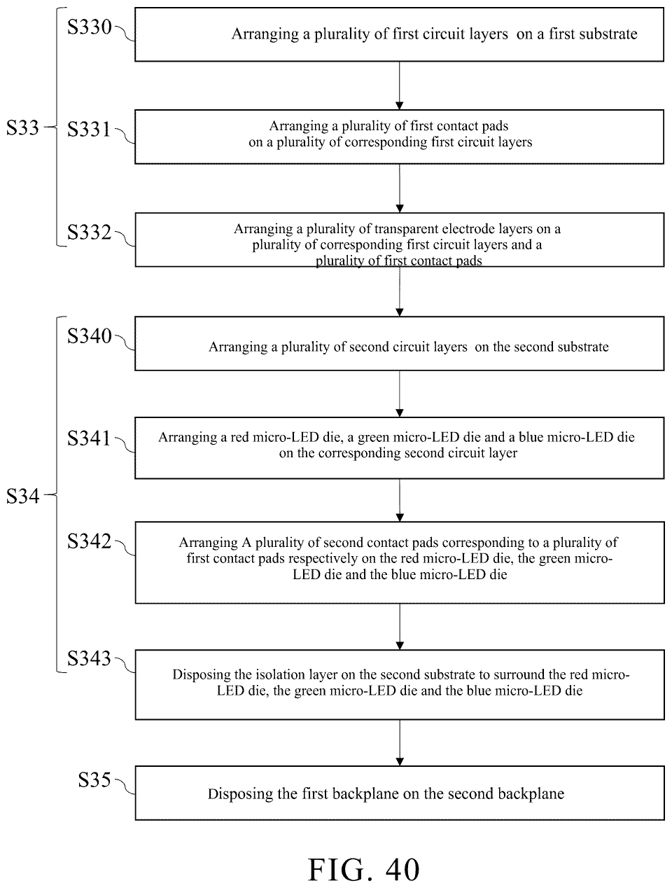

Please refer to FIGS. 26 to 31 and FIGS. 34 to 40. The following takes FIGS. 26 to 31 and FIGS. 34 to 39 as examples to illustrate the manufacturing process and steps of the vertical micro-LED structure 3. As shown in FIG. 40, when starting to manufacture the vertical micro-LED structure 3, the first backplane 31 and the second backplane 32 are formed respectively (steps S33, S34). It should be noted that the order between step S33 of forming the first backplane 31 and step S34 of forming the second backplane 32 can be exchanged. In other words, for the vertical micro-LED structure 3, the first backplane 31 can be formed first and then the second backplane 32 (as shown in FIG. 40), or the second backplane 32 can be formed first and then the first backplane 31.

As shown in FIG. 35, in step S33 of forming the first backplane 31, a plurality of first circuit layers 311 are first disposed on the first substrate 310 (step S330). In other words, the respective first circuit layers 311R, 311G, and 311B of the vertical micro-LED units 30R,30G, 30B are disposed on the same first substrate 310. It should be noted that the first circuit layers 311R, 311G, and 311B are only adjacently disposed on the first substrate 310, and there is no electrical connection between the first circuit layers 311R, 311G, and 311B.

After step S330, a plurality of first contact pads 312R, 312G, 312B are disposed on the corresponding a plurality of first circuit layers 311R, 311G, and 311B (step S331). Subsequently, a plurality of transparent electrode layers 313R, 313G, 313B are disposed on the corresponding a plurality of first circuit layers 311 and a plurality of first contact pads 312R, 312G, 312B (step S332). Among them, there are intervals between the plurality of first contact pads 312R, 312G, 312B, and there are also intervals between the plurality of transparent electrode layers 313R, 313G, 313B (as shown in FIG. 35). Here, the first circuit layer 311R, the first contact pad 312R, and the transparent electrode layer 313R are electrically connected to each other. The first circuit layer 311G, the first contact pad 312G, and the transparent electrode layer 313G are electrically connected to each other. And the first circuit layer 311B, the first contact pad 312B, and the transparent electrode layer 313B are electrically connected to each other.

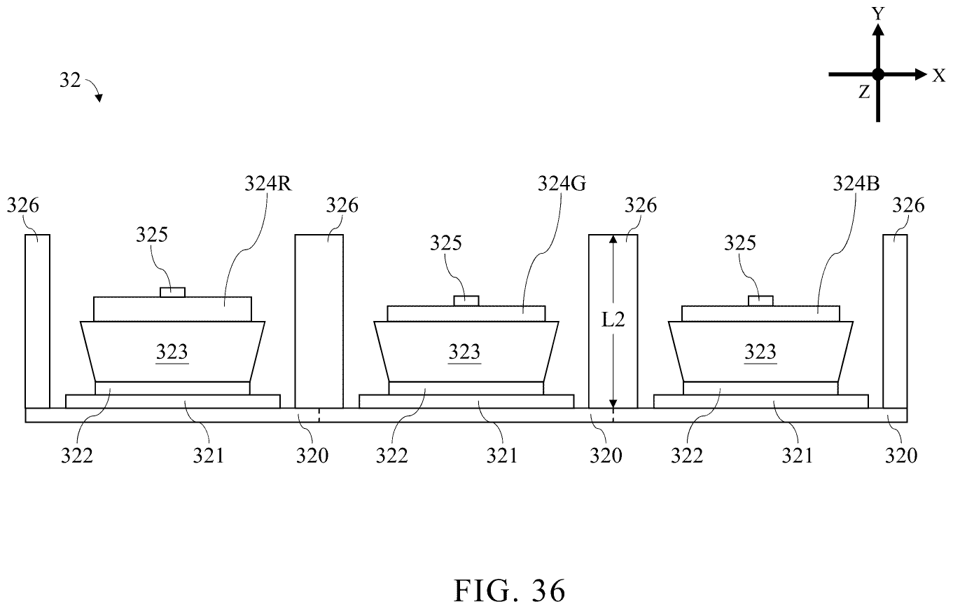

As shown in FIG. 36, in step S34 of forming the second backplane 32, a plurality of second circuit layers 321R, 321G, 321B are first disposed on the second substrate 320 (step S340). Similar to the first backplane 31, the respective second circuit layers 321R, 321G, 321B of the vertical micro-LED units 30R, 30G, 30B are disposed on the same second substrate 320, and there are intervals between the plurality of second circuit layers 321R, 321G, 321B.

After step S340, the red micro-LED dies 324R, the green micro-LED dies 324G, and the blue micro-LED dies 324B are disposed on the corresponding second circuit layers 321R, 321G, 321B (step S341). Subsequently, a plurality of second contact pads 325R, 325G, 325B are respectively disposed on the red micro-LED dies 324R, the green micro-LED dies 324G, and the blue micro-LED dies 324B (step S342), where each second contact pad 325R, 325G, 325B corresponds to each first contact pad 312R, 312G, 312B. Here, the micro-LED dies 324 are electrically connected to the second circuit layer 321 and the second contact pads 325.

After step S342, an isolation layer 326 is disposed on the second substrate 320 to surround the red micro-LED dies 324R, the green micro-LED dies 324G, and the blue micro-LED dies 324B (step S343). Finally, the plurality of transparent electrode layers 313R, 313G, 313B of the first backplane 31 face the plurality of second contact pads 325R, 325G, 325B and the isolation layer 326 of the second backplane 32 and are disposed on the second backplane 32 (step S35) to complete the fabrication of the vertical micro-LED structure 3. At this time, a plurality of cavities 327 are formed between the first backplane 31 and the second backplane 32, and the projected areas of each of the first contact pads 312R, 312G, 312B and each of the second contact pads 325R, 325G, 325B in the normal direction of the first backplane 31 at least partially overlap. Among them, each of the transparent electrode layers 313R, 313G, 313B is connected to the corresponding second contact pads 325R, 325G, 325B, so that each of the first circuit layers 311R, 311G, 311B is electrically connected to the corresponding second circuit layers 321R, 321G, 321B respectively. Here, the paired first circuit layer 311 and second circuit layer 321 can each be used as the two electrodes (including the P pole and the N pole) of the vertical micro-LED units 30R, 30G, 30B.

It should be noted that the thickness of the red micro-LED dies 324R is greater than the thickness of the green micro-LED dies 324G and the thickness of the blue micro-LED dies 324B, and the thickness of the green micro-LED dies 324G is approximately equal to the thickness of the blue micro-LED dies 324B. Therefore, in some embodiments, the thickness of the first contact pad 312G and the thickness of the first contact pad 312B are greater than the thickness of the first contact pad 312R, so that the first backplane 31 can be stably disposed on the second backplane 32.

Similar to the manufacturing process of the vertical micro-LED unit 30, in some embodiments, the micro-LED dies 324R, 324G, and 324B are respectively disposed on the second circuit layer 321 through mass transfer technology. Moreover, when the micro-LED dies 324R, 324G, and 324B are respectively disposed on the corresponding second circuit layers 321R, 321G, 321B through mass transfer, a eutectic metal layer 322 and an alloy layer 323 (as shown in FIGS. 34, 36, and 37) need to be first disposed on the second circuit layers 321R, 321G, and 321B as carriers for the mass transfer of each micro-LED die 324R, 324G, and 324B. Only in this way can the micro-LED dies 324R, 324G, and 324B be disposed on the corresponding second circuit layers 321R, 321G, and 321B and electrically connected thereto.

According to any embodiment, using a structure with double backplanes (i.e., the first backplane and the second backplane) to combine and manufacture micro-LEDs can avoid various problems caused by the current filling technology. In addition, adjusting the thickness of the contact pads according to the die thickness of micro-LEDs of different emission colors so that the contact pads on the top surface of each micro-LED unit are located on the same plane as much as possible also enables the micro-LEDs to avoid the problem of electrode open circuits, thereby improving the yield rate during the manufacturing of micro-LEDs and the reliability of the micro-LEDs themselves.

Referring back to FIG. 1, in some embodiments, the pixel structure 50 includes a substrate 500, a plurality of vertical diode dies 520, flip-chip diode dies 530, and an upper circuit layer 540. In some embodiments, when the pixel structure 50 is applied, it may face the problem that the mass transfer technology cannot accurately and effectively move a large number of vertical diode dies 520 or flip-chip diode dies 530, which causes a bottleneck in the manufacturing process of the panel structure. Also referring to FIG. 21, in some embodiments, the vertical diode die 520 can adopt the structure of a diode die 60. The diode die 60 includes a top electrode 62, an epitaxial layer 63, a bottom electrode 64, and a conductor layer 68. The bottom electrode 64 can be a trapezoidal structure to facilitate the pre-alignment of the diode die 60 before transfer, so that a large number of diode dies 60 can be effectively transferred. In some embodiments, the pre-alignment device and pre-alignment method in the following embodiments can be used for the transfer of the vertical diode die 520 or the flip-chip diode die 530. However, the present disclosure is not limited to this. Under different design considerations or application scenarios, other structures, processes, or manufacturing methods can be used to process the vertical diode die 520 or the flip-chip diode die 530 disclosed in the present disclosure.

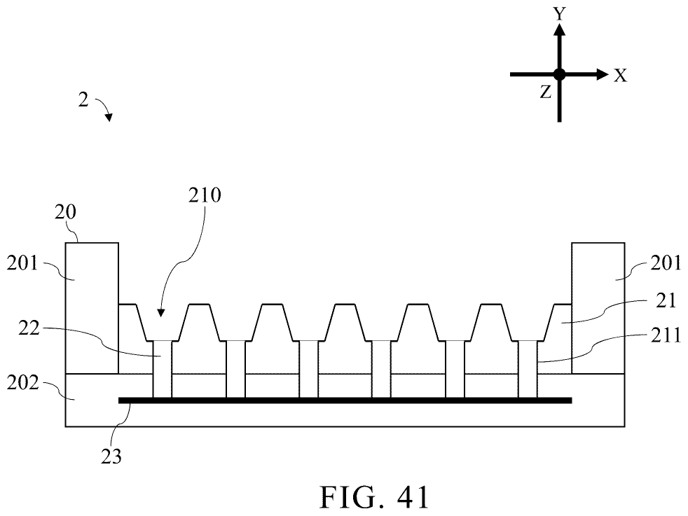

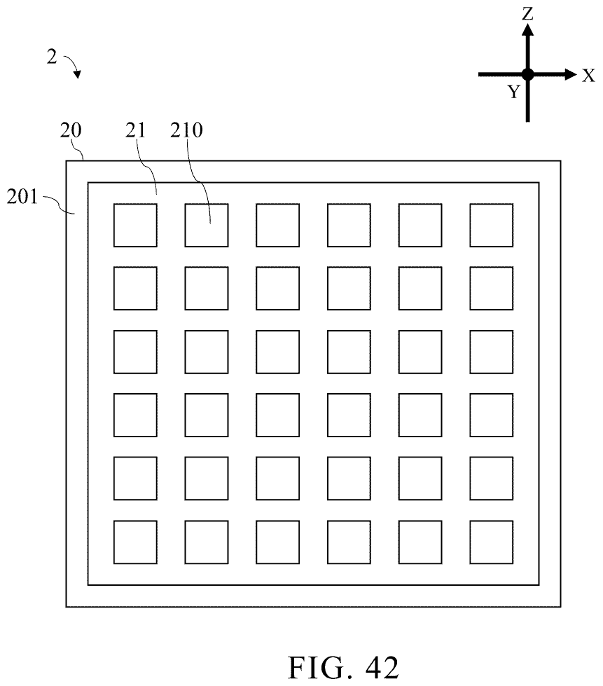

Please refer to FIGS. 41 and 42. A pre-alignment device 2 includes a vibrating machine 20, an alignment tray 21, a plurality of electromagnets 22, and a controller 23. The vibrating machine 20 includes a plurality of side walls 201 and a base plate 202, and the plurality of side walls 201 are disposed around the base plate 202 (as shown in FIG. 42). The alignment tray 21 is disposed on the base plate 202 and includes a plurality of grooves 210 disposed in an array, and the bottom of each groove 210 includes a through hole 211. Taking FIG. 42 as an example, in this embodiment, the alignment tray 21 includes 36 grooves 210 disposed in an array with 6 rows and 6 columns.

Each electromagnet 22 is disposed in each through-hole 211, and each electromagnet 22 is used to generate a magnetic field along the extending direction of the through-hole 211. Taking FIG. 41 as an example, in this embodiment, the extending direction of the through-hole 211 is the Y direction. Here, each electromagnet 22 generates a magnetic field along the Y direction. The controller 23 is electrically connected to the plurality of electromagnets 22, and the controller 23 is used to control each electromagnet 22 to generate a magnetic field. In other words, in some embodiments, each electromagnet 22 can be independently controlled. Therefore, when the controller 23 controls all the electromagnets 22 to be energized to generate a magnetic field, the magnitudes of the magnetic fields generated by each electromagnet 22 are the same, so that each through-hole 211 in the alignment tray 21 has a magnetic field of the same magnitude.

In some embodiments, the electromagnet 22 is a wire coil comprising at least one turn. In addition, in this embodiment, the electromagnet 22 further comprises a columnar body (such as but not limited to a cylinder, a triangular prism, a quadrangular prism, or a polygonal prism) made of a magnetically conductive material, and at least one wire coil in the electromagnet 22 surrounds this columnar body to magnetize this columnar body, thereby enhancing the strength of the magnetic field generated by the electromagnet 22. The magnetically conductive material of this columnar body is, for example but not limited to, iron (Fe), cobalt (Co), nickel (Ni), chromium (Cr), molybdenum (Mo), and alloys containing at least two of the on materials.

In some embodiments, the controller 23 can be a circuit module integrated in the vibrating machine 20 and having a control function. Taking FIG. 41 as an example, in this embodiment, the controller 23 is a circuit layer and is disposed in the base plate 202 of the vibrating machine 20. In other embodiments, the controller 23 can also be a hardware component (not shown in the figure) independent of the pre-alignment device 2 and having a control function, such as but not limited to a central processing unit (CPU), a microprocessor, a digital signal processor (DSP), a complex programmable logic device (CPLD), a field programmable gate array (FPGA), an application specific integrated circuit (ASIC), or a microcontroller unit (MCU).

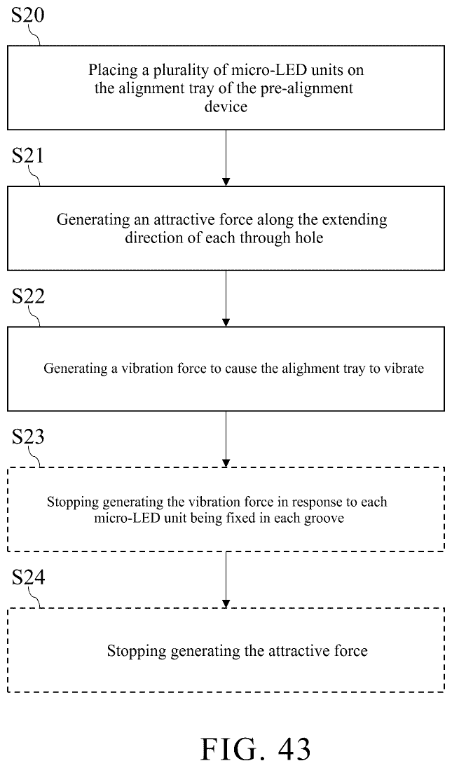

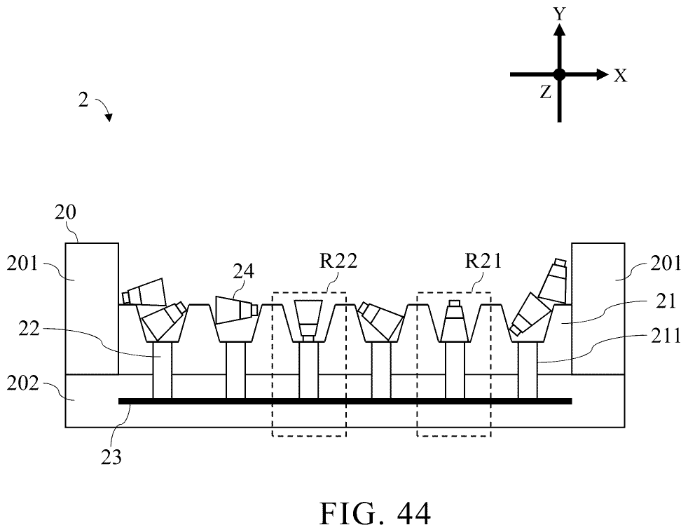

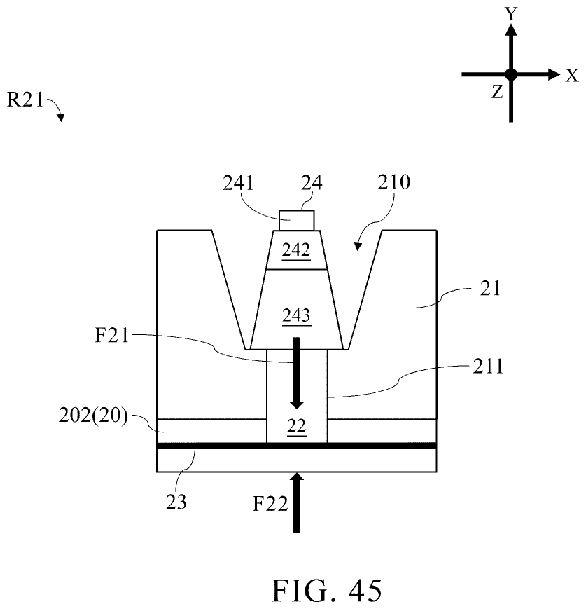

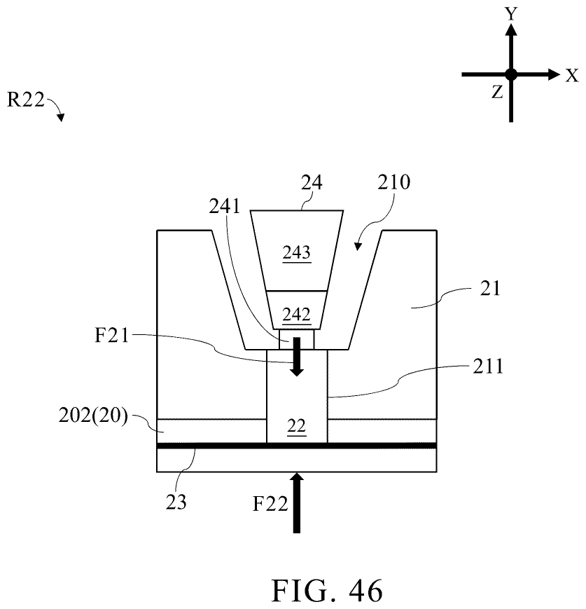

Please refer to FIGS. 41 to 46. FIGS. 45 and 46 are enlarged schematic diagrams of a single groove 210 in the dotted box R21 and a single groove 210 in the dotted box R22 in FIG. 44, respectively. The following takes the pre-alignment device 2 shown in FIG. 41 as an example to illustrate the pre-alignment method of a plurality of micro-LED units 24, but this is not intended to limit the device, hardware components, or software components for executing the pre-alignment method. When the pre-alignment device 2 starts to pre-align a plurality of micro-LED units 24, the user can place a plurality of micro-LED units 24 on the alignment tray 21 of the pre-alignment device 2 (Step S20). Taking FIG. 44 as an example, in this embodiment, a plurality of scattered micro-LED units 24 are randomly placed on the alignment tray 21.

After Step S20, the pre-alignment device 2 generates an attractive force F21 along the extension direction of each through-hole 211 (Step S21), and the pre-alignment device 2 generates a vibration force F22 through the vibrating machine 20 to make the alignment tray 21 vibrate (Step S22). In some embodiments, when the alignment tray 21 starts to vibrate, each micro-LED unit 24 vibrates accordingly and moves into each groove 210 of the alignment tray 21. As shown in FIG. 45 or FIG. 46, in this embodiment, since the pre-alignment device 2 generates an attractive force F21 along the extension direction of each through-hole 211, the direction of the force exerted by the attractive force F21 is parallel to the Y direction. In addition, the direction of the force exerted by the vibration force F22 generated by the vibrating machine 20 is also parallel to the Y direction, and the direction of the force exerted by the vibration force F22 is opposite to the direction of the force exerted by the attractive force F21. Here, in some embodiments, the attractive force F21 generated by the pre-alignment device 2 and the vibration force F22 generated by the vibrating machine 20 can offset each other. When the attractive force F21 is greater than the vibration force F22, the vibration force F22 is eliminated and only the attractive force F21 acts; when the attractive force F21 is less than the vibration force F22, the attractive force F21 is eliminated and only the vibration force F22 acts.

In some embodiments, when the attractive force F21 is greater than the vibration force F22 (as shown in FIG. 45), the micro-LED units 24 that have moved into the grooves 210 are fixed in each groove 210 under the action of the attractive force F21. In other embodiments, when the attractive force F21 is less than the vibration force F22 (as shown in FIG. 46), the micro-LED units 24 that have moved into the grooves 210 are detached from each groove 210 under the action of the vibration force F22. Here, through the interaction between the attractive force F21 and the vibration force F22, each micro-LED unit 24 can gradually move into each groove 210 to be arranged in another array, where the other array corresponds to the array formed by the arrangement of a plurality of grooves 210. Taking FIG. 42 as an example, in this embodiment, since the alignment tray 21 shown in FIG. 42 contains 36 grooves, the pre-alignment device 2 shown in FIG. 42 can arrange 36 micro-LED units on the same plane and neatly through the pre-alignment method.

In some embodiments, the thickness of the alignment tray 21 is less than the height of each side wall 201. Here, when the alignment tray 21 starts to vibrate, even if the attractive force F21 received by the micro-LED units 24 is less than the vibration force F22, the micro-LED units 24 can be blocked by the side walls 201 around the vibrating machine 20 and will not be detached from the pre-alignment device 2 under the action of the vibration force F22.

In some embodiments, the attractive force F21 generated by the pre-alignment device 2 in step S22 is a magnetic attraction force or a vacuum suction force. Taking FIG. 45 and FIG. 46 as an example, in this embodiment, the attractive force F21 generated by the pre-alignment device 2 is a magnetic attraction force. Here, the pre-alignment device 2 includes hardware components for generating a magnetic field, such as but not limited to the electromagnet 22. In addition, in this embodiment, each micro-LED unit 24 needs to have magnetic conductivity so that the magnetic field generated by the electromagnet 22 can generate a magnetic attraction force (i.e., the attractive force F21) on each micro-LED unit 24. Therefore, in some embodiments, each micro-LED unit 24 includes a micro-LED die 241, a carrier layer 242, and a magnetic conductive layer 243 (as shown in FIG. 45 and FIG. 46).

In some embodiments, the carrier layer 242 is disposed on the magnetic conductive layer 243, and the micro-LED die 241 is disposed on the carrier layer 242. The shapes of both the carrier layer 242 and the magnetic conductive layer 243 are trapezoidal, and the width of the bottom of the magnetic conductive layer 243 is smaller than the width of the bottom of each groove 210. Taking FIG. 45 as an example, in this embodiment, the micro-LED die 241 is disposed on the upper base of the carrier layer 242, and the carrier layer 242 is disposed on the upper base of the magnetic conductive layer 243. The width of the lower base of the carrier layer 242 is equal to the width of the upper base of the magnetic conductive layer 243, and the width of the lower base of the magnetic conductive layer 243 is smaller than the width of the bottom of each groove 210.

In some embodiments, the material of the carrier layer 242 has electrical conductivity and non-magnetic conductivity, such as but not limited to aluminum (A1), copper (Cu), and their alloys. In some embodiments, the material of the magnetic conductive layer 243 has magnetic conductivity, such as but not limited to iron, cobalt, nickel, chromium, molybdenum, and alloys containing at least two of the above materials.

In some embodiments, the material of the alignment tray 21 is a non-magnetic insulating material, such as but not limited to glass, silicone, epoxy resin, polyimide (PI), benzocyclobutene (BCB), perfluorocyclobutane (PFCB), SU8 photoresist, acrylic resin, polyethylene terephthalate (PET), polyetherimide, silicon (Si), silicon dioxide (SiO₂), gallium arsenide (GaAs), and silicon carbide (SiC). Here, the pre-alignment device 2 can ensure that the magnetic attractive force generated by each electromagnet 22 will not act on the alignment tray 21.

In some embodiments, when each micro-LED unit 24 moves into each groove 210, the setting direction of each micro-LED unit 24 determines the magnitude of the attractive force F21. Taking FIG. 45 as an example, in this embodiment, the micro-LED unit 24 is disposed in the groove 210 with the micro-LED die 241 facing upward. At this time, the magnetic conductive layer 243 with magnetic conductivity directly contacts the bottom of the groove 210; taking FIG. 46 as an example, in this embodiment, the micro-LED unit 24 is disposed in the groove 210 with the magnetic conductive layer 243 facing upward. At this time, the micro-LED die 241 without magnetic conductivity directly contacts the bottom of the groove 210.

In some embodiments, since the distance between the magnetically conductive layer 243 with magnetic properties in the micro-LED unit 24 shown in FIG. 45 and the electromagnet 22 is smaller than the distance between the magnetically conductive layer 243 with magnetic properties in the micro-LED unit 24 shown in FIG. 46 and the electromagnet 22, the attractive force F21 (i.e., magnetic attraction) received by the micro-LED unit 24 shown in FIG. 45 is greater than the attractive force F21 (i.e., magnetic attraction) received by the micro-LED unit 24 shown in FIG. 46. Here, in some embodiments, the user can adjust the value of the vibration force F22 generated by the vibrating machine 20 in the pre-alignment device 2 to be between the value of the attractive force F21 shown in FIG. 45 and the value of the attractive force F21 shown in FIG. 46, so that the micro-LED units 24 have different force effects when moving into the grooves 210 in different setting directions.

Taking FIG. 45 as an example, in this embodiment, when the micro-LED unit 24 is placed in the groove 210 with the micro-LED die 241 facing upwards, the attractive force F21 received by the micro-LED unit 24 is greater than the vibration force F22, so that the micro-LED unit 24 is fixed in each groove 210 under the action of the attractive force F21. Taking FIG. 46 as an example again, in this embodiment, when the micro-LED unit 24 is placed in the groove 210 with the magnetically conductive layer 243 facing upwards, the attractive force F21 received by the micro-LED unit 24 is less than the vibration force F22, so that the micro-LED unit 24 is detached from the groove 210 under the action of the vibration force F22. Here, when the pre-alignment device 2 completes the pre-alignment of a plurality of micro-LED units 24, it means that all the micro-LED units 24 are fixed in the grooves 210 with the micro-LED dies 241 facing upwards, so that all the micro-LED units 24 face the same side upwards.

In some embodiments, after step S22, when each micro-LED unit 24 is fixed in each groove 210, it means that the pre-alignment device 2 has pre-aligned all the micro-LED units 24. At this time, the pre-alignment device 2 first stops generating the vibration force F22 (step S23) so that the micro-LED units 24 are fixed in the grooves 210 only under the action of the attractive force F21, thereby preventing the micro-LED units 24 from detaching from the grooves 210. Subsequently, the pre-alignment device 2 stops generating the attractive force F21 (step S24) so that the micro-LED units 24 are no longer adsorbed by the attractive force F21 and can move. At this time, the user can then perform mass transfer on the micro-LED units 24.

In some embodiments, the height of each micro-LED unit 24 is greater than the depth of each groove 210. In other words, when the micro-LED unit 24 is placed in the groove 210, the micro-LED unit 24 protrudes from the top surface of the groove 210 (as shown in FIG. 45 or FIG. 46). Here, during the process of the pre-alignment device 2 performing the pre-alignment method, when each micro-LED unit 24 is not fixed in each groove 210, each micro-LED unit 24 can be easily detached from each groove 210 without being blocked by the wall surface of each groove 210. In addition, when the pre-alignment device 2 finishes performing the pre-alignment method and the user starts to perform mass transfer on the micro-LED units 24, the micro-LED units 24 can be easily moved without being stuck in the grooves 210.

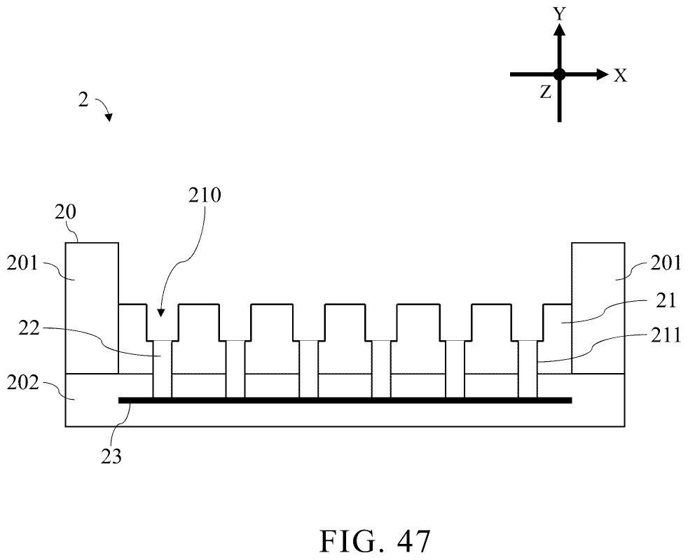

Please refer to FIG. 41 and FIG. 47. As shown in FIG. 41, in some embodiments, the shape of each groove 210 can be a trapezoid, and the width of the bottom of each groove 210 is smaller than the width of the top surface of each groove 210. In other words, the bottom of each groove 210 corresponds to the upper base of this trapezoid, and the top surface of each groove 210 corresponds to the lower base of this trapezoid. Here, when the micro-LED unit 24 moves into the groove 210 and the attractive force F21 is greater than the vibration force F22, the micro-LED unit 24 can be stably fixed in the groove 210. Moreover, the trapezoidal shape can ensure that the micro-LED units 24 that are not yet fixed in the grooves 210 can be easily detached from the grooves 210 during vibration.

As shown in FIG. 47, in other embodiments, each groove 210 can also be rectangular. Here, when the micro-LED unit 24 moves into the groove 210 and the attractive force F21 is greater than the vibration force F22, the micro-LED unit 24 can be stably fixed in the groove 210. Moreover, the rectangular shape can ensure that the micro-LED units 24 that are already fixed in the grooves 210 will not be easily detached from the grooves 210 during vibration.

According to any embodiment, the pre-alignment device and the pre-alignment method can arrange scattered micro-LED units on the same side and neatly, enabling the mass transfer technology to accurately and effectively move a large number of micro-LED units. In addition, regardless of whether the micro-LED units are magnetic or not, the pre-alignment method can generate corresponding attractive forces (such as but not limited to magnetic attraction or vacuum suction) to fix the micro-LED units in the grooves of the alignment tray.

Referring back to FIG. 1, in some embodiments, the pixel structure 50 includes a substrate 500, a plurality of vertical diode dies 520, a flip-chip diode die 530, and an upper circuit layer 540. In some embodiments, when the pixel structure 50 is applied, there may be a problem that there is no suitable method to keep the plurality of vertical diode dies 520 or flip-chip diode dies 530 neat and not skewed after being detached from the PDMS film, which causes a bottleneck in the manufacturing process of the pixel structure 50. In some embodiments, the alignment device and alignment method of the following embodiments can be used for the transfer of the vertical diode dies 520 or flip-chip diode dies 530. However, the present disclosure is not limited to this. Under different design considerations or application scenarios, other structures, processes, or manufacturing processes can be used to handle the vertical diode dies 520 or flip-chip diode dies 530 disclosed in the present disclosure.

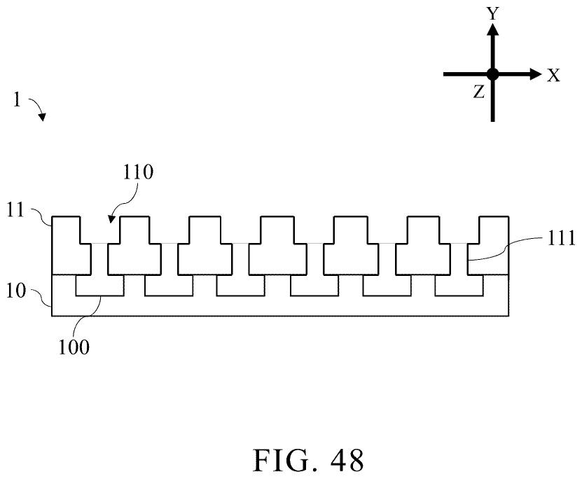

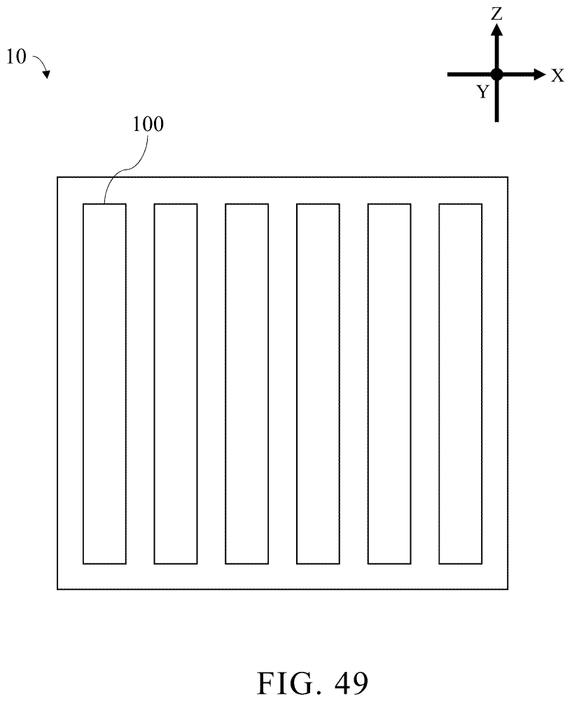

Please refer to FIGS. 48 to 50. An alignment device 1 includes a support tray 10 and an alignment tray 11. The support tray 10 includes a plurality of grooves 100. Each groove 100 extends along a first direction, and the plurality of grooves 100 are disposed at intervals along a second direction. The first direction is orthogonal to the second direction. In other words, the first direction is perpendicular to the second direction. Taking FIG. 49 as an example, in this embodiment, the support tray 10 includes six grooves 100. The first direction corresponds to the Z direction, and the second direction corresponds to the X direction. Here, these six grooves 100 each extend along the Z direction, and these six grooves 100 are arranged at intervals along the X direction.

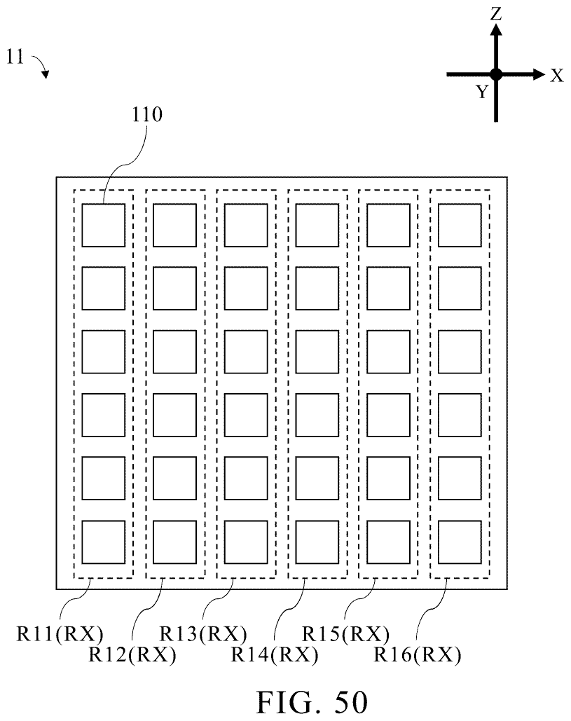

The alignment tray 11 is disposed on the support tray 10. The alignment tray 11 includes a plurality of columns RX, and the plurality of columns RX are arranged at intervals along the second direction and are individually aligned with the plurality of grooves 100. Each column RX is provided with a plurality of grooves 110. The bottom of each groove 110 includes a through hole 111, and the plurality of grooves 110 in each column RX are arranged at intervals along the first direction. Taking FIG. 50 as an example, in this embodiment, the alignment tray 11 includes six columns R11 to R16, and each column R11/R12/R13/R14/R15/R16 includes six grooves 110. The plurality of columns R11 to R16 are arranged at intervals along the X direction (i.e., the second direction) and are individually aligned with the plurality of grooves 100. The six grooves 110 in each column R11/R12/R13/R14/R15/R16 are arranged at intervals along the Z direction (i.e., the first direction). Here, the alignment tray 11 includes 36 grooves 110, and the 36 grooves 110 are arranged at intervals on the alignment tray 11 in an array.

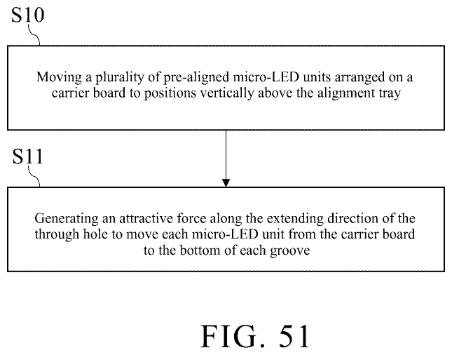

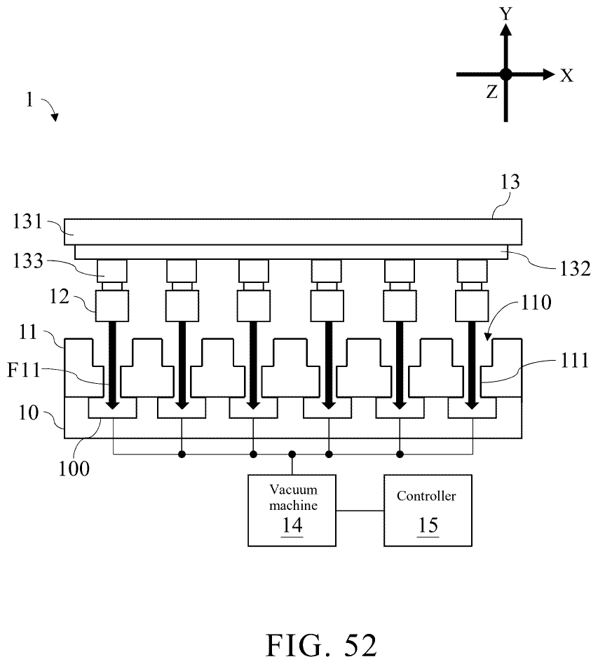

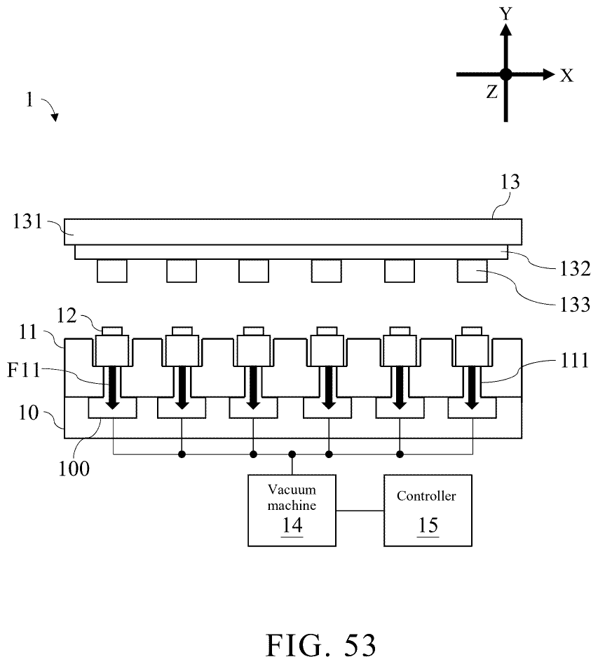

Please refer to FIGS. 48 to 53. The following takes the alignment device 1 shown in FIG. 48 as an example to illustrate the alignment method for a plurality of micro-LED units 12, but this is not intended to limit the device, hardware components, or software components for executing the alignment method. When the user starts to align a plurality of micro-LED units 12, the user operates a moving mechanism (not shown in the figure) to move the pre-aligned multiple micro-LED units 12 on a carrier board 13 to positions vertically above the alignment tray 11 (Step S10). It should be noted that the “pre-aligned multiple micro-LED units 12” means that the plurality of micro-LED units 12 on the carrier board 13 have been arranged in another array at intervals in advance, and this other array corresponds to the array formed by the plurality of grooves 110 arranged at intervals. Here, when the plurality of micro-LED units 12 are moved to positions vertically above the alignment tray 11, each micro-LED unit 12 is located vertically above each groove 110 on the alignment tray 11 (as shown in FIG. 52).

In some embodiments, the moving mechanism can be a device with the function of two-dimensional movement of an object, such as but not limited to a robotic arm. In some embodiments, the carrier board 13 includes a substrate layer 131, a thin film layer 132, and a plurality of bumps 133. Among them, the thin film layer 132 is disposed on the lower surface of the substrate layer 131, and the plurality of bumps 133 are disposed on the lower surface of the thin film layer 132 (as shown in FIG. 52). Here, the user can adsorb the plurality of micro-LED units 12 through the plurality of bumps 133 on the carrier board 13, and then move the plurality of micro-LED units 12.

In some embodiments, the material of the substrate layer 131 can be a light-transmitting insulating material, such as but not limited to glass, silicone, epoxy resin, polyimide (PI), benzocyclobutene (BCB), perfluorocyclobutane (PFCB), SU8 photoresist, acrylic resin, polyethylene terephthalate (PET), and polyetherimide. In other embodiments, the material of the substrate layer 131 can also be an opaque insulating material, such as but not limited to silicon (Si), silicon dioxide (SiO₂), gallium arsenide (GaAs), and silicon carbide (SiC). In addition, in some embodiments, the material of the thin film layer 132 and the material of the plurality of bumps 133 can be soft materials with adhesiveness, such as but not limited to polydimethylsiloxane (PDMS) or polysiloxane.

After step S10, the alignment device 1 generates an attractive force F11 along the extension direction of the through-holes 111 to move each micro-LED unit 12 from the carrier board 13 to the bottom of each groove 110 (step S11). In some embodiments, the alignment device 1 further includes a vacuum machine 14 and a controller 15. The vacuum machine 14 is coupled to the plurality of grooves 100 on the support plate 10, and the controller 15 is electrically connected to the vacuum machine 14. In some embodiments, the alignment device 1 can control the vacuum machine 14 through the controller 15 to evacuate the plurality of grooves 100, thereby generating a vacuum suction force (i.e., the attractive force F11) along the extension direction of each through-hole 111 to apply a force to each micro-LED unit 12 (as shown in FIG. 52). Here, each micro-LED unit 12 is affected by the attractive force F11 and detaches from each bump 133 on the carrier board 13, and then moves to the bottom of each groove 110 (as shown in FIG. 53).

In some embodiments, the controller 15 can be a hardware component with a control function and independent of the vacuum machine 14, such as but not limited to a central processing unit (CPU), a Microprocessor, a Digital Signal Processor (DSP), a Complex Programmable Logic Device (CPLD), a field-programmable gate array (FPGA), an Application Specific Integrated Circuit, (ASIC), or a Microcontroller Unit (MCU). In other embodiments, the controller 15 can also be a circuit module integrated in the vacuum machine 14 and having a control function.

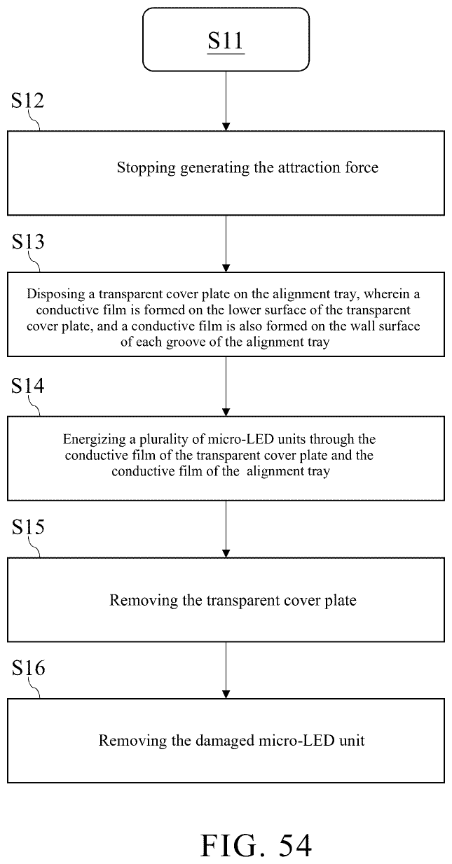

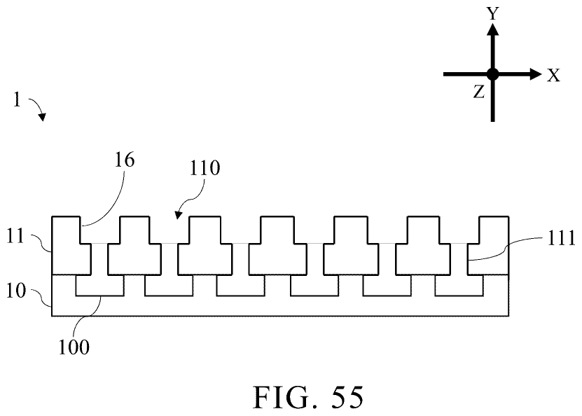

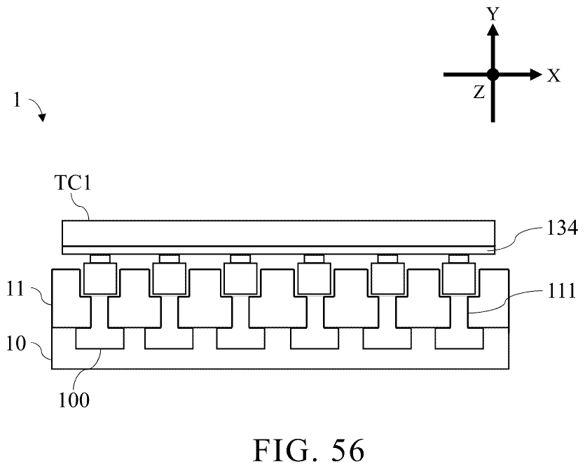

Please refer to FIGS. 48 to 57. As shown in FIG. 54, in some embodiments, the alignment device 1 can further perform a lighting test on a plurality of micro-LED units 12 to check whether the functions of the plurality of micro-LED units 12 are normal. Here, in this embodiment, the alignment tray 11 of the alignment device 1 includes a conductive film 16, and the conductive film 16 is disposed on the wall surface of each groove 110 (as shown in FIG. 55).

In some embodiments, after step S11, the alignment device 1 first stops generating the attractive force F11 (step S12). Subsequently, the user can operate the aforementioned moving mechanism to set a transparent cover plate TC1 on the alignment tray 11 (step S13). Wherein, a conductive film 134 is also formed on the lower surface of the transparent cover plate TC1. Here, in this embodiment, when the transparent cover plate TC1 is set on the alignment tray 11 so that the conductive film 134 of the transparent cover plate TC1 is directly connected to the plurality of micro-LED units 12 (as shown in FIG. 56), the conductive film 134 of the transparent cover plate TC1 and the conductive film 16 of the alignment tray 11 can serve as the two terminals (i.e., the N pole and the P pole) of the micro-LED unit 12.

In some embodiments, the user can electrically connect one of the conductive film 134 of the transparent cover plate TC1 and the conductive film 16 of the alignment tray 11 to an external power supply, and ground the other one of the conductive film 134 of the transparent cover plate TC1 and the conductive film 16 of the alignment tray 11. Here, after step S13, the user can control the external power supply to energize the plurality of micro-LED units 12 via the conductive film 134 of the transparent cover plate TC1 and the conductive film 16 of the alignment tray 11 (step S14), and then perform a lighting test on the plurality of micro-LED units 12.

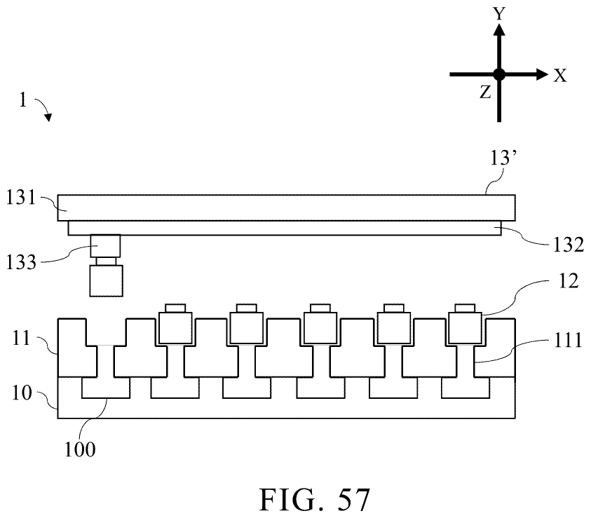

In some embodiments, after the lighting test of the plurality of micro-LED units 12 is completed (i.e., after step S14), the user operates the moving mechanism to remove the transparent cover plate TC1 (step S15). Subsequently, the user operates the moving mechanism to remove the damaged micro-LED units 12 (step S16). Taking FIG. 57 as an example, in this embodiment, another carrier board 13 is coupled to the moving mechanism (not shown in the figure), and the other carrier board 13 includes the aforementioned substrate layer 131, the thin film layer 132, and a single bump 133. Here, when performing the step of removing the damaged micro-LED units 12 (i.e., step S16), the moving mechanism can only remove one damaged micro-LED unit 12 at a time.

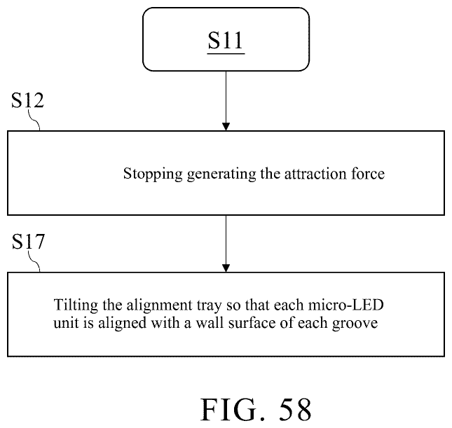

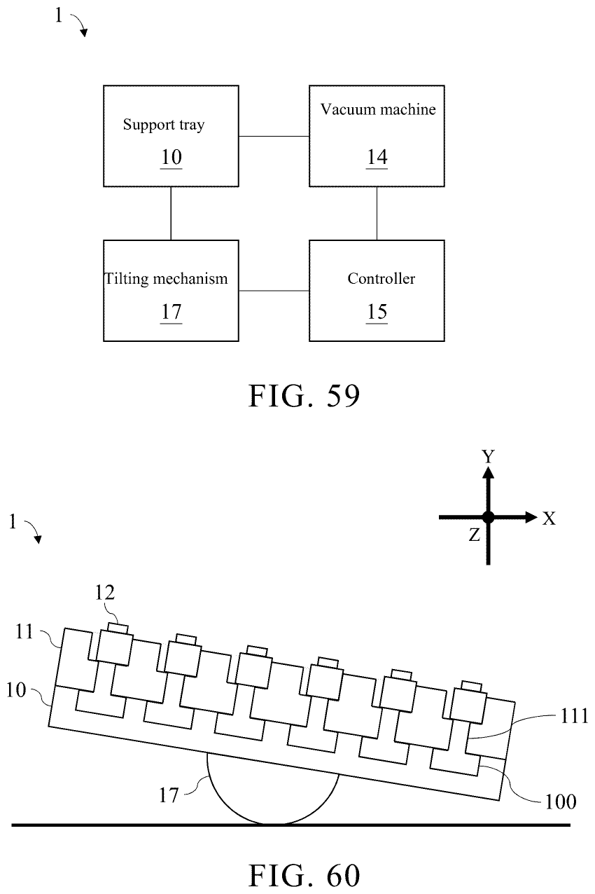

Please refer to FIGS. 48 to 52 and FIGS. 58 to 60. As shown in FIG. 59, in some embodiments, the alignment device 1 further includes a tilting mechanism 17. The tilting mechanism 17 is disposed on the lower surface of the support tray 10 and electrically connected to the controller 15, and the controller 15 is further used to control the tilting mechanism 17. Here, after each micro-LED unit 12 has been placed in each groove 110 (i.e., after step S11), the alignment device 1 can control the vacuum machine 14 through the controller 15 to stop generating the attractive force F11 (i.e., the vacuum suction force) (step S12). Subsequently, the alignment device 1 can control the tilting mechanism 17 to tilt through the controller 15, so that the alignment tray 11 tilts accordingly, causing each micro-LED unit 12 to align with one wall surface of each groove 110 (step S17). Taking FIG. 60 as an example, in this embodiment, the tilting mechanism 17 tilts in the clockwise direction. Here, the right half of the alignment tray 11 tilts downward, causing each micro-LED unit 12 to align with the right side wall surface of each groove 110.

It should be noted that the tilting mechanism 17 is not limited to tilting in the clockwise direction. In other embodiments, the tilting mechanism 17 can also tilt in the counterclockwise direction, causing the left half of the alignment tray 11 to tilt downward, thereby causing each micro-LED unit 12 to align with the left side wall surface of each groove 110 (not shown in the figure).

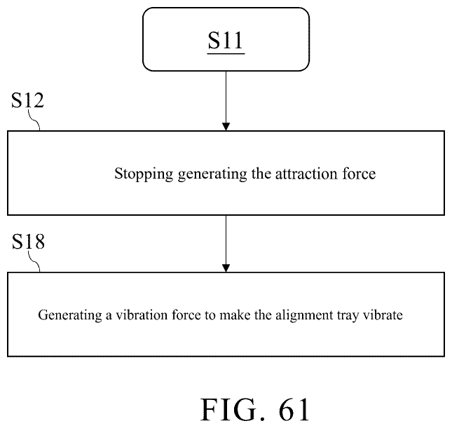

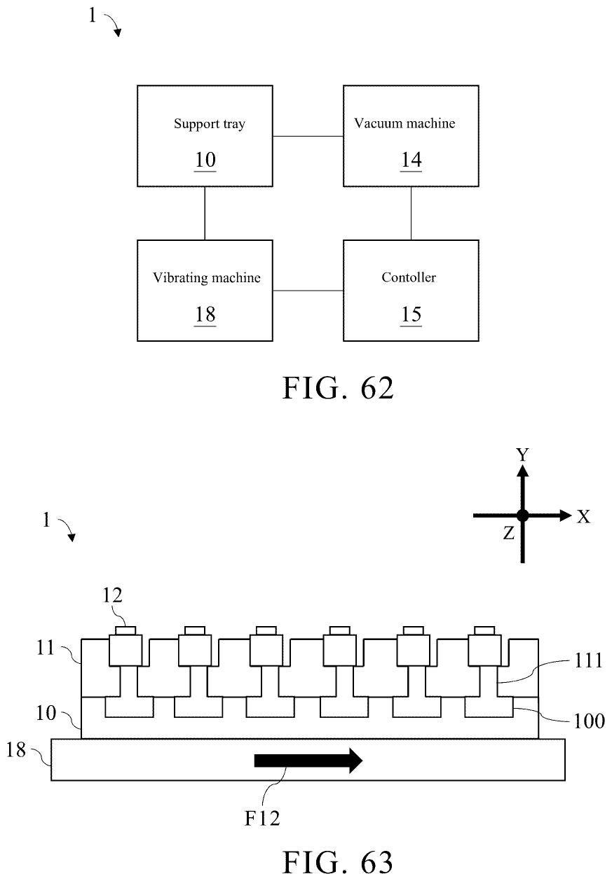

Please refer to FIGS. 48 to 52 and FIGS. 61 to 63. As shown in FIG. 62, in some embodiments, the alignment device 1 further includes a vibrating machine 18. The vibrating machine 18 is disposed on the lower surface of the support tray 10 and electrically connected to the controller 15, and the controller 15 is further used to control the vibrating machine 18. Here, after each micro-LED unit 12 has been placed in each groove 110 (i.e., after step S11), the alignment device 1 can control the vacuum machine 14 through the controller 15 to stop generating the attractive force F11 (i.e., the vacuum suction force) (step S12). Subsequently, the alignment device 1 can control the vibrating machine 18 through the controller 15 to generate a vibration force F12 to make the alignment tray 11 vibrate (step S18). In response to the vibration of the alignment tray 11, each micro-LED unit 12 is aligned with one wall surface of each groove 110. Taking FIG. 63 as an example, in this embodiment, the vibrating machine 18 generates a vibration force F12 in the X direction to make the alignment tray 11 vibrate in the X direction. Here, a friction force in the opposite direction of the X direction is generated between each micro-LED unit 12 and the bottom of each groove 110 (not shown in the figure), so that each micro-LED unit 12 is displaced to the left under the action of the friction force, and then each micro-LED unit 12 is aligned with the left wall surface of each groove 110.

It should be noted that the vibrating machine 18 is not limited to generating the vibration force F12 in the X direction. In other embodiments, the vibrating machine 18 can also generate a vibration force F12 in the opposite direction of the X direction, so that a friction force in the X direction is generated between each micro-LED unit 12 and the bottom of each groove 110. Then each micro-LED unit 12 is displaced to the right under the action of the friction force and aligned with the right wall surface of each groove 110 (not shown in the figure).

In some embodiments, the support tray 10 is made of a hard material without conductivity, such as but not limited to glass, silicon (Si), silicon dioxide (SiO₂), gallium arsenide (GaAs), and silicon carbide (SiC). In addition, in some embodiments, the alignment tray 11 is made of an insulating material, such as but not limited to silicone, epoxy resin, polyimide (PI), benzocyclobutene (BCB), perfluorocyclobutane (PFCB), SU8 photoresist, acrylic resin, polyethylene terephthalate (PET), and polyetherimide. Here, benefiting from the characteristics of the material of the support tray 10, the sidewalls around each groove 100 in the support tray 10 can support the alignment tray 11, thereby ensuring that the alignment tray 11 will not be deformed by the action of the attractive force F11 (such as but not limited to vacuum suction) or the vibration force F12.

According to any embodiment, the alignment device and the alignment method can remove the film of a plurality of pre-aligned micro-LED units and place each micro-LED unit in each groove of the alignment tray. In addition, the alignment device and the alignment method can align each micro-LED unit with one wall surface of each groove through a tilting mechanism or a vibrating machine to achieve the neat arrangement of a plurality of micro-LED units, thereby improving the accuracy and efficiency of the subsequent mass transfer of a plurality of micro-LED units.

Although the present disclosure has been clearly disclosed according to the above different embodiments, each embodiment is not intended to limit the present disclosure. Any person with ordinary knowledge in the technical field can make various modifications, substitutions, or omissions to the above embodiments without departing from the spirit and scope of the present disclosure, and still have the technical scope protected by the present disclosure. Therefore, the protection scope of the present disclosure shall be subject to the scope defined by the patent application.

### SYMBOL EXPLANATION

1: Alignment device
10: Support tray
100: Groove
11: Alignment tray
110: Groove
111: Through-hole
12: Micro-LED unit
13: Carrier board
13′: Carrier board
131: Substrate layer
132: Thin film layer
133: Bump
134: Conductive film
14: Vacuum machine
15: Controller
16: Conductive film
17: Tilting mechanism
18: Vibrating machine
F11: Attractive force
F12: Vibration force
R11: Column
R12: Column
R13: Column
R14: Column
R15: Column
R16: Column
RX: Column
S10: Step
S11: Step
S12: Step
S13: Step
S14: Step
S15: Step
S16: Step
S17: Step
S18: Step
TC1: Transparent cover plate
2: Pre-alignment device
20: Vibrating machine
201: Side wall
202: Base plate
21: Alignment tray
210: Groove
211: Through hole
22: Electromagnet
23: Controller
24: Micro-LED unit
241: Micro-LED die
242: Carrier layer
243: Magnetic conductive layer
F21: Attractive force
F22: Vibration force
R21: Dotted box
R22: Dotted box
S20: Step
S21: Step
S22: Step
S23: Step
S24: Step
3: Vertical micro-LED structure
30: Vertical micro-LED unit
30B: Micro-LED unit
30G: Micro-LED unit
30R: Micro-LED unit
31: First backplane
310: First substrate
311: First circuit layer
311B: First circuit layer
311G: First circuit layer
311R: First circuit layer
312: First contact pad
312B: First contact pad
312G: First contact pad
312R: First contact pad
313: Transparent electrode layer
313B: Transparent electrode layer
313G: Transparent electrode layer
313R: Transparent electrode layer
32: Second backplane
320: Second substrate
321: Second circuit layer
321B: Second circuit layer
321G: Second circuit layer
321R: Second circuit layer
322: Eutectic metal layer
323: Alloy layer
324: Micro-LED die
324B: Micro-LED die
324G: Micro-LED die
324R: Micro-LED die
325: Second contact pad
325B: Second contact pad
325G: Second contact pad
325R: Second contact pad
326: Isolation layer
326A: Opaque material
326B: Light-transmissive material
327: Cavity
A1: Axis
A2: Axis
A3: Axis
L1: Thickness
L2: Thickness
S30-S35: Steps
S300-S302: Steps
S310-S313: Steps
S330-S332: Steps
S340-S343: Steps
40: Hybrid micro-LED structure
400: Substrate
410: Micro-LED die
410R: Red micro-LED die
410G: Green micro-LED die
410B: Blue micro-LED die
410S: Spare micro-LED die
420: Isolation layer
420A: Opaque material
420B: Isolation material
430: Filling layer
440: Light-transmitting layer
450: Inkjet space
IM: Inkjet material
S40-S45: Steps
50: Pixel structure
500: Substrate
510: Lower circuit layer
511: First circuit
512: Second circuit
513: Lower electrode
520, V1, V2, V3: Vertical diode die
V2′, V3′: Ineffective vertical diode die
521: First electrode
522: First doped layer
523: First quantum well
524: Second doped layer
525: Second electrode
526: First light conversion material layer
530, F: Flip-chip diode die
531: Third electrode
532: Third doped layer
533: Second quantum well
534: Fourth doped layer
535: Fourth electrode
536: Substrate layer
537: Second light conversion material layer
538: First filling layer
539: Second filling layer
540: Upper circuit layer
541: Third circuit
542: Upper electrode
550: First blocking dam
551: Accommodation site
560: Second blocking dam
570: Protective layer
580: Third filling layer
51: Panel structure
S511-S519: Steps
S521-S5212: Steps
S531-S5312: Steps
600: Panel structure
60: Diode die
601: First diode die
602: Second diode die
603: Third diode die
601′: The first diode substrate
602′: The second diode substrate
603′: The third diode substrate
61,611,612,613: The first substrate
62,621,622,623: Top electrode
63,631,632,633: Epitaxial Layer
64,641,642,643: Bottom electrode
65,651,652,653: The second substrate
66: First bonding layer
67: Second bonding layer
68,681,682,683: Conductor layer
69: The third substrate
G6: Grinding machine
BL1: First reference line
BL2: Second reference line
BL3: Third reference line
BLA: Fourth reference line
D61, D62, D63: Thickness
H61, H62, H63: Height
S601-S612: Steps
S6051-S6054: Steps.

What is claimed is:

1. A pixel structure, comprising:
a substrate having a lower circuit layer, the lower circuit layer comprising a plurality of first circuits and a second circuit, the first circuits having a first polarity, and the second circuit having a second polarity;
a plurality of vertical diode dies disposed on the substrate and respectively coupled to the first circuits;
a flip-chip diode die disposed on the substrate and coupled to one of the first circuits and the second circuit; and
an upper circuit layer disposed on the plurality of vertical diode dies and the flip-chip diode die, the upper circuit layer comprising a plurality of third circuits respectively coupled to the vertical diode dies, and the third circuits having the second polarity.

2. The pixel structure according to claim 1, wherein the pixel structure further comprises a plurality of blocking dams and a light-transmitting filling layer, wherein the plurality of blocking dams define a plurality of accommodation sites, the plurality of vertical diode dies and the flip-chip diode die are respectively located within the plurality of accommodation sites; and wherein the light-transmitting filling layer covers the flip-chip diode die, and a top surface of the light-transmitting filling layer is substantially coplanar with top surfaces of the blocking dams.

3. The pixel structure according to claim 1, wherein the plurality of vertical diode dies comprise at least one ineffective vertical diode and at least one effective vertical diode; and wherein a color category of light beam corresponding to the flip-chip diode die is different from color categories of light beams respectively corresponding to the at least one effective vertical diode.

4. The pixel structure according to claim 1, wherein the pixel structure further comprises a plurality of first light conversion material layers respectively covering tops of the vertical diode dies.

5. The pixel structure according to claim 1, wherein the pixel structure further comprises a second light conversion material layer covering a top of the flip-chip diode die.

6. The pixel structure according to claim 1, wherein the pixel structure further comprises a vertical diode die unit, comprising:
a first backplane, comprising:
another substrate;
the upper circuit layer, disposed on the other substrate;
a first contact pad disposed on the upper circuit layer; and
a transparent electrode layer disposed on the upper circuit layer and the first contact pad; and
a second backplane, comprising:
the substrate;
the lower circuit layer disposed on the substrate;
a eutectic metal layer disposed on the lower circuit layer;
an alloy layer disposed on the eutectic metal layer;
one of the vertical diode dies disposed on the alloy layer;
a second contact pad disposed on the one vertical diode die; and
an isolation layer disposed on the substrate to surround the one vertical diode die;
wherein, the first backplane is disposed on the second backplane to form a cavity, projected areas of the first contact pad and the second contact pad in a normal direction of the first backplane at least partially overlap, and the transparent electrode layer connects the second contact pad and the isolation layer;
when the first backplane is disposed on the second backplane, the isolation layer deforms such that a thickness of the deformed isolation layer is equal to a sum of a thickness of the first contact pad, a thickness of the lower circuit layer, a thickness of the eutectic metal layer, a thickness of the alloy layer, a thickness of the one vertical diode die, and a thickness of the second contact pad.

7. The pixel structure according to claim 6, wherein the isolation layer of the vertical diode die unit comprises an opaque material and a light-transmissive material, wherein the opaque material surrounds the one vertical diode die and the second contact pad, and the light-transmissive material surrounds the lower circuit layer, the eutectic metal layer, and the alloy layer.

8. The pixel structure according to claim 1, wherein the plurality of vertical diode dies comprise:
a first diode die comprising a first electrode, the first electrode having a first electrode thickness; and
a second diode die comprising a second electrode, the second electrode having a second electrode thickness, the first electrode thickness being greater than the second electrode thickness, and die heights of the first diode die and the second diode die being substantially the same.

9. The pixel structure according to claim 8, wherein the first electrode is a bottom electrode of the first diode die, and the second electrode is a bottom electrode of the second diode die.

10. A panel structure, comprising a plurality of pixel structures according to claim 8, respectively comprising the first diode die and the second diode die, wherein the first electrode thickness of the first electrode of the first diode die in each pixel structure is substantially the same, and the second electrode thickness of the second electrode of the second diode die in each pixel structure is substantially the same.

11. A panel structure, comprising:
a substrate having a lower circuit layer, the lower circuit layer comprising a plurality of first circuits and a plurality of second circuits, the first circuits having a first polarity, the second circuits having a second polarity;
a first pixel structure having a plurality of first accommodation sites, wherein the first pixel structure comprises:
a plurality of first vertical diode dies disposed on the substrate and respectively located within the first accommodation sites, and respectively coupled to the first circuits; and
a flip-chip diode die disposed on the substrate and located within one of the first accommodation sites, and coupled to one of the first circuits and one of the second circuits;
a second pixel structure having a plurality of second accommodation sites, wherein the second pixel structure comprises:
a plurality of second vertical diode dies disposed on the substrate and respectively located within the second accommodation sites, and respectively coupled to the first circuits; and
a filling layer disposed on the substrate and located within one of the second accommodation sites; and
an upper circuit layer disposed on the first pixel structure and the second pixel structure, the upper circuit layer comprising a plurality of third circuits respectively coupled to the first vertical diode dies and the second vertical diode dies, wherein the third circuits have the second polarity.

12. A method for repairing a pixel structure, comprising the following steps of:
providing a substrate;
forming a lower circuit layer on the substrate, the lower circuit layer comprising a first circuit and a second circuit, the first circuit having a first polarity, and the second circuit having a second polarity;
disposing a vertical diode die on the substrate and connecting the vertical diode die to the first circuit; and
determining whether the vertical diode die is effective to decide whether to dispose a flip-chip diode die on the substrate.

13. The method for repairing a pixel structure according to claim 12, wherein the method for repairing a pixel structure further comprises disposing the flip-chip diode die on the substrate when it is determined that the vertical diode die is ineffective.

14. The method for repairing a pixel structure according to claim 12, wherein the method for repairing a pixel structure further comprises:
when it is determined that the vertical diode die is ineffective, disposing the flip-chip diode die on the substrate, wherein the flip-chip diode die is a short-wavelength light-emitting diode die; and
coating a light conversion material layer on the flip-chip diode die.

15. The method for repairing a pixel structure according to claim 12, wherein the method for repairing a pixel structure further comprises:
forming a plurality of blocking dams on the substrate, wherein the plurality of blocking dams define a plurality of accommodation sites;
disposing a plurality of vertical diode dies on the substrate and respectively locating the plurality of vertical diode dies within the accommodation sites; and
when it is determined that all the vertical diode dies are effective, disposing a filling layer within the remaining accommodation sites, wherein the remaining accommodation sites do not contain the vertical diode dies.

16. The method for repairing a pixel structure according to claim 12, wherein the method for repairing a pixel structure further comprises: forming an upper circuit layer on the plurality of vertical diode dies and the flip-chip diode die, wherein the upper circuit layer comprises a third circuit coupled to the vertical diode die, wherein the third circuit has the second polarity.

17. A pixel structure, comprising:
a substrate;
a red micro-LED die disposed on the substrate;
a green micro-LED die disposed on the substrate;
a blue micro-LED die disposed on the substrate;
a spare micro-LED die disposed on the substrate;
an isolation layer disposed on the substrate, the isolation layer surrounding the spare micro-LED die and forming an inkjet space with the spare micro-LED die, wherein the inkjet space is configured to fill an inkjet material;
a filling layer disposed on the substrate to fix the red micro-LED die, the green micro-LED die, the blue micro-LED die, the spare micro-LED, and the isolation layer on the substrate; and
a light-transmitting layer disposed on the filling layer;
wherein, any one of the red micro-LED die, the green micro-LED die, the blue micro-LED die, and the spare micro-LED die is adjacent to at least one of the remaining three.

18. The pixel structure according to claim 17, wherein the spare micro-LED die is an ultraviolet micro-LED die, and the light-transmitting layer contains an anti-ultraviolet material.

19. The pixel structure according to claim 17, wherein the spare micro-LED die is another blue micro-LED die.

20. The pixel structure according to claim 19, wherein the spare micro-LED die is adjacent to the blue micro-LED die.

21. The pixel structure according to claim 20, wherein the spare micro-LED die is further adjacent to the red micro-LED die or the green micro-LED die.

22. The pixel structure according to claim 17, wherein the isolation layer contains an opaque material, wherein the opaque material surrounds the spare micro-LED die and the inkjet space.

23. The pixel structure according to claim 17, wherein the isolation layer contains an opaque material and a light-transmissive material, wherein the opaque material surrounds the inkjet space, and the light-transmissive material surrounds the spare micro-LED die.

24. The pixel structure according to claim 17, wherein when one of the red micro-LED die, the green micro-LED die, and the blue micro-LED die is damaged, the inkjet space is filled with an inkjet material corresponding to a color of the damaged one.

25. The pixel structure according to claim 17, wherein the spare micro-LED die is a flip-chip diode die.
